(19) United States
(12) Patent Application Publication
(10) Pub. No.: US 2023/0320163 A1
(43) Pub. Date: Oct. 5, 2023

(54) COLOR CONVERSION FILM, METHOD FOR MANUFACTURING COLOR CONVERSION FILM, BACKLIGHT UNIT, AND LIQUID CRYSTAL DISPLAY DEVICE

(71) Applicant: FUJIFILM CORPORATION, Tokyo (JP)

(72) Inventor: Yohei ARITOSHI, Shizuoka (JP)

(21) Appl. No.: 18/316,242

(22) Filed: May 12, 2023

Related U.S. Application Data
(63) Continuation of application No. PCT/JP2021/039167, filed on Oct. 22, 2021.

(30) Foreign Application Priority Data
Dec. 18, 2020 (JP) 2020-210832

(51) Int. Cl. H10K 59/38; G02F 1/1335; F21V 8/00; G02F 1/13357; C09K 11/06

(52) U.S. Cl. CPC H10K 59/38; C09K 11/06; G02B 6/005; G02F 1/133614; G02F 1/133621; C09K 2211/1018; G02F 2201/50

(57) ABSTRACT

A color conversion film including a support, a first color conversion layer containing an organic light-emitting material which emits, by an excitation light having a wavelength of 400 nm or more and less than 500 nm, light observed in a region having a peak wavelength of 500 nm or more and less than 580 nm, a second color conversion layer containing an organic light-emitting material which emits, by at least one of the excitation light having a wavelength of 400 nm or more and less than 500 nm or the light emitted from the organic light-emitting material, light observed in a region having a peak wavelength of 580 nm or more and less than 750 nm, and an interlayer mixing layer between the first color conversion layer and the second color conversion layer, in which the first color conversion layer and the second color conversion layer are mixed together.

### CROSS-REFERENCE TO RELATED APPLICATIONS

This application is a continuation application of International Application No. PCT/JP2021/039167, filed Oct. 22, 2021, the disclosure of which is incorporated herein by reference in its entirety. Further, this application claims priority from Japanese Patent Application No. 2020-210832, filed Dec. 18, 2020, the disclosure of which is incorporated herein by reference in its entirety.

### BACKGROUND OF THE INVENTION

### 1. Field of the Invention

The present disclosure relates to a color conversion film, a method for manufacturing a color conversion film, a backlight unit, and a liquid crystal display device.

### 2. Description of the Related Art

A flat panel display such as a liquid crystal display device (LCD) has low power consumption, and its use has been expanded year by year as a space-saving display device.

Since a color conversion film of a backlight unit included in the LCD contains a light-emitting material which emits green light and red light by blue light, white light in which the blue light, the green light, and the red light are mixed can be extracted from the color conversion film.

As the color conversion film, for example, a color conversion film including a support, a layer (A) that contains an organic light-emitting material which emits green light having a peak wavelength of 500 nm or more and less than 580 nm by blue light having a wavelength of 400 nm or more and less than 500 nm, and a layer (B) that contains an organic light-emitting material which emits red light having a peak wavelength of 580 nm or more and 750 nm or less by the blue light or the green light, in which SP values of binder resins contained in the layer (A) the layer (B) have a specific relationship, has been known (for example, see WO2018/221216A and the like).

### SUMMARY OF THE INVENTION

In the color conversion film proposed in WO2018/221216A, the lamination of the layer (A) and the layer (B) is obtained by heating laminating, and the present inventor has recently found that the above-described color conversion film has room for improvement in adhesiveness between the layer (A) and the layer (B).

The present disclosure has been made based on the above-described findings, and an object to be achieved is to provide a color conversion film having excellent interlayer adhesiveness, a method for manufacturing a color conversion film, a backlight unit including the color conversion film, and a liquid crystal display device including the backlight unit.

<1> A color conversion film comprising, in the following order:
a support;
a first color conversion layer containing an organic light-emitting material which emits, by an excitation light having a wavelength of 400 nm or more and less than 500 nm, light observed in a region having a peak wavelength of 500 nm or more and less than 580 nm;
a second color conversion layer containing an organic light-emitting material which emits, by at least one of the excitation light having a wavelength of 400 nm or more and less than 500 nm or the light emitted from the organic light-emitting material, light observed in a region having a peak wavelength of 580 nm or more and less than 750 nm; and
an interlayer mixing layer between the first color conversion layer and the second color conversion layer, in which the first color conversion layer and the second color conversion layer are mixed together.

<2> A color conversion film comprising, in the following order:
a support;
a first color conversion layer containing an organic light-emitting material which emits, by at least one of an excitation light having a wavelength of 400 nm or more and less than 500 nm or light emitted from an organic light-emitting material contained in a second color conversion layer, light observed in a region having a peak wavelength of 580 nm or more and less than 750 nm;
a second color conversion layer containing the organic light-emitting material which emits, by the excitation light having a wavelength of 400 nm or more and less than 500 nm, light observed in a region having a peak wavelength of 500 nm or more and less than 580 nm; and
an interlayer mixing layer between the first color conversion layer and the second color conversion layer, in which the first color conversion layer and the second color conversion layer are mixed together.

<3> The color conversion film according to <1> or <2>, in which a thickness of the interlayer mixing layer is 0.1 µm to 2.0 µm.

<4> The color conversion film according to any one of <1> to <3>, further comprising:
a protective layer on a side of the second color conversion layer opposite to the first color conversion layer.

<5> The composition for a color conversion film according to any one of <1> to <4>, in which at least one of the organic light-emitting material contained in the first color conversion layer or the organic light-emitting material contained in the second color conversion layer is represented by General Formula (1),

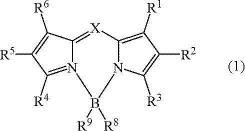

in General Formula (1), X represents C-R⁷ or N, and R¹ to R⁹ are each independently selected from a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an arylether group, an arylthioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, or a phosphine oxide group, where adjacent groups of R¹ to R⁹ may form a fused ring.

<6> A method for manufacturing a color conversion film, comprising:
forming, on a support, a first color conversion layer containing an organic light-emitting material which emits, by an excitation light having a wavelength of 400 nm or more and less than 500 nm, light observed in a region having a peak wavelength of 500 nm or more and less than 580 nm; and
forming, on the first color conversion layer, a second color conversion layer containing an organic light-emitting material which emits, by at least one of the excitation light having a wavelength of 400 nm or more and less than 500 nm or the light emitted from the organic light-emitting material, light observed in a region having a peak wavelength of 580 nm or more and less than 750 nm, and forming an interlayer mixing layer between the first color conversion layer and the second color conversion layer, in which the first color conversion layer and the second color conversion layer are mixed together.

<7> A method for manufacturing a color conversion film, comprising:
forming, on a support, a first color conversion layer containing an organic light-emitting material which emits, by at least one of an excitation light having a wavelength of 400 nm or more and less than 500 nm or light emitted from an organic light-emitting material contained in a second color conversion layer, light observed in a region having a peak wavelength of 580 nm or more and less than 750 nm; and
forming, on the first color conversion layer, a second color conversion layer containing an organic light-emitting material which emits, by the excitation light having a wavelength of 400 nm or more and less than 500 nm, light observed in a region having a peak wavelength of 500 nm or more and less than 580 nm, and forming an interlayer mixing layer between the first color conversion layer and the second color conversion layer, in which the first color conversion layer and the second color conversion layer are mixed together.

<8> The method for manufacturing a color conversion film according to <6> or <7>,
in which the forming of the first color conversion layer is performed by applying and drying a coating liquid for forming the first color conversion layer on the support.

<9> The method for manufacturing a color conversion film according to any one of <6> to <8>,
in which the forming of the second color conversion layer is performed by applying and drying a coating liquid for forming the second color conversion layer on the first color conversion layer.

<10> The method for manufacturing a color conversion film according to <9>,
in which the coating liquid for forming the second color conversion layer contains a high-boiling-point organic solvent having a boiling point of 100° C. or higher and a low-boiling-point organic solvent having a boiling point of 99° C. or lower.

<11> The method for manufacturing a color conversion film according to <10>,
in which a content of the high-boiling-point organic solvent is 20 parts by mass to 80 parts by mass with respect to 100 parts by mass of a total amount of the organic solvents contained in the coating liquid for forming the second color conversion layer.

<12> A backlight unit comprising:
a light source; and
the color conversion film according to any one of <1> to <5>.

<13> A liquid crystal display device comprising:
the backlight unit according to <12>; and
a liquid crystal cell unit.

According to the present disclosure, it is possible to provide a color conversion film having excellent interlayer adhesiveness, a method for manufacturing a color conversion film, a backlight unit including the color conversion film, and a liquid crystal display device including the backlight unit.

### BRIEF DESCRIPTION OF THE DRAWINGS

FIG. 1 is a schematic cross-sectional diagram showing one embodiment of a color conversion film according to a first aspect.

FIG. 2 is a schematic configuration cross-sectional diagram showing an embodiment of a backlight unit according to the present disclosure.

FIG. 3 is a schematic configuration cross-sectional diagram showing an embodiment of a liquid crystal display device according to the present disclosure.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present disclosure, the numerical ranges shown using “to” include the numerical values described before and after “to” as the minimum value and the maximum value.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example.

In the present disclosure, each component may contain a plurality of types of corresponding substances. In a case where a plurality of types of substances corresponding to each component are present in the composition, a content rate or a content of each component is the total content rate or the total content of the plurality of types of substances present in the composition, unless otherwise specified.

In the present disclosure, “(meth)acrylic” is a term used in a concept which includes both acrylic and methacrylic.

In the present disclosure, a term “layer” includes not only a case where the layer is formed over the entire region but also a case where the layer is formed only in part of the region.

In the present disclosure, “light-emitting material” refers to a material which, when irradiated with light, emits light having a wavelength different from that of the light.

In the present disclosure, “excitation light” refers to light which can excite the organic light-emitting material to emit light.

In the present disclosure, a peak wavelength of light emitted from an organic light-emitting material contained in a first color conversion layer included in the color conversion film and a peak wavelength of light emitted from an organic light-emitting material contained in a second color conversion layer included in the color conversion film are measured as follows.

First, the color conversion film is disposed on a planar light-emitting device capable of emitting excitation light having a wavelength of 400 nm or more and less than 500 nm, and a prism sheet is placed on the color conversion film.

Since white light including blue light, green light, and red light is observed in a case where a current is passed through the planar light-emitting device and the above-described color conversion film is irradiated with the above-described excitation light, emission spectrum of the white light is obtained using a spectral emission brightness meter (for example, CS-1000 manufactured by Konica Minolta Inc.), and from the emission spectrum, light emission observed in a region with a peak wavelength of 500 nm or more and less than 580 nm and light emission observed in a region with a peak wavelength of 580 nm or more and 750 nm or less are confirmed.

In the present disclosure, a thickness of each layer can be controlled by adjusting a coating amount of a coating liquid and a concentration (% by mass) of solid contents of a liquid so as to obtain a desired thickness. In addition, the thickness can be determined from a cross-sectional image of the color conversion film, which is obtained by a scanning electron microscopy (SEM) or a transmission electron microscopy (TEM).

In the present disclosure, “boiling point” means a standard boiling point (boiling point at 1 atm). In addition, the boiling point is measured according to JIS K 2254:2018.

In the drawings, constituent components substantially the same are designated by the same reference numerals, and the description thereof will be omitted.

Hereinafter, the present disclosure will be described in detail.

### Color Conversion Film According to First Aspect

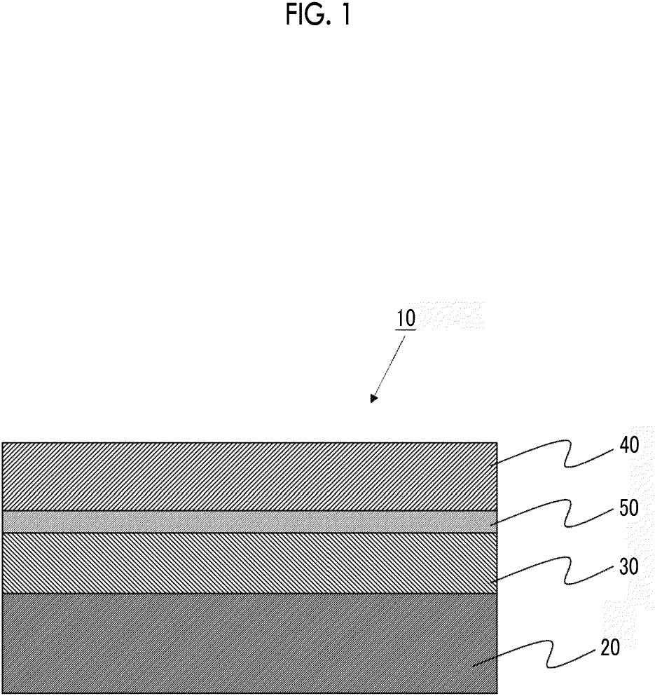

In a first aspect, as shown in FIG. 1, a color conversion film 10 includes, in the following order, a support 20; a first color conversion layer 30 containing an organic light-emitting material which emits, by excitation light having a wavelength of 400 nm or more and less than 500 nm, light observed in a region having a peak wavelength of 500 nm or more and less than 580 nm; a second color conversion layer 40 containing an organic light-emitting material which emits, by at least one of the excitation light having a wavelength of 400 nm or more and less than 500 nm or the light emitted from the organic light-emitting material, light observed in a region having a peak wavelength of 580 nm or more and less than 750 nm; and an interlayer mixing layer 50 between the first color conversion layer 30 and the second color conversion layer 40, in which the first color conversion layer 30 and the second color conversion layer 40 are mixed together.

With the above-described color conversion film, it is possible to provide a color conversion film having excellent adhesiveness between the first color conversion layer and the second color conversion layer.

The reason why the above-described effect is obtained is presumed as follows, but is not limited thereto.

The color conversion film according to the first aspect includes an interlayer mixing layer between the first color conversion layer and the second color conversion layer, in which these layers are mixed together. Since the first color conversion layer and the second color conversion layer included in the color conversion film are integrated by the above-described interlayer mixing layer, it is presumed that the adhesiveness therebetween is improved.

### Support

The support is not particularly limited, and a known support in the related art can be used. Examples of the support include a resin film, glass, ceramic, paper, a metal plate, and a foil.

Examples of a resin material contained in the above-described resin film include polyester such as polyethylene terephthalate (PET), a cellulose resin such as cellulose acetate, a polyolefin resin such as polyethylene and polypropylene, a polyamide resin, a polyimide resin, a polystyrene resin, a polycarbonate resin, a vinyl resin, a silicone resin, a fluororesin, a thermocurable resin, and a photocurable resin.

The above-described resin film may be surface-treated, and for example, a resin film subjected to chemical matting treatment may be used as the support. By using the resin film which is subjected to the chemical matting treatment, it is possible to impart a function of light diffusion layer to the support.

From the viewpoint that it has flexibility, does not undergo significant deformation, shrinkage, or elongation under pressure or under pressure and heat, has excellent transparency, and has excellent smoothness, the above-described resin film is preferably a polyester film and particularly preferably a polyethylene terephthalate film.

The polyester film is preferably a biaxially stretching film.

In addition, a thickness of the polyester film is preferably 20 µm to 250 µm.

Examples of a commercially available product of the polyester film include LUMIRROR (registered trademark) #38-U48, LUMIRROR (registered trademark) #50-U48, LUMIRROR (registered trademark) #75-U48, LUMIRROR (registered trademark) #50-U40, and LUMIRROR (registered trademark) #75-U40 (all of which are manufactured by Toray Industries, Inc.); and COSMOSHINE (registered trademark) A4100 (film thickness: 50 µm, 75 µm, 100 µm, 125 µm, and 188 µm), COSMOSHINE (registered trademark) A4300 (film thickness: 38 µm, 50 µm, 75 µm, 100 µm, 125 µm, 188 µm, and 250 µm), and COSMOSHINE (registered trademark) A8300 (film thickness: 100 µm) (all of which are manufactured by TOYOBO Co., Ltd.).

The support may be manufactured by a known method in the related art, or a commercially available support may be used. Examples of the above-described resin film subjected to the chemical matting treatment include Chemical Matte 125PW manufactured by KIMOTO. Examples of the chemical matting treatment include treating a surface of the film with a chemical agent to form an uneven structure.

A thickness of the support is not particularly limited, but from the viewpoint of strength of the color conversion film and retention of the color conversion layer, it is preferably 20 µm or more, and more preferably 30 µm or more.

In addition, from the viewpoint of downsizing of a backlight unit or the like, the thickness of the support is preferably 1000 µm or less.

### First Color Conversion Layer

In the first aspect, the first color conversion layer contains an organic light-emitting material (hereinafter, also referred to as a specific organic light-emitting material A) which emits, by excitation light having a wavelength of 400 nm or more and less than 500 nm, light observed in a region having a peak wavelength of 500 nm or more and less than 580 nm.

Examples of the specific organic light-emitting material A include a compound having a fused aryl ring and a derivative thereof. Examples of the fused aryl ring include naphthalene, anthracene, phenanthrene, pyrene, chrycene, naphthacene, triphenylene, perylene, fluorantene, fluorene, and indene.

In addition, examples of the specific organic light-emitting material A include a compound having a heteroaryl ring, a derivative thereof, and a borane compound. Examples of the heteroaryl ring include furan, pyrrole, thiophene, silole, 9-silafluorene, 9,9′-spirobisilafluorene, benzothiophene, benzofuran, indole, dibenzothiophene, dibenzofuran, imidazopyridine, phenanthroline, pyridine, pyrazine, naphthyridine, quinoxaline, and pyrrolopyridine.

In addition, examples of the specific organic light-emitting material A include a stillbene compound, an aromatic acetylene compound, a tetraphenylbutadiene compound, an aldazine compound, a pyrromethene compound, and a diketopyrrolo[3,4-c]pyrrole compound. Examples of the stillbene compound include 1,4-distyrylbenzene, 4,4′-bis(2-(4-diphenylaminophenyl)ethenyl)biphenyl, and 4,4′-bis(N-(stillben-4-yl)-N-phenylamino)stillbene.

In addition, examples of the specific organic light-emitting material A include coumarin compounds such as coumarin 6, coumarin 7, and coumarin 153; azole compounds such as imidazole, thiazole, thiadiazole, carbazole, oxazole, oxadiazole, and triazole and metal complexes thereof, cyanine-based compounds such as indocyanine green; xanthene-based compounds such as fluorescein, eosin, and rhodamine; and thioxanthene-based compounds.

In addition, examples of the specific organic light-emitting material A include polyphenylene-based compounds, naphthalimide compounds, phthalocyanine compounds and metal complexes thereof, porphyrin compounds and metal complexes thereof, oxazine-based compounds such as Nile red and Nile blue, helicene-based compounds, and aromatic amine compounds such as N,N′-diphenyl-N,N′-di(3-methylphenyl)-4,4′-diphenyl-1,1′-diamine.

In addition, examples of the specific organic light-emitting material A include organic metal complex compounds of iridium (Ir), ruthenium (Ru), rhodium (Rh), palladium (Pd), platinum (Pt), osmium (Os), renium (Re), and the like.

However, in the present disclosure, the specific organic light-emitting material A is not limited to those described above.

The specific organic light-emitting material A may be a fluorescent light-emitting material or a phosphorus light-emitting material, but in order to achieve excellent color purity, a fluorescent light-emitting material is preferable.

Among the above, from the viewpoint of excellent thermal stability and photostability, a compound having a fused aryl ring or a derivative thereof is preferable.

In addition, from the viewpoint of solubility and diversity of a molecular structure, the specific organic light-emitting material A is preferably a compound having a coordinate bond. From the viewpoint that a half-width is small and highly efficient light emission is possible, a boron-containing compound such as a boron fluoride complex is also preferable.

For example, as the specific organic light-emitting material A, coumarin compounds such as coumarin 6, coumarin 7, and coumarin 153; cyanine compounds such as indocyanine green; fluorescein compounds such as fluorescein, fluorescein isothiocyanate, and carboxyfluorescein diacetate; phthalocyanine compounds such as phthalocyanine green; perylene compounds such as diisobutyl-4,10-dicyanoperylene-3,9-dicarboxylate; pyrromethene compounds; stillbene compounds; oxazine compounds; naphthalimide compounds; pyrazine compounds; benzoimidazole compounds; benzoxazole compounds; benzothiazole compounds; imidazole pyridine compounds; azole compounds; compounds having a fused aryl ring, such as anthracene; derivatives thereof, aromatic amine compounds; organic metal complex compounds; or the like is preferable. However, the specific organic light-emitting material A is not particularly limited thereto.

Among the above-described compounds, a pyrromethene compound is a particularly suitable compound because it provides an excellent emission quantum yield and has good durability. As the pyrromethene compound, for example, a compound represented by General Formula (1) described below is preferable because it exhibits light emission with excellent color purity.

### Compound Represented by General Formula 1

The specific organic light-emitting material A is preferably a compound represented by General Formula (1).

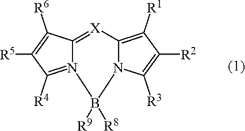

In General Formula (1), X represents C-R⁷ or N. R¹ to R⁹ are independently selected from a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an arylether group, an arylthioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, or a phosphine oxide group, where adjacent groups of R¹ to R⁹ may form a fused ring.

In all the above-described groups, the hydrogen atom may be a deuterium atom.

This also applies to the compound described below or a partial structure thereof. In addition, in the following description, for example, a substituted or unsubstituted aryl group having 6 to 40 carbon atoms is an aryl group in which the number of carbon atoms including the substituent substituted on the aryl group is 6 to 40 carbon atoms. The same applies to other substituents which specify the number of carbon atoms.

In addition, in all the above-described groups, as a substituent in a case of being substituted, an alkyl group, a cycloalkyl group, a heterocyclic group, an alkenyl group, a cycloalkenyl group, an alkynyl group, a hydroxyl group, a thiol group, an alkoxy group, an alkylthio group, an arylether group, an arylthioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, or a phosphine oxide group is preferable, and furthermore, a specific substituent that is preferred in the description of each substituent is preferable. In addition, these substituents may be further substituted with the above-described substituent.

The term “unsubstituted” in the case of “substituted or unsubstituted” means that a hydrogen atom or a deuterium atom has been substituted. The same applies to a case where the compound described below or a partial structure thereof is “substituted or unsubstituted”.

In all the above-described groups, the alkyl group represents, for example, a saturated aliphatic hydrocarbon group such as a methyl group, an ethyl group, an n-propyl group, an isopropyl group, an n-butyl group, an sec-butyl group, and a tert-butyl group, and the alkyl group may or may not have a substituent. The additional substituent in a case of being substituted is not particularly limited, and examples thereof an alkyl group, halogen, an aryl group, and a heteroaryl group. This point is also common to the following description. In addition, the number of carbon atoms in the alkyl group is not particularly limited, but from the viewpoint of availability and cost, it is preferably in a range of 1 or more and 20 or less, and more preferably in a range of 1 or more and 8 or less.

The cycloalkyl group represents, for example, a saturated alicyclic hydrocarbon group such as a cyclopropyl group, a cyclohexyl group, a norbornyl group, and an adamantyl group, and the cycloalkyl group may or may not have a substituent. The number of carbon atoms in an alkyl group moiety is not particularly limited, but is preferably in a range of 3 or more and 20 or less.

The heterocyclic group represents, for example, an aliphatic ring having a non-carbon atom in the ring, such as a pyran ring, a piperidine ring, and a cyclic amide, and the heterocyclic group may or may not have a substituent.

The number of carbon atoms in the heterocyclic group is not particularly limited, but is preferably in a range of 2 or more and 20 or less.

The alkenyl group represents, for example, an unsaturated aliphatic hydrocarbon group containing a double bond, such as a vinyl group, an allyl group, and a butadienyl group, and the alkenyl group may or may not have a substituent. The number of carbon atoms in the alkenyl group is not particularly limited, but is preferably in a range of 2 or more and 20 or less.

The cycloalkenyl group represents, for example, an unsaturated alicyclic hydrocarbon group containing a double bond, such as a cyclopentenyl group, a cyclopentadienyl group, and a cyclohexenyl group, and the cycloalkenyl group may or may not have a substituent.

The alkynyl group represents, for example, an unsaturated aliphatic hydrocarbon group containing a triple bond, such as an ethynyl group, and the alkynyl group may or may not have a substituent. The number of carbon atoms in the alkynyl group is not particularly limited, but is preferably in a range of 2 or more and 20 or less.

The alkoxy group represents, for example, a functional group in which an aliphatic hydrocarbon group is bonded through an ether bond, such as a methoxy group, an ethoxy group, and a propoxy group, and the aliphatic hydrocarbon group may or may not have a substituent. The number of carbon atoms in the alkoxy group is not particularly limited, but is preferably in a range of 1 or more and 20 or less.

The alkylthio group is a group in which an oxygen atom of the ether bond of the alkoxy group is replaced with a sulfur atom. A hydrocarbon group of the alkylthio group may or may not have a substituent. The number of carbon atoms in the alkylthio group is not particularly limited, but is preferably in a range of 1 or more and 20 or less.

The arylether group represents, for example, a functional group in which an aromatic hydrocarbon group is bonded through an ether bond, such as a phenoxy group, and the aromatic hydrocarbon group may or may not have a substituent. The number of carbon atoms in the arylether group is not particularly limited, but is preferably in a range of 6 or more and 40 or less.

The arylthioether group is a group in which an oxygen atom of the ether bond of the arylthio group is replaced with a sulfur atom. The aromatic hydrocarbon group in the arylthioether group may or may not have a substituent. The number of carbon atoms in the arylthioether group is not particularly limited, but is preferably in a range of 6 or more and 40 or less.

The aryl group represents, for example, an aromatic hydrocarbon group such as a phenyl group, a biphenyl group, a terphenyl group, a naphthyl group, a fluorenyl group, a benzofluorenyl group, a dibenzofluorenyl group, a phenanthryl group, an anthracenyl group, a benzophenanthryl group, a benzoanthracenyl group, a chrysenyl group, a pyrenyl group, a fluoranthenyl group, a triphenylenyl group, a benzofluoranthenyl group, a dibenzoanthracenyl group, a perylenyl group, and a helicenyl group. Among the above, a phenyl group, a biphenyl group, a terphenyl group, a naphthyl group, a fluorenyl group, a phenanthryl group, an anthracenyl group, a pyrenyl group, a fluoranthenyl group, or a triphenylenyl group is preferable. The aryl group may or may not have a substituent. The number of carbon atoms in the aryl group is not particularly limited, but is preferably in a range of 6 or more and 40 or less and more preferably in a range of 6 or more and 30 or less.

In a case where R¹ to R⁹ represent a substituted or unsubstituted aryl group, as the aryl group, a phenyl group, a biphenyl group, a terphenyl group, a naphthyl group, a fluorenyl group, a phenanthryl group, or an anthracenyl group is preferable, a phenyl group, a biphenyl group, a terphenyl group, or a naphthyl group is more preferable. A phenyl group, a biphenyl group, or a terphenyl group is still more preferable, and a phenyl group is particularly preferable.

In a case where each substituent is further substituted with an aryl group, as the aryl group, a phenyl group, a biphenyl group, a terphenyl group, a naphthyl group, a fluorenyl group, a phenanthryl group, or an anthracenyl group is preferable, a phenyl group, a biphenyl group, a terphenyl group, or a naphthyl group is more preferable. A phenyl group is particularly preferable.

The heteroaryl group represents, for example, a cyclic aromatic group having one or more atoms other than carbon in the ring, such as a pyridyl group, a furanyl group, a thienyl group, a quinolinyl group, an isoquinolinyl group, a pyrazinyl group, a pyrimidyl group, a pyridazinyl group, a triazinyl group, a naphthyridinyl group, a cinnolinyl group, a phthalazinyl group, a quinoxalinyl group, a quinazolinyl group, a benzofuranyl group, a benzothienyl group, an indolyl group, a dibenzofuranyl group, a dibenzothienyl group, a carbazolyl group, a benzocarbazolyl group, a carbolinyl group, an indolocarbazolyl group, a benzofurocarbazolyl group, a benzothienocarbazolyl group, a dihydroindenocarbazolyl group, a benzoquinolinyl group, acridinyl group, a dibenzoacridinyl group, a benzimidazolyl group, an imidazopyridyl group, a benzoxazolyl group, a benzothiazolyl group, and a phenanthrolinyl group.

The naphthyridinyl group represents any of a 1,5-naphthyridinyl group, a 1,6-naphthyridinyl group, a 1,7-naphthyridinyl group, a 1,8-naphthyridinyl group, a 2,6-naphthyridinyl group, or a 2,7-naphthyridinyl group. The heteroaryl group may or may not have a substituent. The number of carbon atoms in the heteroaryl group is not particularly limited, but is preferably in a range of 2 or more and 40 or less and more preferably in a range of 2 or more and 30 or less.

In a case where R¹ to R⁹ represent a substituted or unsubstituted heteroaryl group, as the heteroaryl group, a pyridyl group, a furanyl group, a thienyl group, a quinolinyl group, a pyrimidyl group, a triazinyl group, a benzofuranyl group, a benzothienyl group, an indolyl group, a dibenzofuranyl group, a dibenzothienyl group, a carbazolyl group, a benzimidazolyl group, an imidazopyridyl group, a benzoxazolyl group, a benzothiazolyl group, or a phenanthrolinyl group is preferable, and a pyridyl group, a furanyl group, a thienyl group, or a quinolinyl group is more preferable. A pyridyl group is particularly preferable.

In a case where each substituent is further substituted with a heteroaryl group, as the heteroaryl group, a pyridyl group, a furanyl group, a thienyl group, a quinolinyl group, a pyrimidyl group, a triazinyl group, a benzofuranyl group, a benzothienyl group, an indolyl group, a dibenzofuranyl group, a dibenzothienyl group, a carbazolyl group, a benzimidazolyl group, an imidazopyridyl group, a benzoxazolyl group, a benzothiazolyl group, or a phenanthrolinyl group is preferable, and a pyridyl group, a furanyl group, a thienyl group, or a quinolinyl group is more preferable. A pyridyl group is particularly preferable.

The halogen represents an atom selected from fluorine, chlorine, bromine, or iodine. In addition, the carbonyl group, the carboxyl group, the oxycarbonyl group, and the carbamoyl group may or may not have a substituent. Here, examples of the substituent include an alkyl group, a cycloalkyl group, an aryl group, and a heteroaryl group, and these substituents may be further substituted.

The amino group is a substituted or unsubstituted amino group. Examples of the substituent in a case of being substituted include an aryl group, a heteroaryl group, a linear alkyl group, and a branched alkyl group. As the aryl group and the heteroaryl group, a phenyl group, a naphthyl group, a pyridyl group, or a quinolinyl group is preferable. These substituents may be further substituted. The number of carbon atoms is not particularly limited, but is preferably in a range of 2 or more and 50 or less, more preferably in a range of 6 or more and 40 or less, and particularly preferably in a range of 6 or more and 30 or less.

The silyl group represents, for example, an alkylsilyl group such as a trimethylsilyl group, a triethylsilyl group, a tert-butyldimethylsilyl group, a propyldimethylsilyl group, and a vinyldimethylsilyl group; or an arylsilyl group such as a phenyldimethylsilyl group, a tert-butyldiphenylsilyl group, a triphenylsilyl group, and a trinaphthylsilyl group. A substituent on silicon may be further substituted. The number of carbon atoms in the silyl group is not particularly limited, but is preferably in a range of 1 or more and 30 or less.

The siloxanyl group represents, for example, a silicon compound group through an ether bond, such as a trimethylsiloxanyl group. A substituent on silicon may be further substituted.

In addition, the boryl group is a substituted or unsubstituted boryl group. Examples of the substituent in a case of being substituted include an aryl group, a heteroaryl group, a linear alkyl group, a branched alkyl group, an arylether group, an alkoxy group, and a hydroxyl group. Among the above, an aryl group or an arylether group is preferable. In addition, the phosphine oxide group is a group represented by —P(═O)R¹⁰R¹¹. R¹⁰ and R¹¹ are selected from the same groups as R¹ to R⁹.

The fused ring and the aliphatic ring formed between the adjacent substituents means that any two adjacent substituents (for example, R¹ and R² in General Formula (1)) are bonded to each other to form a conjugated or non-conjugated cyclic skeleton. Examples of a constituent element of such a fused ring and an aliphatic ring include carbon, nitrogen, oxygen, sulfur, phosphorus, and silicon. In addition, the fused ring and the aliphatic ring may be fused with another ring.

Since the compound represented by General Formula (1) exhibits excellent emission quantum yield and has a small half-width of the emission spectrum, it is possible to achieve both efficient color conversion and excellent color purity. Furthermore, in the compound represented by General Formula (1), by introducing an appropriate substituent at an appropriate position, various characteristics and physical properties such as light emission efficiency, color purity, thermal stability, photostability, and dispersibility can be adjusted.

For example, as compared with a case where R¹, R³, R⁴, and R⁶ all represent hydrogen atoms, a case where at least one of R¹, R³, R⁴, or R⁶ represents a group selected from the group including a substituted or unsubstituted alkyl group, a substituted or unsubstituted aryl group, and a substituted or unsubstituted heteroaryl group exhibits more excellent thermal stability and photostability.

In a case where at least one of R¹, R³, R⁴, or R⁶ represents a substituted or unsubstituted alkyl group, as the alkyl group, an alkyl group having 1 to 6 carbon atoms, such as a methyl group, an ethyl group, an n-propyl group, an isopropyl group, an n-butyl group, a sec-butyl group, a tert-butyl group, a pentyl group, and a hexyl group, is preferable.

Further, from the viewpoint of excellent thermal stability, the above-described alkyl group is preferably a methyl group, an ethyl group, an n-propyl group, an isopropyl group, an n-butyl group, an sec-butyl group, or a tert-butyl group. In addition, from the viewpoint of preventing concentration quenching and improving the emission quantum yield, the above-described alkyl group is more preferably a sterically bulky tert-butyl group. In addition, from the viewpoint of ease of synthesis and availability of raw materials, a methyl group is also preferably used as the above-described alkyl group.

In a case where at least one of R¹, R³, R⁴, or R⁶ represents a substituted or unsubstituted aryl group, as the aryl group, a phenyl group, a biphenyl group, a terphenyl group, or a naphthyl group is preferable, a phenyl group or a biphenyl group is more preferable. A phenyl group is particularly preferable.

In a case where at least one of R¹, R³, R⁴, or R⁶ represents a substituted or unsubstituted heteroaryl group, as the heteroaryl group, a pyridyl group, a quinolinyl group, or a thienyl group is preferable, and a pyridyl group or a quinolinyl group is more preferable. A pyridyl group is particularly preferable.

A case where all of R¹, R³, R⁴, and R⁶ each independently represent a substituted or unsubstituted alkyl group is preferable because of its good solubility in a binder resin or a solvent. In this case, from the viewpoint of ease of synthesis and availability of raw materials, the alkyl group is preferably a methyl group.

A case where all of R¹, R³, R⁴, and R⁶ are each independently a substituted or unsubstituted aryl group or a substituted or unsubstituted heteroaryl group is preferable because it exhibits better thermal stability and photostability. In this case, it is more preferable that all of R¹, R³, R⁴, and R⁶ each independently represent a substituted or unsubstituted aryl group.

Although there are a plurality of substituents which improve properties, the substituents which exhibit sufficient performance in all of them are limited. In particular, it is difficult to achieve both high light emission efficiency and high color purity. Therefore, by introducing a plurality of types of substituents into the compound represented by General Formula (1), it is possible to obtain a compound having balanced emission characteristics, color purity, and the like.

In particular, in a case where all of R¹, R³, R⁴, and R⁶ each independently represent a substituted or unsubstituted aryl group, for example, it is preferable to introduce a plurality of types of substituents, such as R¹ ≠ R⁴, R³ ≠ R⁶, R¹ ≠ R³, or R⁴ ≠ R⁶.

Here, “≠” indicates that the groups have different structures. For example, R¹ ≠ R⁴ indicates that R¹ and R⁴ are groups having different structures. By introducing a plurality of types of substituents as described above, an aryl group which affects the color purity and an aryl group which affects the light emission efficiency can be simultaneously introduced, so that fine adjustment is possible.

A case where R¹ ≠ R³ or R⁴ ≠ R⁶ is preferable because the light emission efficiency and the color purity can be improved in a balanced manner. In this case, with respect to the compound represented by General Formula (1), since one or more aryl groups which affect the color purity are introduced to each of pyrrole rings on both side and aryl groups which affect the light emission efficiency are introduced at other positions, both of these properties can be improved. In addition, in the case where R¹ ≠ R³ or R⁴ ≠ R⁶, from the viewpoint of improving both the heat resistance and the color purity, it is more preferable that R¹ = R⁴ and R³ = R⁶.

As the aryl group which affects the color purity, an aryl group substituted with an electron-donating group is preferable. The electron-donating group is an atomic group which donates an electron to the substituted atomic group by an inductive effect or a resonance effect in organic electron theory. Examples of the electron-donating group include groups having a negative value as the substituent constant (σp (para)) of Hammett’s law. The substituent constant of Hammett’s law can be quoted from the 5th edition of the Basics of Chemistry Handbook (page 380 of II).

Specific examples of the electron-donating group include an alkyl group (σp of methyl group: -0.17), an alkoxy group (σp of methoxy group: -0.27), and an amino group (σp of -NH₂: -0.66).

In particular, an alkyl group having 1 to 8 carbon atoms or an alkoxy group having 1 to 8 carbon atoms is preferable, and a methyl group, an ethyl group, a tert-butyl group, or a methoxy group is more preferable. From the viewpoint of dispersibility, a tert-butyl group or a methoxy group is particularly preferable, and in a case where these are used as the above-described electron-donating group, in the compound represented by General Formula (1), quenching due to aggregation of molecules can be prevented.

The substitution position of the substituent is not particularly limited, but since it is necessary to suppress torsion of a bond in order to increase the photostability of the compound represented by General Formula (1), it is preferable that the substituent is bonded at a meta-position or para-position with respect to the bonding position with the pyrromethene skeleton. On the other hand, as the aryl group which mainly affects the light emission efficiency, an aryl group having a bulky substituent such as a tert-butyl group, an adamantyl group, or a methoxy group is preferable.

In a case where R¹, R³, R⁴, and R⁶ each independently represent a substituted or unsubstituted aryl group, it is preferable that R¹, R³, R⁴, and R⁶ each independently represent a substituted or unsubstituted phenyl group. In this case, it is more preferable that R¹, R³, R⁴, and R⁶ are each selected from the following Ar-1 to Ar-6. In this case, examples of a preferred combination of R¹, R³, R⁴, and R⁶ include combinations shown in Tables 1 to 22, but the preferred combination thereof is not limited thereto. The black circle means a bonding portion with the main skeleton.

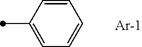

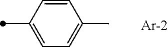

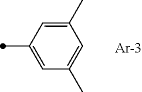

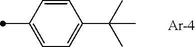

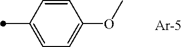

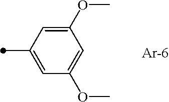

TABLE 1

| | | | |
|---|---|---|---|
| R1 | R3 | R4 | R6 |
| Ar-1 | Ar-1 | Ar-1 | Ar-1 |
| Ar-1 | Ar-1 | Ar-1 | Ar-2 |
| Ar-1 | Ar-1 | Ar-1 | Ar-3 |
| Ar-1 | Ar-1 | Ar-1 | Ar-4 |
| Ar-1 | Ar-1 | Ar-1 | Ar-5 |
| Ar-1 | Ar-1 | Ar-1 | Ar-6 |
| Ar-1 | Ar-1 | Ar-2 | Ar-1 |
| Ar-1 | Ar-1 | Ar-2 | Ar-2 |
| Ar-1 | Ar-1 | Ar-2 | Ar-3 |
| Ar-1 | Ar-1 | Ar-2 | Ar-4 |
| Ar-1 | Ar-1 | Ar-2 | Ar-5 |
| Ar-1 | Ar-1 | Ar-2 | Ar-6 |
| Ar-1 | Ar-1 | Ar-3 | Ar-1 |
| Ar-1 | Ar-1 | Ar-3 | Ar-2 |
| Ar-1 | Ar-1 | Ar-3 | Ar-3 |
| Ar-1 | Ar-1 | Ar-3 | Ar-4 |
| Ar-1 | Ar-1 | Ar-3 | Ar-5 |
| Ar-1 | Ar-1 | Ar-3 | Ar-6 |
| Ar-1 | Ar-1 | Ar-4 | Ar-1 |
| Ar-1 | Ar-1 | Ar-4 | Ar-2 |
| Ar-1 | Ar-1 | Ar-4 | Ar-3 |
| Ar-1 | Ar-1 | Ar-4 | Ar-4 |
| Ar-1 | Ar-1 | Ar-4 | Ar-5 |
| Ar-1 | Ar-1 | Ar-4 | Ar-6 |
| Ar-1 | Ar-1 | Ar-5 | Ar-1 |
| Ar-1 | Ar-1 | Ar-5 | Ar-2 |
| Ar-1 | Ar-1 | Ar-5 | Ar-3 |
| Ar-1 | Ar-1 | Ar-5 | Ar-4 |
| Ar-1 | Ar-1 | Ar-5 | Ar-5 |
| Ar-1 | Ar-1 | Ar-5 | Ar-6 |

TABLE 2

| | | | |
|---|---|---|---|
| R1 | R3 | R4 | R6 |
| Ar-1 | Ar-1 | Ar-6 | Ar-1 |
| Ar-1 | Ar-1 | Ar-6 | Ar-2 |
| Ar-1 | Ar-1 | Ar-6 | Ar-3 |
| Ar-1 | Ar-1 | Ar-6 | Ar-4 |
| Ar-1 | Ar-1 | Ar-6 | Ar-5 |
| Ar-1 | Ar-1 | Ar-6 | Ar-6 |
| Ar-1 | Ar-2 | Ar-1 | Ar-2 |
| Ar-1 | Ar-2 | Ar-1 | Ar-3 |
| Ar-1 | Ar-2 | Ar-1 | Ar-4 |
| Ar-1 | Ar-2 | Ar-1 | Ar-5 |
| Ar-1 | Ar-2 | Ar-1 | Ar-6 |
| Ar-1 | Ar-2 | Ar-2 | Ar-1 |
| Ar-1 | Ar-2 | Ar-2 | Ar-2 |
| Ar-1 | Ar-2 | Ar-2 | Ar-3 |
| Ar-1 | Ar-2 | Ar-2 | Ar-4 |
| Ar-1 | Ar-2 | Ar-2 | Ar-5 |
| Ar-1 | Ar-2 | Ar-2 | Ar-6 |
| Ar-1 | Ar-2 | Ar-3 | Ar-1 |
| Ar-1 | Ar-2 | Ar-3 | Ar-2 |
| Ar-1 | Ar-2 | Ar-3 | Ar-3 |
| Ar-1 | Ar-2 | Ar-3 | Ar-4 |
| Ar-1 | Ar-2 | Ar-3 | Ar-5 |
| Ar-1 | Ar-2 | Ar-3 | Ar-6 |
| Ar-1 | Ar-2 | Ar-4 | Ar-1 |
| Ar-1 | Ar-2 | Ar-4 | Ar-2 |
| Ar-1 | Ar-2 | Ar-4 | Ar-3 |
| Ar-1 | Ar-2 | Ar-4 | Ar-4 |
| Ar-1 | Ar-2 | Ar-4 | Ar-5 |
| Ar-1 | Ar-2 | Ar-4 | Ar-6 |

TABLE 3

| | | | |
|---|---|---|---|
| R1 | R3 | R4 | R6 |
| Ar-1 | Ar-2 | Ar-5 | Ar-1 |
| Ar-1 | Ar-2 | Ar-5 | Ar-2 |
| Ar-1 | Ar-2 | Ar-5 | Ar-3 |
| Ar-1 | Ar-2 | Ar-5 | Ar-4 |
| Ar-1 | Ar-2 | Ar-5 | Ar-5 |
| Ar-1 | Ar-2 | Ar-5 | Ar-6 |
| Ar-1 | Ar-2 | Ar-6 | Ar-1 |
| Ar-1 | Ar-2 | Ar-6 | Ar-2 |
| Ar-1 | Ar-2 | Ar-6 | Ar-3 |
| Ar-1 | Ar-2 | Ar-6 | Ar-4 |
| Ar-1 | Ar-2 | Ar-6 | Ar-5 |
| Ar-4 | Ar-2 | Ar-6 | Ar-6 |
| Ar-1 | Ar-3 | Ar-1 | Ar-2 |
| Ar-1 | Ar-3 | Ar-1 | Ar-3 |
| Ar-1 | Ar-3 | Ar-1 | Ar-4 |
| Ar-1 | Ar-3 | Ar-1 | Ar-5 |
| Ar-1 | Ar-3 | Ar-1 | Ar-6 |
| Ar-1 | Ar-3 | Ar-2 | Ar-2 |
| Ar-1 | Ar-3 | Ar-2 | Ar-3 |
| Ar-1 | Ar-3 | Ar-2 | Ar-4 |
| Ar-1 | Ar-3 | Ar-2 | Ar-5 |
| Ar-1 | Ar-3 | Ar-2 | Ar-6 |
| Ar-1 | Ar-3 | Ar-3 | Ar-1 |
| Ar-1 | Ar-3 | Ar-3 | Ar-2 |
| Ar-1 | Ar-3 | Ar-3 | Ar-3 |
| Ar-1 | Ar-3 | Ar-3 | Ar-4 |
| Ar-1 | Ar-3 | Ar-3 | Ar-5 |
| Ar-1 | Ar-3 | Ar-3 | Ar-6 |
| Ar-1 | Ar-3 | Ar-4 | Ar-1 |
| Ar-1 | Ar-3 | Ar-4 | Ar-2 |
| Ar-1 | Ar-3 | Ar-4 | Ar-3 |

TABLE 4

| | | | |
|---|---|---|---|
| R1 | R3 | R4 | R6 |
| Ar-1 | Ar-3 | Ar-4 | Ar-4 |
| Ar-1 | Ar-3 | Ar-4 | Ar-5 |
| Ar-1 | Ar-3 | Ar-4 | Ar-6 |
| Ar-1 | Ar-3 | Ar-5 | Ar-1 |
| Ar-1 | Ar-3 | Ar-5 | Ar-2 |
| Ar-1 | Ar-3 | Ar-5 | Ar-3 |
| Ar-1 | Ar-3 | Ar-5 | Ar-4 |
| Ar-1 | Ar-3 | Ar-5 | Ar-5 |
| Ar-1 | Ar-3 | Ar-5 | Ar-6 |
| Ar-1 | Ar-3 | Ar-6 | Ar-1 |
| Ar-1 | Ar-3 | Ar-6 | Ar-2 |
| Ar-1 | Ar-3 | Ar-6 | Ar-3 |
| Ar-1 | Ar-3 | Ar-6 | Ar-4 |
| Ar-1 | Ar-3 | Ar-6 | Ar-5 |
| Ar-1 | Ar-3 | Ar-6 | Ar-6 |
| Ar-1 | Ar-4 | Ar-1 | Ar-2 |
| Ar-1 | Ar-4 | Ar-1 | Ar-3 |
| Ar-1 | Ar-4 | Ar-1 | Ar-4 |
| Ar-1 | Ar-4 | Ar-1 | Ar-5 |
| Ar-1 | Ar-4 | Ar-1 | Ar-6 |
| Ar-1 | Ar-4 | Ar-2 | Ar-2 |
| Ar-1 | Ar-4 | Ar-2 | Ar-3 |
| Ar-1 | Ar-4 | Ar-2 | Ar-4 |
| Ar-1 | Ar-4 | Ar-2 | Ar-5 |
| Ar-1 | Ar-1 | Ar-2 | Ar-6 |
| Ar-1 | Ar-4 | Ar-3 | Ar-2 |
| Ar-1 | Ar-4 | Ar-3 | Ar-3 |
| Ar-1 | Ar-4 | Ar-3 | Ar-4 |
| Ar-1 | Ar-4 | Ar-3 | Ar-5 |
| Ar-1 | Ar-4 | Ar-3 | Ar-6 |

TABLE 5

| | | | |
|---|---|---|---|
| R1 | R3 | R4 | R6 |
| Ar-1 | Ar-4 | Ar-4 | Ar-1 |
| Ar-1 | Ar-4 | Ar-4 | Ar-2 |
| Ar-1 | Ar-4 | Ar-4 | Ar-3 |
| Ar-1 | Ar-4 | Ar-4 | Ar-4 |
| Ar-1 | Ar-4 | Ar-4 | Ar-5 |
| Ar-1 | Ar-4 | Ar-4 | Ar-6 |
| Ar-1 | Ar-4 | Ar-5 | Ar-1 |
| Ar-1 | Ar-4 | Ar-5 | Ar-2 |
| Ar-1 | Ar-4 | Ar-5 | Ar-3 |
| Ar-1 | Ar-4 | Ar-5 | Ar-4 |
| Ar-1 | Ar-4 | Ar-5 | Ar-5 |
| Ar-1 | Ar-4 | Ar-5 | Ar-6 |
| Ar-1 | Ar-4 | Ar-6 | Ar-1 |
| Ar-1 | Ar-4 | Ar-6 | Ar-2 |
| Ar-1 | Ar-4 | Ar-6 | Ar-3 |
| Ar-1 | Ar-4 | Ar-6 | Ar-4 |
| Ar-1 | Ar-4 | Ar-6 | Ar-5 |
| Ar-1 | Ar-4 | Ar-6 | Ar-6 |
| Ar-1 | Ar-5 | Ar-1 | Ar-2 |
| Ar-1 | Ar-5 | Ar-1 | Ar-3 |
| Ar-1 | Ar-5 | Ar-1 | Ar-4 |
| Ar-1 | Ar-5 | Ar-1 | Ar-5 |
| Ar-1 | Ar-5 | Ar-1 | Ar-6 |
| Ar-1 | Ar-5 | Ar-2 | Ar-2 |
| Ar-1 | Ar-5 | Ar-2 | Ar-3 |
| Ar-1 | Ar-5 | Ar-2 | Ar-4 |
| Ar-1 | Ar-5 | Ar-2 | Ar-5 |
| Ar-1 | Ar-5 | Ar-2 | Ar-6 |
| Ar-1 | Ar-5 | Ar-3 | Ar-2 |
| Ar-1 | Ar-5 | Ar-3 | Ar-3 |

TABLE 6

| | | | |
|---|---|---|---|
| R1 | R3 | R4 | R6 |
| Ar-1 | Ar-5 | Ar-3 | Ar-4 |
| Ar-1 | Ar-5 | Ar-3 | Ar-5 |
| Ar-1 | Ar-5 | Ar-3 | Ar-6 |
| Ar-1 | Ar-5 | Ar-4 | Ar-2 |
| Ar-1 | Ar-5 | Ar-4 | Ar-3 |
| Ar-1 | Ar-5 | Ar-4 | Ar-4 |
| Ar-1 | Ar-5 | Ar-4 | Ar-5 |
| Ar-1 | Ar-5 | Ar-4 | Ar-6 |
| Ar-1 | Ar-5 | Ar-5 | Ar-1 |
| Ar-1 | Ar-5 | Ar-5 | Ar-2 |
| Ar-1 | Ar-5 | Ar-5 | Ar-3 |
| A1-1 | Ar-5 | Ar-5 | Ar-4 |
| Ar-1 | Ar-5 | Ar-5 | Ar-5 |
| Ar-1 | Ar-5 | Ar-5 | Ar-6 |
| Ar-1 | Ar-5 | Ar-6 | Ar-1 |
| Ar-1 | Ar-5 | Ar-6 | Ar-2 |
| Ar-1 | Ar-5 | Ar-6 | Ar-3 |
| Ar-1 | Ar-5 | Ar-6 | Ar-4 |
| Ar-1 | Ar-5 | Ar-6 | Ar-5 |
| Ar-1 | Ar-5 | Ar-6 | Ar-6 |
| Ar-1 | Ar-6 | Ar-1 | Ar-2 |
| Ar-1 | Ar-6 | Ar-1 | Ar-3 |
| Ar-1 | Ar-6 | Ar-1 | Ar-4 |
| Ar-1 | Ar-6 | Ar-1 | Ar-5 |
| Ar-1 | Ar6 | Ar-1 | Ar-6 |
| Ar-1 | Ar-6 | Ar-2 | Ar-2 |
| Ar-1 | Ar-6 | Ar-2 | Ar-3 |
| Ar-1 | Ar-6 | Ar-2 | Ar-4 |
| Ar-1 | Ar-6 | Ar-2 | Ar-5 |
| Ar-1 | Ar-6 | Ar-2 | Ar-6 |

TABLE 7

| | | | |
|---|---|---|---|
| R1 | R3 | R4 | R6 |
| Ar-1 | Ar-6 | Ar-3 | Ar-2 |
| Ar-1 | Ar-6 | Ar-3 | Ar-3 |
| Ar-1 | Ar-6 | Ar-3 | Ar-4 |
| Ar-1 | Ar-6 | Ar-3 | Ar-5 |
| Ar-1 | Ar-6 | Ar-3 | Ar-6 |
| Ar-1 | Ar-6 | Ar-4 | Ar-2 |
| Ar-1 | Ar-6 | Ar-4 | Ar-3 |
| Ar-1 | Ar-6 | Ar-4 | Ar-4 |
| Ar-1 | Ar-6 | Ar-4 | Ar-5 |
| Ar-1 | Ar-6 | Ar-4 | Ar-6 |
| Ar-1 | Ar-6 | Ar-5 | Ar-2 |
| Ar-1 | Ar-6 | Ar-5 | Ar-3 |
| Ar-1 | Ar-6 | Ar-5 | Ar-4 |
| Ar-1 | Ar-6 | Ar-5 | Ar-5 |
| Ar-1 | Ar-6 | Ar-5 | Ar-6 |
| Ar-1 | Ar-6 | Ar-6 | Ar-1 |
| Ar-1 | Ar-6 | Ar-6 | Ar-2 |
| Ar-1 | Ar-6 | Ar-6 | Ar-3 |
| Ar-1 | Ar-6 | Ar-6 | Ar-4 |
| Ar-1 | Ar-6 | Ar-6 | Ar-5 |
| Ar-1 | Ar-6 | Ar-6 | Ar-6 |
| Ar-2 | Ar-1 | Ar-1 | Ar-2 |
| Ar-2 | Ar-1 | Ar-1 | Ar-3 |
| Ar-2 | Ar-1 | Ar-1 | Ar-4 |
| Ar-2 | Ar-1 | Ar-1 | Ar-5 |
| Ar-2 | Ar-1 | Ar-1 | Ar-6 |
| Ar-2 | Ar-1 | Ar-2 | Ar-2 |
| Ar-2 | Ar-1 | Ar-2 | Ar-3 |
| Ar-2 | Ar-1 | Ar-2 | Ar-4 |
| Ar-2 | Ar-1 | Ar-2 | Ar-5 |

TABLE 8

| | | | |
|---|---|---|---|
| R1 | R3 | R4 | R6 |
| Ar-2 | Ar-1 | Ar-2 | Ar-6 |
| Ar-2 | Ar-1 | Ar-3 | Ar-2 |
| Ar-2 | Ar-1 | Ar-3 | Ar-3 |
| Ar-1 | Ar-1 | Ar-3 | Ar-4 |
| Ar-2 | Ar-1 | Ar-3 | Ar-5 |
| Ar-2 | Ar-1 | Ar-3 | Ar-6 |
| Ar-2 | Ar-1 | Ar-4 | Ar-2 |
| Ar-2 | Ar-1 | Ar-4 | Ar-3 |
| Ar-2 | Ar-1 | Ar-4 | Ar-4 |
| Ar- 2 | Ar-1 | Ar-4 | Ar-5 |
| Ar-2 | Ar-1 | Ar-4 | Ar-6 |
| Ar-2 | Ar-1 | Ar-5 | Ar-2 |
| Ar-2 | Ar-1 | Ar-5 | Ar-3 |
| Ar-2 | Ar-1 | Ar-5 | Ar-4 |
| Ar-2 | Ar-1 | Ar-5 | Ar-5 |
| Ar-2 | Ar-1 | Ar-5 | Ar-6 |
| Ar-2 | Ar-1 | Ar-6 | Ar-2 |
| Ar-2 | Ar-1 | Ar-6 | Ar-3 |
| Ar-2 | Ar-1 | Ar-6 | Ar-4 |
| Ar-2 | Ar-1 | Ar-6 | Ar-5 |
| Ar-2 | Ar-1 | Ar-6 | Ar-6 |
| Ar-2 | Ar-2 | Ar-1 | Ar-3 |
| Ar-2 | Ar-2 | Ar-1 | Ar-4 |
| Ar-2 | Ar-2 | Ar-1 | Ar-5 |
| Ar-2 | Ar-2 | Ar-1 | Ar-6 |
| Ar-2 | Ar-2 | Ar-2 | Ar-2 |
| Ar-2 | Ar-2 | Ar-2 | Ar-3 |
| Ar-2 | Ar-2 | Ar-2 | Ar-4 |
| Ar-2 | Ar-2 | Ar-2 | Ar-5 |
| Ar-2 | Ar-2 | Ar-2 | Ar-6 |

TABLE 9

| | | | |
|---|---|---|---|
| R1 | R3 | R4 | R6 |
| Ar-2 | Ar-2 | Ar-3 | Ar-2 |
| Ar-2 | Ar-2 | Ar-3 | Ar-3 |
| Ar-2 | Ar-2 | Ar-3 | Ar-4 |
| Ar-2 | Ar-2 | Ar-3 | Ar-5 |
| Ar-2 | Ar-2 | Ar-3 | Ar-6 |
| Ar-2 | Ar-2 | Ar-4 | Ar-2 |
| Ar-2 | Ar-2 | Ar-4 | Ar-3 |
| Ar-2 | Ar-2 | Ar-4 | Ar-4 |
| Ar-2 | Ar-2 | Ar-4 | Ar-5 |
| Ar-2 | Ar-2 | Ar-4 | Ar-6 |
| Ar-2 | Ar-2 | Ar-5 | Ar-2 |
| Ar-2 | Ar-2 | Ar-5 | Ar-3 |
| Ar-2 | Ar-2 | Ar-5 | Ar-4 |
| Ar-2 | Ar-2 | Ar-5 | Ar-5 |
| Ar-2 | Ar-2 | Ar-5 | Ar-6 |
| Ar-2 | Ar-2 | Ar-6 | Ar-2 |
| Ar-2 | Ar-2 | Ar-6 | Ar-3 |
| Ar-2 | Ar-2 | Ar-6 | Ar-4 |
| Ar-2 | Ar-2 | Ar-6 | Ar-5 |
| Ar-2 | Ar-2 | Ar-6 | Ar-6 |
| Ar-2 | Ar-3 | Ar-1 | Ar-3 |
| Ar-2 | Ar-3 | Ar-1 | Ar-4 |
| Ar-2 | Ar-3 | Ar-1 | Ar-5 |
| Ar-2 | Ar-3 | Ar-1 | Ar-6 |
| Ar-2 | Ar-3 | Ar-2 | Ar-3 |
| Ar-2 | Ar-3 | Ar-2 | Ar-4 |
| Ar-2 | Ar-3 | Ar-2 | Ar-5 |
| Ar-2 | Ar-3 | Ar-2 | Ar-6 |
| Ar-2 | Ar-3 | Ar-3 | Ar-2 |
| Ar-2 | Ar-3 | Ar-3 | Ar-3 |

TABLE 10

| | | | |
|---|---|---|---|
| R1 | R3 | R4 | R6 |
| Ar-2 | Ar-3 | Ar-3 | Ar-4 |
| Ar-2 | Ar-3 | Ar-3 | Ar-5 |
| Ar-2 | Ar-3 | Ar-3 | Ar-6 |
| Ar-2 | Ar-3 | Ar-4 | Ar-2 |
| Ar-2 | Ar-3 | Ar-4 | Ar-3 |
| Ar-2 | Ar-3 | Ar-4 | Ar-4 |
| Ar-2 | Ar-3 | Ar-4 | Ar-5 |
| Ar-2 | Ar-3 | Ar-4 | Ar-6 |
| Ar-2 | Ar-3 | Ar-5 | Ar-2 |
| Ar-2 | Ar-3 | Ar-5 | Ar-3 |
| Ar-2 | Ar-3 | Ar-5 | Ar-4 |
| Ar-2 | Ar-3 | Ar-5 | Ar-5 |
| Ar-2 | Ar-3 | Ar-5 | Ar-6 |
| Ar-2 | Ar-3 | Ar-6 | Ar-2 |
| Ar-2 | Ar-3 | Ar-6 | Ar-3 |
| Ar-2 | Ar-3 | Ar-6 | Ar-4 |
| Ar-2 | Ar-3 | Ar-6 | Ar-5 |
| Ar-2 | Ar-3 | Ar-6 | Ar-6 |
| Ar-2 | Ar-4 | Ar-1 | Ar-3 |
| Ar-2 | Ar-4 | Ar-1 | Ar-4 |
| Ar-2 | Ar-4 | Ar-1 | Ar-5 |
| Ar-2 | Ar-4 | Ar-1 | Ar-6 |
| Ar-2 | Ar-4 | Ar-2 | Ar-3 |
| Ar-2 | Ar-4 | Ar-2 | Ar-4 |
| Ar-2 | Ar-4 | Ar2 | Ar-5 |
| Ar-2 | Ar-4 | Ar-2 | Ar-6 |
| Ar-2 | Ar-4 | Ar-3 | Ar-3 |
| Ar-2 | Ar-4 | Ar-3 | Ar-4 |
| Ar-2 | Ar-4 | Ar-3 | Ar-5 |
| Ar-2 | Ar-4 | Ar-3 | Ar-6 |

TABLE 11

| | | | |
|---|---|---|---|
| R1 | R3 | R4 | R6 |
| Ar-2 | Ar-4 | Ar-4 | Ar-2 |
| Ar-2 | Ar-4 | Ar-4 | Ar-3 |
| Ar-2 | Ar-4 | Ar-4 | Ar-4 |
| Ar-2 | Ar-4 | Ar-4 | Ar-5 |
| Ar-2 | Ar-4 | Ar-4 | Ar-6 |
| Ar-2 | Ar-4 | Ar-5 | Ar-2 |
| Ar-2 | Ar-4 | Ar-5 | Ar-3 |
| Ar-2 | Ar-4 | Ar-5 | Ar-4 |
| Ar-2 | Ar-4 | Ar-5 | Ar-5 |
| Ar-2 | Ar-4 | Ar-5 | Ar-6 |
| Ar-2 | Ar-4 | Ar-6 | Ar-2 |
| Ar-2 | Ar-4 | Ar-6 | Ar-3 |
| Ar-2 | Ar-4 | Ar-6 | Ar-4 |
| Ar-2 | Ar-4 | Ar-6 | Ar-5 |
| Ar-2 | Ar-4 | Ar-6 | Ar-6 |
| Ar-2 | Ar-5 | Ar-1 | Ar-3 |
| Ar-2 | Ar-5 | Ar-1 | Ar-4 |
| Ar-2 | Ar-5 | Ar-1 | Ar-5 |
| Ar-2 | Ar-5 | Ar-1 | Ar-6 |
| Ar-2 | Ar5 | Ar-2 | Ar-3 |
| Ar-2 | Ar-5 | Ar-2 | Ar-4 |
| Ar-2 | Ar-5 | Ar-2 | Ar-5 |
| Ar-2 | Ar-5 | Ar-2 | Ar-6 |
| Ar-2 | Ar-5 | Ar-3 | Ar-3 |
| Ar-2 | Ar-5 | Ar-3 | Ar-4 |
| Ar-2 | Ar-5 | Ar-3 | Ar-5 |
| Ar-2 | Ar-5 | Ar-3 | Ar-6 |
| Ar-2 | Ar-5 | Ar-4 | Ar-3 |
| Ar-2 | Ar-5 | Ar-4 | Ar-4 |
| Ar-2 | Ar-5 | Ar-4 | Ar-5 |
| Ar-2 | Ar-5 | Ar-4 | Ar-6 |

TABLE 12

| | | | |
|---|---|---|---|
| R1 | R3 | R4 | R6 |
| Ar-2 | Ar-5 | Ar-5 | Ar-2 |
| Ar-2 | Ar-5 | Ar-5 | Ar-3 |
| Ar-2 | Ar-5 | Ar-5 | Ar-4 |
| Ar-2 | Ar-5 | Ar-5 | Ar-5 |
| Ar-2 | Ar-5 | Ar-5 | Ar-6 |
| Ar-2 | Ar-5 | Ar-6 | Ar-2 |
| Ar-2 | Ar-5 | Ar-6 | Ar-3 |
| Ar-2 | Ar-5 | Ar-6 | Ar-4 |
| Ar-2 | Ar-5 | Ar-6 | Ar-5 |
| Ar-2 | Ar-5 | Ar-6 | Ar-6 |
| Ar-2 | Ar-6 | Ar-1 | Ar-3 |
| Ar-2 | Ar-6 | Ar-1 | Ar-4 |
| Ar-2 | Ar-6 | Ar-1 | Ar-5 |
| Ar-2 | Ar-6 | Ar-1 | Ar-6 |
| Ar-2 | Ar-6 | Ar-2 | Ar-3 |
| Ar-2 | Ar-6 | Ar-2 | Ar-4 |
| Ar-2 | Ar-6 | Ar-2 | Ar-5 |
| Ar-2 | Ar-6 | Ar-2 | Ar-6 |
| Ar-2 | Ar-6 | Ar-3 | Ar-3 |
| Ar-2 | Ar--6 | Ar-3 | Ar-4 |
| Ar-2 | Ar-6 | Ar-3 | Ar-5 |
| Ar-2 | Ar-6 | Ar-3 | Ar-6 |
| Ar-2 | Ar-6 | Ar-4 | Ar-3 |
| Ar-2 | Ar-6 | Ar-4 | Ar-4 |
| Ar-2 | Ar-6 | Ar-4 | Ar-5 |
| Ar-2 | Ar-6 | Ar-4 | Ar-6 |
| Ar-2 | Ar-6 | Ar-5 | Ar-3 |
| Ar-2 | Ar-6 | Ar-5 | Ar-4 |
| Ar-2 | Ar-6 | Ar-5 | Ar-5 |
| Ar-2 | Ar-6 | Ar-5 | Ar-6 |

TABLE 13

| | | | |
|---|---|---|---|
| R1 | R3 | R4 | R6 |
| Ar-2 | Ar-6 | Ar-6 | Ar-2 |
| Ar-2 | Ar-6 | Ar-6 | Ar-3 |
| Ar-2 | Ar-6 | Ar-6 | Ar-4 |
| Ar-2 | Ar-6 | Ar-6 | Ar-5 |
| Ar-2 | Ar-6 | Ar-6 | Ar-6 |
| Ar-3 | Ar-1 | Ar-1 | Ar-3 |
| Ar-3 | Ar-1 | Ar-1 | Ar-4 |
| Ar-3 | Ar-1 | Ar-1 | Ar-5 |
| Ar-3 | Ar-1 | Ar-1 | Ar-6 |
| Ar-3 | Ar-1 | Ar-2 | Ar-3 |
| Ar-3 | Ar-1 | Ar-2 | Ar-4 |
| Ar-3 | Ar-1 | Ar-2 | Ar-5 |
| Ar-3 | Ar-1 | Ar-2 | Ar-6 |
| Ar-3 | Ar-1 | Ar-3 | Ar-3 |
| Ar-3 | Ar-1 | Ar-3 | Ar-4 |
| Ar-3 | Ar-1 | Ar-3 | Ar-5 |
| Ar-3 | Ar-1 | Ar-3 | Ar-6 |
| Ar-3 | Ar-1 | Ar-4 | Ar-3 |
| Ar-3 | Ar-1 | Ar-4 | Ar-4 |
| Ar-3 | Ar-1 | Ar-4 | Ar-5 |
| Ar-3 | Ar-1 | Ar-4 | Ar-6 |
| Ar-3 | Ar-1 | Ar-5 | Ar-3 |
| Ar-3 | Ar-1 | Ar-5 | Ar-4 |
| Ar-3 | Ar-1 | Ar-5 | Ar-5 |
| Ar-3 | Ar-1 | Ar-5 | Ar-6 |
| Ar-3 | Ar-1 | Ar-6 | Ar-3 |
| Ar-3 | Ar-1 | Ar-6 | Ar-4 |
| Ar-3 | Ar-1 | Ar-6 | Ar-5 |
| Ar-3 | Ar-1 | Ar-6 | Ar-6 |
| Ar-3 | Ar-2 | Ar-1 | Ar-4 |
| Ar-3 | Ar-2 | Ar-1 | Ar-5 |

TABLE 14

| | | | |
|---|---|---|---|
| R1 | R3 | R4 | R6 |
| Ar-3 | Ar-2 | Ar-1 | Ar-6 |
| Ar-3 | Ar-2 | Ar-2 | Ar-3 |
| Ar-3 | Ar-2 | Ar-2 | Ar-4 |
| Ar-3 | Ar-2 | Ar-2 | Ar-5 |
| Ar-3 | Ar-2 | Ar-2 | Ar-6 |
| Ar-3 | Ar-2 | Ar-3 | Ar-3 |
| Ar-3 | Ar-2 | Ar-3 | Ar-4 |
| Ar-3 | Ar-2 | Ar-3 | Ar-5 |
| Ar-3 | Ar-2 | Ar-3 | Ar-6 |
| Ar-3 | Ar-2 | Ar-4 | Ar-3 |
| Ar-3 | Ar-2 | Ar-4 | Ar-4 |
| Ar-3 | Ar-2 | Ar-4 | Ar-5 |
| Ar-3 | Ar-2 | Ar-4 | Ar-6 |
| Ar-3 | Ar-2 | Ar-5 | Ar-3 |
| Ar-3 | Ar-2 | Ar-5 | Ar-4 |
| Ar-3 | Ar-2 | Ar-5 | Ar-5 |
| Ar-3 | Ar-2 | Ar-5 | Ar-6 |
| Ar-3 | Ar-2 | Ar-6 | Ar-3 |
| Ar-3 | Ar-2 | Ar-6 | Ar-4 |
| Ar-3 | Ar-2 | Ar-6 | Ar-5 |
| At-3 | Ar-2 | Ar-6 | Ar-6 |
| Ar-3 | Ar-3 | Ar-1 | Ar-4 |
| Ar-3 | Ar-3 | Ar-1 | Ar-5 |
| Ar-3 | Ar-3 | Ar-1 | Ar-6 |
| Ar-3 | Ar-3 | Ar-2 | Ar-4 |
| Ar-3 | Ar-3 | Ar-2 | Ar-5 |
| Ar-3 | Ar-3 | Ar-2 | Ar-6 |
| Ar-3 | Ar-3 | Ar-3 | Ar-3 |
| Ar-3 | Ar-3 | Ar-3 | Ar-4 |
| Ar-3 | Ar-3 | Ar-3 | Ar-5 |

TABLE 15

| | | | |
|---|---|---|---|
| R1 | R3 | R4 | R6 |
| Ar-3 | Ar-3 | Ar-3 | Ar-6 |
| Ar-3 | Ar-3 | Ar-4 | Ar-3 |
| Ar-3 | Ar-3 | Ar-4 | Ar-4 |
| Ar-3 | Ar-3 | Ar-4 | Ar-5 |
| Ar-3 | Ar-3 | Ar-4 | Ar-6 |
| Ar-3 | Ar-3 | Ar-5 | Ar-3 |
| Ar-3 | Ar-3 | Ar-5 | Ar-4 |
| Ar-3 | Ar-3 | Ar-5 | Ar-5 |
| Ar-3 | Ar-3 | Ar-5 | Ar-6 |
| Ar3 | Ar-3 | Ar-6 | Ar-3 |
| Ar-3 | Ar-3 | Ar-6 | Ar-4 |
| Ar-3 | Ar-3 | Ar-6 | Ar-5 |
| Ar-3 | Ar-3 | Ar-6 | Ar-6 |
| Ar-3 | Ar-4 | Ar-1 | Ar-4 |
| Ar-3 | Ar-4 | Ar-1 | Ar-5 |
| Ar-3 | Ar-4 | Ar-1 | Ar-6 |
| Ar-3 | Ar-4 | Ar-2 | Ar-4 |
| Ar-3 | Ar-4 | Ar-2 | Ar-5 |
| Ar-3 | Ar-4 | Ar-2 | Ar-6 |
| Ar-3 | Ar-4 | Ar-3 | Ar-4 |
| Ar-3 | Ar-4 | Ar-3 | Ar-5 |
| Ar-3 | Ar-4 | Ar-3 | Ar-6 |
| Ar-3 | Ar-4 | Ar-4 | Ar-3 |
| Ar-3 | Ar-4 | Ar-4 | Ar-4 |
| Ar-3 | Ar-4 | Ar-4 | Ar-5 |
| Ar-3 | Ar-4 | Ar-4 | Ar-6 |
| Ar-3 | Ar-4 | Ar-5 | Ar-3 |
| Ar-3 | Ar-4 | Ar-5 | Ar-4 |
| Ar-3 | Ar-4 | Ar-5 | Ar-5 |
| Ar-3 | Ar-4 | Ar-5 | Ar-6 |

TABLE 16

| | | | |
|---|---|---|---|
| R1 | R3 | R4 | R6 |
| Ar-3 | Ar-4 | Ar-6 | Ar-3 |
| Ar-3 | Ar-4 | Ar-6 | Ar-4 |
| Ar-3 | Ar-4 | Ar-6 | Ar-5 |
| Ar-3 | Ar-4 | Ar-6 | Ar-6 |
| Ar-3 | Ar-5 | Ar-1 | Ar-4 |
| Ar-3 | Ar-5 | Ar-1 | Ar-5 |
| Ar-3 | Ar-5 | Ar-1 | Ar-6 |
| Ar-3 | Ar-5 | Ar-2 | Ar-4 |
| Ar-3 | Ar-5 | Ar-2 | Ar-5 |
| Ar-3 | Ar-5 | Ar-2 | Ar-6 |
| Ar-3 | Ar-5 | Ar-3 | Ar-4 |
| Ar-3 | Ar-5 | Ar-3 | Ar-5 |
| Ar-3 | Ar-5 | Ar-3 | Ar-6 |
| Ar-3 | Ar-5 | Ar-4 | Ar-4 |
| Ar-3 | Ar-5 | Ar-4 | Ar-5 |
| Ar-3 | Ar-5 | Ar-4 | Ar-6 |
| Ar-3 | Ar-5 | Ar-5 | Ar-3 |
| Ar-3 | Ar-5 | Ar-5 | Ar-4 |
| Ar-3 | Ar-5 | Ar-5 | Ar-5 |
| Ar-3 | Ar-5 | Ar-5 | Ar-6 |
| Ar-3 | Ar-5 | Ar-6 | Ar-3 |
| Ar-3 | Ar-5 | Ar-6 | Ar-4 |
| Ar-3 | Ar-5 | Ar-6 | Ar-5 |
| Ar-3 | Ar-5 | Ar-6 | Ar-6 |
| Ar-3 | Ar-6 | Ar-1 | Ar-4 |
| Ar-3 | Ar-6 | Ar-1 | Ar-5 |
| Ar-3 | Ar-6 | Ar-1 | Ar-6 |
| Ar-3 | Ar-6 | Ar-2 | Ar-4 |
| Ar-3 | Ar-6 | Ar-2 | Ar-5 |
| Ar-5 | Ar-6 | Ar-2 | Ar-6 |

TABLE 17

| | | | |
|---|---|---|---|
| R1 | R3 | R4 | R6 |
| Ar-3 | Ar-6 | Ar-3 | Ar-4 |
| Ar-3 | Ar-6 | Ar-3 | Ar-5 |
| Ar-3 | Ar-6 | Ar-3 | Ar-6 |
| Ar-3 | Ar-6 | Ar-4 | Ar-4 |
| Ar-3 | Ar-6 | Ar-4 | Ar-5 |
| Ar-3 | Ar-6 | Ar-4 | Ar-6 |
| Ar-3 | Ar-6 | Ar-5 | Ar-4 |
| Ar-3 | Ar-6 | Ar-5 | Ar-5 |
| Ar-3 | Ar-6 | Ar-5 | Ar-6 |
| Ar-3 | Ar-6 | Ar-6 | Ar-3 |
| Ar-3 | Ar-6 | Ar-6 | Ar-4 |
| Ar-3 | Ar-6 | Ar-6 | Ar-5 |
| Ar-3 | Ar-6 | Ar-6 | Ar-6 |
| Ar-4 | Ar-1 | Ar-1 | Ar-4 |
| Ar-4 | Ar-1 | Ar-1 | Ar-5 |
| Ar-4 | Ar-1 | Ar-1 | Ar-6 |
| Ar-4 | Ar-1 | Ar-2 | Ar-4 |
| Ar-4 | Ar-1 | Ar-2 | Ar-5 |
| Ar-4 | Ar-1 | Ar-2 | Ar-6 |
| Ar-4 | Ar-1 | Ar-3 | Ar-4 |
| Ar-4 | Ar-1 | Ar-3 | Ar-5 |
| Ar-4 | Ar-1 | Ar-3 | Ar-6 |
| Ar-4 | Ar-1 | Ar-4 | Ar-4 |
| Ar-4 | Ar-1 | Ar-4 | Ar-5 |
| Ar-4 | Ar-1 | Ar-4 | Ar-6 |
| Ar-4 | Ar-1 | Ar-5 | Ar-4 |
| Ar-4 | Ar-1 | Ar-5 | Ar-5 |
| Ar-4 | Ar-1 | Ar-5 | Ar-6 |
| Ar-4 | Ar-1 | Ar-6 | Ar-4 |
| Ar-4 | Ar-1 | Ar-6 | Ar-5 |
| Ar-4 | Ar-1 | Ar-6 | Ar-6 |

TABLE 18

| | | | |
|---|---|---|---|
| R1 | R3 | R4 | R6 |
| Ar-4 | Ar-2 | Ar-1 | Ar-5 |
| Ar-4 | Ar-2 | Ar-1 | Ar-6 |
| Ar-4 | Ar-2 | Ar-2 | Ar-4 |
| Ar-4 | Ar-2 | Ar-2 | Ar-5 |
| Ar-4 | Ar-2 | Ar-2 | Ar-6 |
| Ar-4 | Ar-2 | Ar-3 | Ar-4 |
| Ar-4 | Ar-2 | Ar-3 | Ar-5 |
| Ar-4 | Ar-2 | Ar-3 | Ar-6 |
| Ar-4 | Ar-2 | Ar-4 | Ar-4 |
| Ar-4 | Ar-2 | Ar-4 | Ar-5 |
| Ar-4 | Ar-2 | Ar-4 | Ar-6 |
| Ar-4 | Ar-2 | Ar-5 | Ar-4 |
| Ar-4 | Ar-2 | Ar-5 | Ar-5 |
| Ar-4 | Ar-2 | Ar-5 | Ar-6 |
| Ar-4 | Ar-2 | Ar-6 | Ar-4 |
| Ar-4 | Ar-2 | Ar-6 | Ar-5 |
| Ar-4 | Ar-2 | Ar-6 | Ar-6 |
| Ar-4 | Ar-3 | Ar-1 | Ar-5 |
| Ar-4 | Ar-3 | Ar-1 | Ar-6 |
| Ar-4 | Ar-3 | Ar-2 | Ar-5 |
| Ar-4 | Ar-3 | Ar-2 | Ar-6 |
| Ar-4 | Ar-3 | Ar-3 | Ar-4 |
| Ar-4 | Ar-3 | Ar-3 | Ar-5 |
| Ar-4 | Ar-3 | Ar-3 | Ar-6 |
| Ar-4 | Ar-3 | Ar-4 | Ar-4 |
| Ar-4 | Ar-3 | Ar-4 | Ar-5 |
| Ar-4 | Ar-3 | Ar-4 | Ar-6 |
| Ar-4 | Ar-3 | Ar-5 | Ar-4 |
| Ar-4 | Ar-3 | Ar-5 | Ar-5 |
| Ar-4 | Ar-3 | Ar-5 | Ar-6 |

TABLE 19

| | | | |
|---|---|---|---|
| R1 | R3 | R4 | R6 |
| Ar-4 | Ar-3 | Ar-6 | Ar-4 |
| Ar-4 | Ar-3 | Ar-6 | Ar-5 |
| Ar-4 | Ar-3 | Ar-6 | Ar-6 |
| Ar-4 | Ar-4 | Ar-1 | Ar-5 |
| Ar-4 | Ar-4 | Ar-1 | Ar-6 |
| Ar-4 | Ar-4 | Ar-2 | Ar-5 |
| Ar-4 | Ar-4 | Ar-2 | Ar6 |
| Ar-4 | Ar-4 | Ar-3 | Ar5 |
| Ar-4 | Ar4 | Ar-3 | Ar-6 |
| Ar-4 | Ar-4 | Ar-4 | Ar-4 |
| Ar-4 | Ar-4 | Ar-4 | Ar-5 |
| Ar-4 | Ar-4 | Ar-4 | Ar-6 |
| Ar-4 | Ar-4 | Ar-5 | Ar-4 |
| Ar-4 | Ar-4 | Ar-5 | Ar-5 |
| Ar-4 | Ar-4 | Ar-5 | Ar-6 |
| Ar-4 | Ar-4 | Ar-6 | Ar-4 |
| Ar-4 | Ar-4 | Ar-6 | Ar-5 |
| Ar-4 | Ar-4 | Ar-6 | Ar-6 |
| Ar-4 | Ar-5 | Ar-1 | Ar-5 |
| Ar-4 | Ar-5 | Ar-1 | Ar-6 |
| Ar-4 | Ar-5 | Ar-2 | Ar-5 |
| Ar-4 | Ar-5 | Ar-2 | Ar-6 |
| Ar-4 | Ar-5 | Ar-3 | Ar-5 |
| Ar-4 | Ar-5 | Ar-3 | Ar-6 |
| Ar-4 | Ar-5 | Ar-4 | Ar-5 |
| Ar-4 | Ar-5 | Ar-4 | Ar-6 |
| Ar-4 | Ar-5 | Ar-5 | Ar-4 |
| Ar-4 | Ar-5 | Ar-5 | Ar-5 |
| Ar-4 | Ar-5 | Ar-5 | Ar-6 |
| Ar-4 | Ar-5 | Ar-6 | Ar-4 |
| Ar-4 | Ar-5 | Ar-6 | Ar-5 |

TABLE 20

| | | | |
|---|---|---|---|
| R1 | R3 | R4 | R6 |
| Ar-4 | Ar-5 | Ar-6 | Ar-6 |
| Ar-4 | Ar-6 | Ar-1 | Ar-5 |
| Ar-4 | Ar-6 | Ar-1 | Ar-6 |
| Ar-4 | Ar-6 | Ar-2 | Ar-5 |
| Ar-4 | Ar-6 | Ar-2 | Ar-6 |
| Ar-4 | Ar-6 | Ar-3 | Ar-5 |
| Ar-4 | Ar-6 | Ar-3 | Ar-6 |
| Ar-4 | Ar-6 | Ar-4 | Ar-5 |
| Ar-4 | Ar-6 | Ar-4 | Ar-6 |
| Ar-4 | Ar-6 | Ar-5 | Ar-5 |
| Ar-4 | Ar-6 | Ar-5 | Ar-6 |
| Ar-4 | Ar-6 | Ar-6 | Ar-4 |
| Ar-4 | Ar-6 | Ar-6 | Ar-5 |
| Ar-4 | Ar-6 | Ar-6 | Ar-6 |
| Ar-5 | Ar-1 | Ar-1 | Ar-5 |
| Ar-5 | Ar-1 | Ar-1 | Ar-6 |
| Ar-5 | Ar-1 | Ar-2 | Ar-5 |
| Ar-5 | Ar-1 | Ar-2 | Ar-6 |
| Ar-5 | Ar-1 | Ar-3 | Ar-5 |
| Ar-5 | Ar-1 | Ar-3 | Ar-6 |
| Ar-5 | Ar-1 | Ar-4 | Ar-5 |
| Ar-5 | Ar-1 | Ar-4 | Ar-6 |
| Ar-5 | Ar-1 | Ar-5 | Ar-5 |
| Ar-5 | Ar-1 | Ar-5 | Ar-6 |
| Ar-5 | Ar-1 | Ar-6 | Ar-5 |
| Ar-5 | Ar-1 | Ar-6 | Ar-6 |
| Ar-5 | Ar-2 | Ar-1 | Ar-6 |
| Ar-5 | Ar-2 | Ar-2 | Ar-5 |
| Ar-5 | Ar-2 | Ar-2 | Ar-6 |
| Ar-5 | Ar-2 | Ar-3 | Ar-5 |
| Ar-5 | Ar-2 | Ar-3 | Ar-6 |

TABLE 21

| | | | |
|---|---|---|---|
| R1 | R3 | R4 | R6 |
| Ar-5 | Ar-2 | Ar-4 | Ar-5 |
| Ar-5 | Ar-2 | Ar-4 | Ar-6 |
| Ar-5 | Ar-2 | Ar-5 | Ar-5 |
| Ar-5 | Ar-2 | Ar-5 | Ar-6 |
| Ar-5 | Ar-2 | Ar-6 | Ar-5 |
| Ar-5 | Ar-2 | Ar-6 | Ar-6 |
| Ar-5 | Ar-3 | Ar-1 | Ar-6 |
| Ar-5 | Ar-3 | Ar-2 | Ar-6 |
| Ar-5 | Ar-3 | Ar-3 | Ar-5 |
| Ar-5 | Ar-3 | Ar-3 | Ar-6 |
| Ar-5 | Ar-3 | Ar-4 | Ar-5 |
| Ar-5 | Ar-3 | Ar-4 | Ar-6 |
| Ar-5 | Ar-3 | Ar-5 | Ar-5 |
| Ar-5 | Ar-3 | Ar-5 | Ar-6 |
| Ar-5 | Ar-3 | Ar-6 | Ar-5 |
| Ar-5 | Ar-3 | Ar-6 | Ar-6 |
| Ar-5 | Ar-4 | Ar-1 | Ar-6 |
| Ar-5 | Ar-4 | Ar-2 | Ar-6 |
| Ar-5 | Ar-4 | Ar-3 | Ar-6 |
| Ar-5 | Ar-4 | Ar-4 | Ar-5 |
| Ar-5 | Ar-4 | Ar-4 | Ar-6 |
| Ar-5 | Ar-4 | Ar-5 | Ar5 |
| Ar-5 | Ar-4 | Ar-5 | Ar-6 |
| Ar-5 | Ar-4 | Ar-6 | Ar-5 |
| Ar-5 | Ar-4 | Ar-6 | Ar-6 |
| Ar-5 | Ar-5 | Ar-1 | Ar-6 |
| Ar-5 | Ar-5 | Ar-2 | Ar-6 |
| Ar-5 | Ar-5 | Ar-3 | Ar-6 |
| Ar-5 | Ar-5 | Ar-4 | Ar-6 |
| Ar-5 | Ar-5 | Ar-5 | Ar-5 |

TABLE 22

| | | | |
|---|---|---|---|
| R1 | R3 | R4 | R6 |
| Ar-5 | Ar-5 | Ar-6 | Ar-5 |
| Ar-5 | Ar-5 | Ar-6 | Ar-6 |
| Ar-5 | Ar-6 | Ar-1 | Ar-6 |
| Ar-5 | Ar-6 | Ar-2 | Ar-6 |
| Ar-5 | Ar-6 | Ar-3 | Ar-6 |
| Ar-5 | Ar-6 | Ar-4 | Ar-6 |
| Ar-5 | Ar-6 | Ar-5 | Ar-6 |
| Ar-5 | Ar-6 | Ar-6 | Ar-5 |
| Ar-5 | Ar-6 | Ar-6 | Ar-6 |
| Ar-6 | Ar-1 | Ar-1 | Ar-6 |
| Ar-6 | Ar-1 | Ar-2 | Ar-6 |
| Ar-6 | Ar-1 | Ar-3 | Ar-6 |
| Ar-6 | Ar-1 | Ar-4 | Ar-6 |
| Ar-6 | Ar-1 | Ar-5 | Ar-6 |
| Ar-6 | Ar-1 | Ar-6 | Ar-6 |
| Ar-6 | Ar-2 | Ar-2 | Ar-6 |
| Ar-6 | Ar-2 | Ar-3 | Ar-6 |
| Ar-6 | Ar-2 | Ar-4 | Ar-6 |
| Ar-6 | Ar-2 | Ar-5 | Ar-6 |
| Ar-6 | Ar-2 | Ar-6 | Ar-6 |
| Ar-6 | Ar-3 | Ar-3 | Ar-6 |
| Ar-6 | Ar-3 | Ar-4 | Ar-6 |
| Ar-6 | Ar-3 | Ar-5 | Ar-6 |
| Ar-6 | Ar-3 | Ar-5 | Ar-6 |
| Ar-6 | Ar-4 | Ar-4 | Ar-6 |
| Ar-6 | Ar-4 | Ar-5 | Ar-6 |
| Ar-6 | Ar-4 | Ar-6 | Ar-6 |
| Ar-6 | Ar-5 | Ar-5 | Ar-6 |
| Ar-6 | Ar-5 | Ar-6 | Ar-6 |
| Ar-6 | Ar-6 | Ar-6 | Ar-6 |

It is preferable that R² and R⁵ are any one of a hydrogen atom, an alkyl group, a carbonyl group, an oxycarbonyl group, or an aryl group. Among these, from the viewpoint of thermal stability, a hydrogen atom or an alkyl group is preferable, and from the viewpoint that it is easy to obtain a narrow half-width in the emission spectrum, a hydrogen atom is more preferable.

It is preferable that R⁸ and R⁹ are an alkyl group, an aryl group, a heteroaryl group, fluorine, a fluorine-containing alkyl group, a fluorine-containing heteroaryl group, or a fluorine-containing aryl group. In particular, since it is stable to the excitation light and a more excellent emission quantum yield is obtained, it is more preferable that R⁸ and R⁹ represent fluorine or a fluorine-containing aryl group. Furthermore, from the viewpoint of ease of synthesis, it is still more preferable that R⁸ and R⁹ are fluorine.

The fluorine-containing aryl group is an aryl group containing fluorine, and examples thereof include a fluorophenyl group, a trifluoromethylphenyl group, and a pentafluorophenyl group. The fluorine-containing heteroaryl group is a heteroaryl group containing fluorine, and examples thereof include a fluoropyridyl group, a trifluoromethylpyridyl group, and a trifluoropyridyl group. The fluorine-containing alkyl group is an alkyl group containing fluorine, and examples thereof include a trifluoromethyl group and a pentafluoroethyl group.

In General Formula (1), from the viewpoint of photostability, it is preferable that X is C-R⁷. In a case where X is C-R⁷, the substituent R⁷ has a great influence on durability of the compound represented by General Formula (1), that is, decrease in light emission intensity of the compound over time. Specifically, in a case where R⁷ is a hydrogen atom, since reactivity of this portion is high, moisture or oxygen in the air easily reacts with the portion. This may cause decomposition of the compound represented by General Formula (1). In addition, in a case where R⁷ is a substituent having a high degree of freedom of molecular chain movement, such as an alkyl group, the reactivity is lowered, but the compounds aggregate with each other in the color conversion film over time, and as a result, concentration quenching may cause a decrease in light emission intensity. Therefore, it is preferable that R⁷ is a group which is rigid, has a small degree of freedom of movement, and is unlikely to cause aggregation, and specifically, it is preferable either a substituted or unsubstituted aryl group or a substituted or unsubstituted heteroaryl group.

From the viewpoint of providing more excellent emission quantum yield, less thermal decomposition, and photostability, it is preferable that X is C-R⁷ and R⁷ is a substituted or unsubstituted aryl group. As the aryl group, from the viewpoint of not impairing a light emission wavelength, a phenyl group, a biphenyl group, a terphenyl group, a naphthyl group, a fluorenyl group, a phenanthryl group, or an anthracenyl group is preferable.

Further, in a case where the torsion is excessively large, in order to increase the photostability of the compound represented by General Formula (1), since the photostability decreases due to increased reactivity to the excitation light, it is preferable to moderately suppress torsion of the carbon-carbon bond between R⁷ and the pyrromethene skeleton.

From the above-described viewpoint, R⁷ is preferably a substituted or unsubstituted phenyl group, a substituted or unsubstituted biphenyl group, a substituted or unsubstituted terphenyl group, or a substituted or unsubstituted naphthyl group, and more preferably represents a substituted or unsubstituted phenyl group, a substituted or unsubstituted biphenyl group, or a substituted or unsubstituted terphenyl group. R⁷ is particularly preferably a substituted or unsubstituted phenyl group.

In addition, R⁷ preferably represents an appropriately bulky substituent. Since R⁷ has a certain degree of bulkiness, the aggregation of molecules can be prevented, and as a result, the light emission efficiency and durability of the compound represented by General Formula (1) are further improved.

More preferred examples of the bulky substituent include a structure of R⁷ represented by General Formula (2).

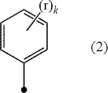

In General Formula (2), r is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an arylether group, an arylthioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, and a phosphine oxide group. k is an integer of 1 to 3. In a case where k is 2 or more, r’s may be the same or different from each other.

From the viewpoint of emission quantum yield, r preferably represents a substituted or unsubstituted aryl group. Among the above-described aryl groups, particularly preferred examples of the aryl group include a phenyl group or a naphthyl group. In a case where r represents an aryl group, k in General Formula (2) is preferably 1 or 2, and from the viewpoint of further preventing aggregation of molecules, more preferably 2. Further, in a case where k is 2 or more, it is preferable that at least one of r is substituted with an alkyl group. From the viewpoint of thermal stability, particularly preferred examples of the alkyl group include a methyl group, an ethyl group, and a tert-butyl group.

From the viewpoint of control of fluorescence wavelength and absorption wavelength, and compatibility with the solvent, r is preferably a substituted or unsubstituted alkyl group, a substituted or unsubstituted alkoxy group, or halogen, and more preferably a methyl group, an ethyl group, a tert-butyl group, or a methoxy group. From the viewpoint of dispersibility, a tert-butyl group or a methoxy group is particularly preferable. The fact that r represents a tert-butyl group or a methoxy group is also effective from the viewpoint of preventing quenching due to the aggregation of molecules.

In addition, as another aspect of the compound represented by General Formula (1), it is preferable that at least one of R¹ to R⁷ represents an electron-attracting group.

In particular, it is preferable that (1) at least one of R¹ to R⁶ represents an electron-attracting group, (2) R⁷ represents an electron-attracting group, or (3) at least one of R¹ to R⁶ is an electron-attracting group and R⁷ represents an electron-attracting group.

By introducing the electron-attracting group into the pyrromethene skeleton of the above-described compound, an electron density of the pyrromethene skeleton can be significantly reduced. Accordingly, the stability of the above-described compound with respect to oxygen is further improved, and as a result, the durability of the above-described compound can be further improved.

The electron-attracting group is also called as an electron-accepting group, and is an atomic group which attracts an electron from the substituted atomic group by an inductive effect or a resonance effect in organic electron theory. Examples of the electron-attracting group include groups having a positive value as the substituent constant (σp (para)) of Hammett’s law. The substituent constant of Hammett’s law can be quoted from the 5th edition of the Basics of Chemistry Handbook (page 380 of II). In some cases, the phenyl group also takes a positive value as described above, but in the present disclosure, the electron-attracting group does not include the phenyl group.

Examples of the electron-attracting group include -F (σp: +0.06), -Cl (σp: +0.23), -Br (σp: +0.23), -I (σp: +0.18), -CO₂R¹² (σp: +0.45 in a case where R¹² is an ethyl group), -CONH₂ (σp: +0.38), -COR¹² (σp: +0.49 in a case where R¹² is a methyl group), -CF₃ (σp: +0.50), -SO₂R¹² (σp: +0.69 in a case where R¹² is a methyl group), and -NO₂ (σp: +0.81).

R¹²′s each independently represent a hydrogen atom, a substituted or unsubstituted aromatic hydrocarbon group having 6 to 30 ring-forming carbon atoms, a substituted or unsubstituted heterocyclic group having 5 to 30 ring-forming carbon atoms, a substituted or unsubstituted alkyl group having 1 to 30 carbon atoms, or a substituted or unsubstituted cycloalkyl group having 1 to 30 carbon atoms. Specific examples of each of these groups include the same examples as described above.

From the viewpoint of decomposability, preferred examples of the electron-attracting group include fluorine, a fluorine-containing aryl group, a fluorine-containing heteroaryl group, a fluorine-containing alkyl group, a substituted or unsubstituted acyl group, a substituted or unsubstituted ester group, a substituted or unsubstituted amide group, a substituted or unsubstituted sulfonyl group, and a cyano group.

More preferred examples of the electron-attracting group include a fluorine-containing alkyl group, a fluorine-containing aryl group, a substituted or unsubstituted acyl group, a substituted or unsubstituted ester group, and a cyano group.

According to the electron-attracting group described above, the concentration quenching can be prevented and the emission quantum yield can be improved. The electron-attracting group is particularly preferably a substituted or unsubstituted ester group.

Preferred examples of the compound represented by General Formula (1), which can be suitably used as the specific organic light-emitting material A, include a case where all of R¹, R³, R⁴, and R⁶ each independently represent a substituted or unsubstituted alkyl group WO, X represents C-R⁷, and R⁷ represents the group represented by General Formula (2). In this case, it is particularly preferable that R⁷ represents the group represented by General Formula (2), in which r is a substituted or unsubstituted phenyl group.

Examples of the compound represented by General Formula (1) are shown below, but the compound is not limited thereto.

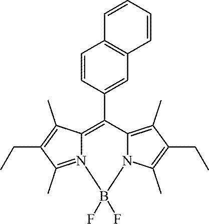

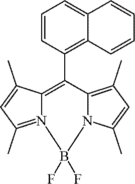

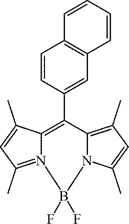

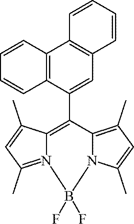

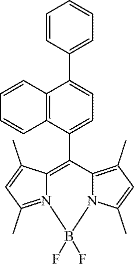

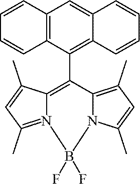

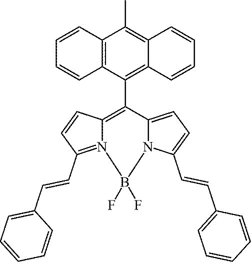

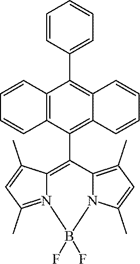

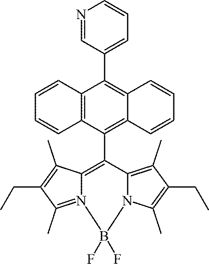

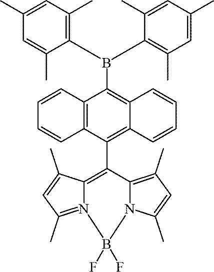

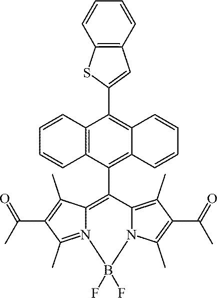

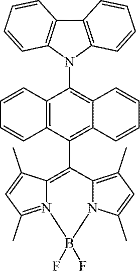

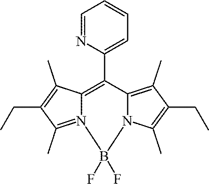

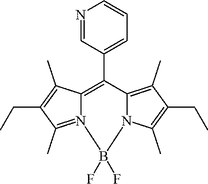

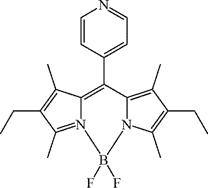

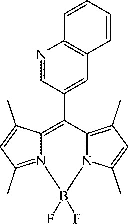

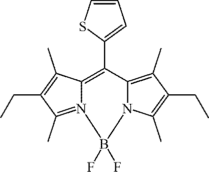

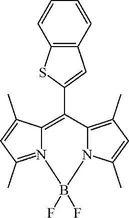

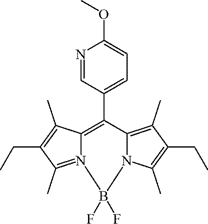

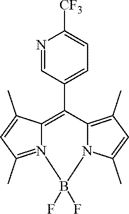

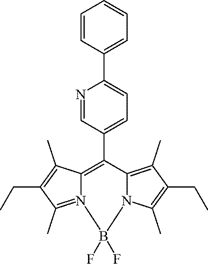

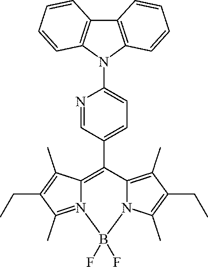

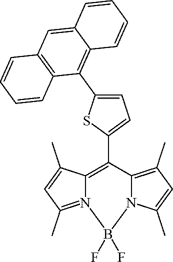

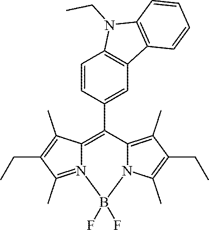

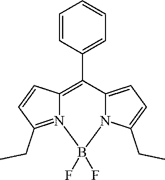

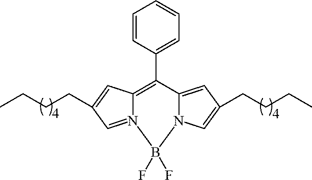

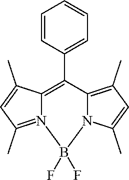

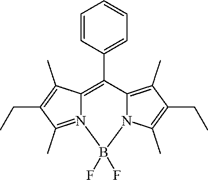

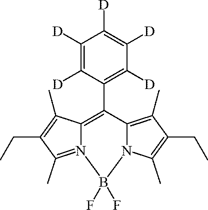

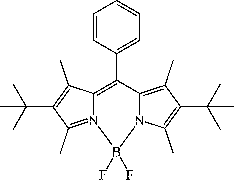

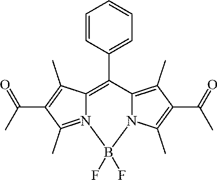

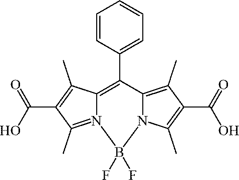

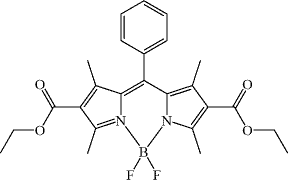

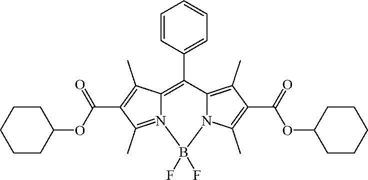

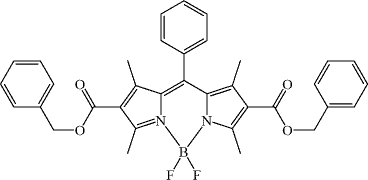

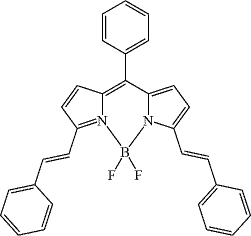

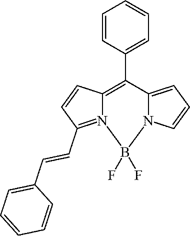

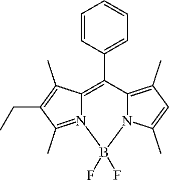

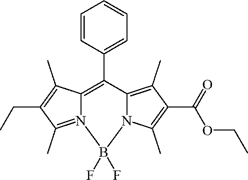

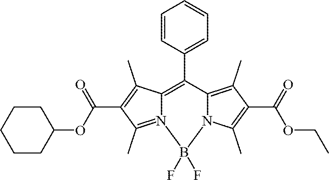

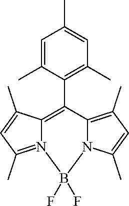

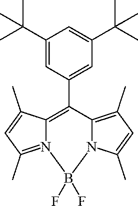

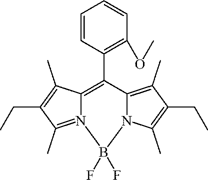

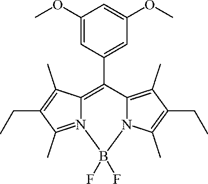

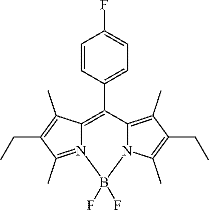

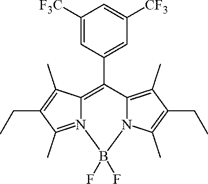

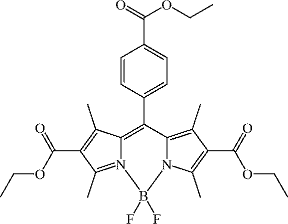

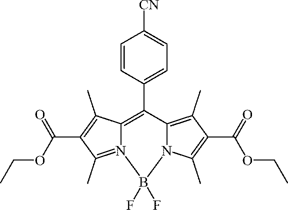

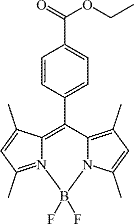

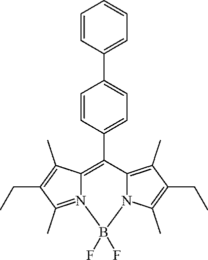

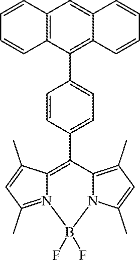

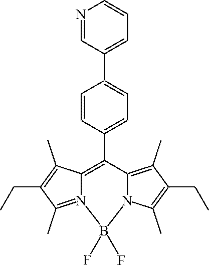

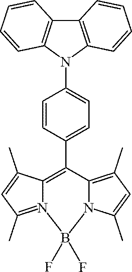

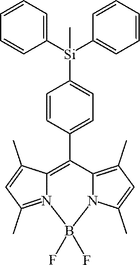

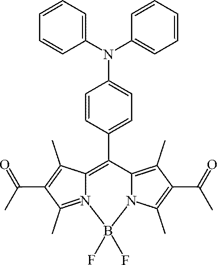

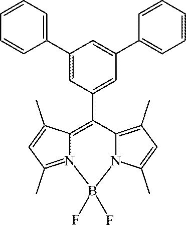

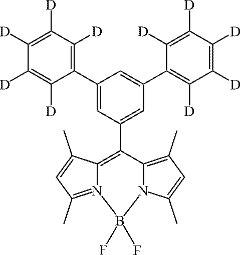

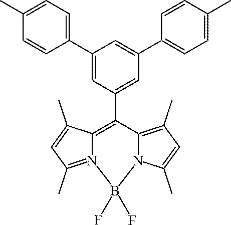

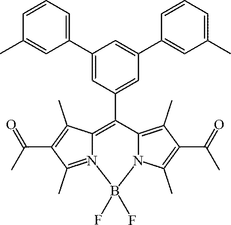

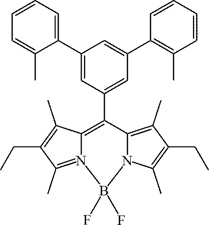

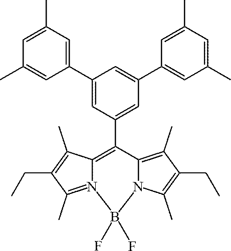

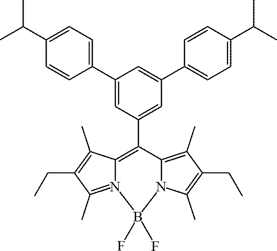

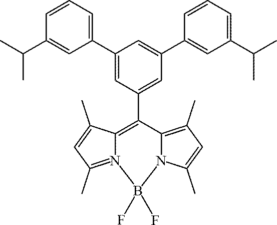

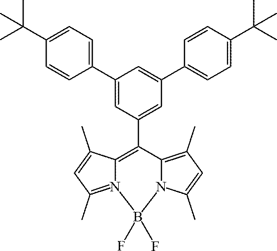

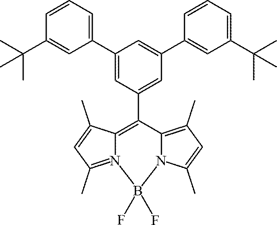

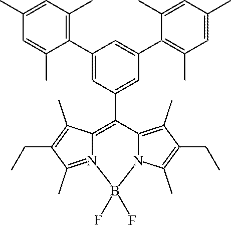

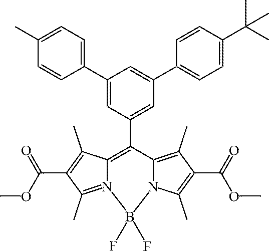

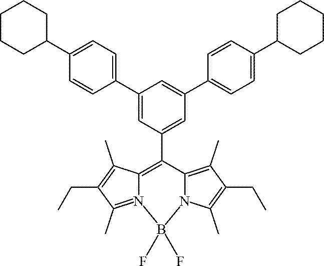

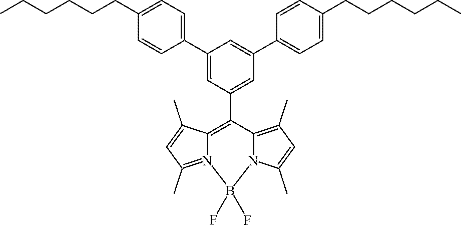

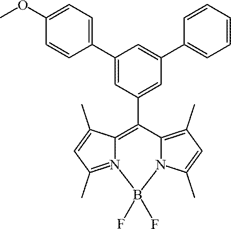

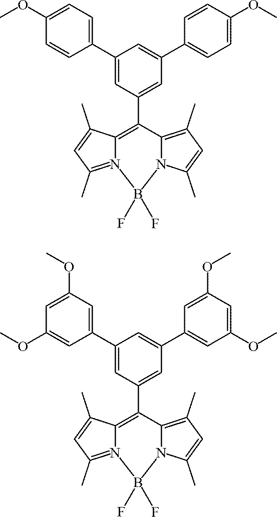

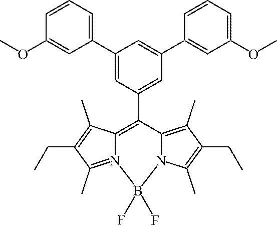

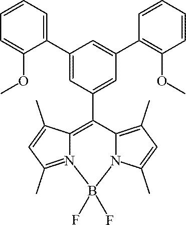

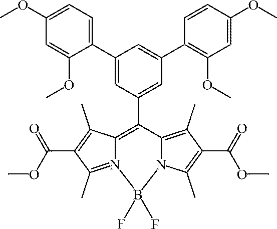

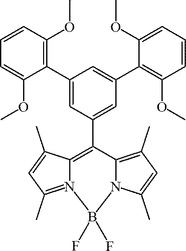

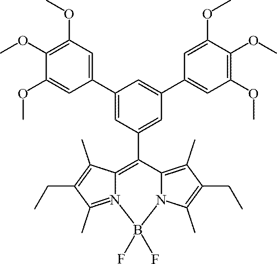

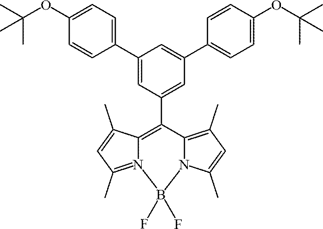

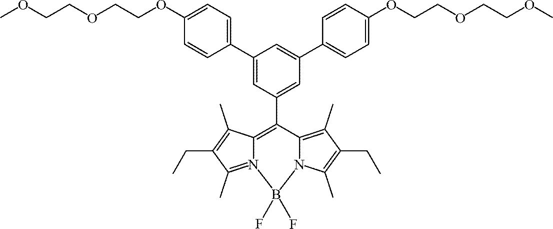

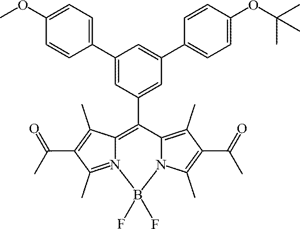

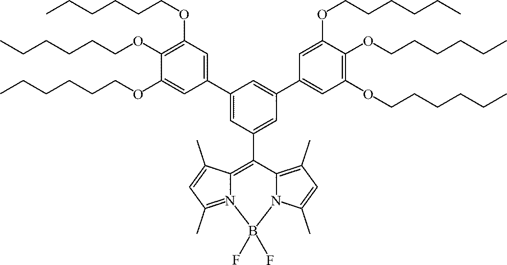

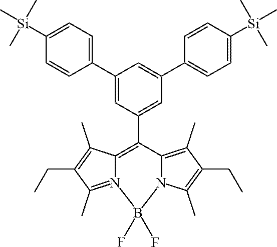

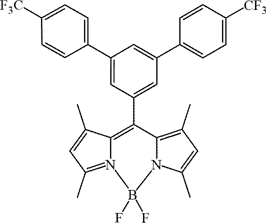

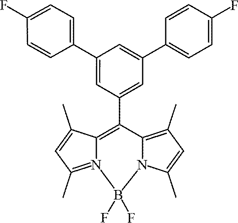

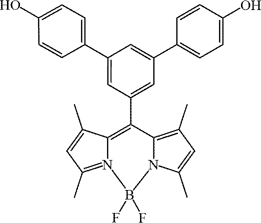

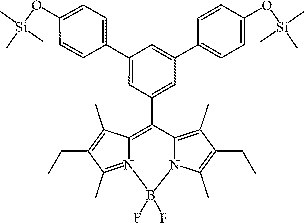

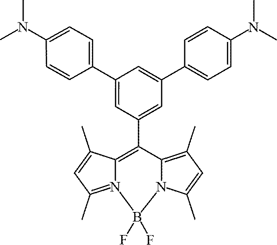

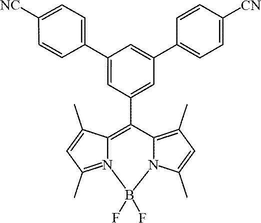

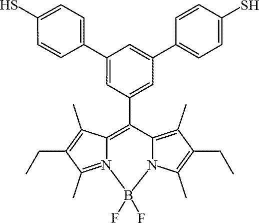

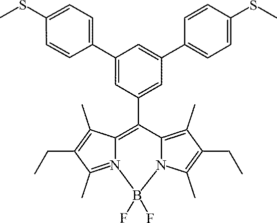

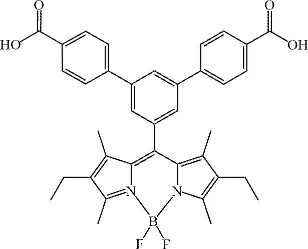

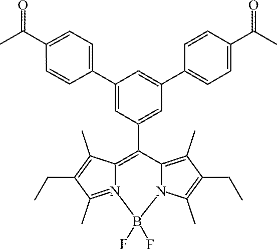

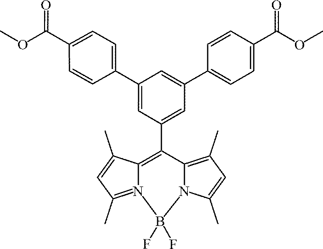

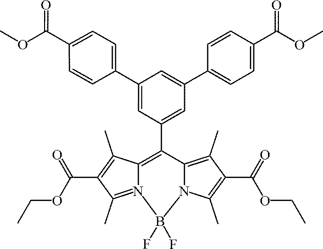

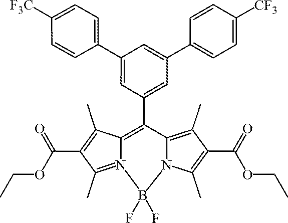

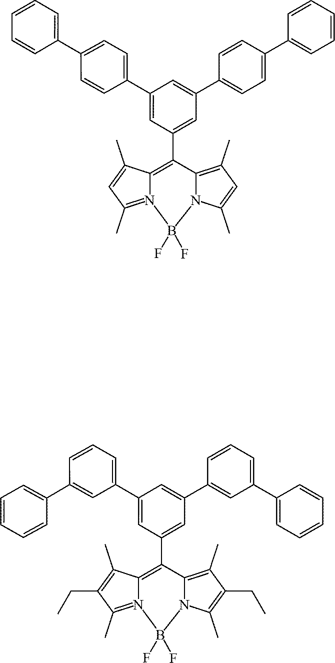

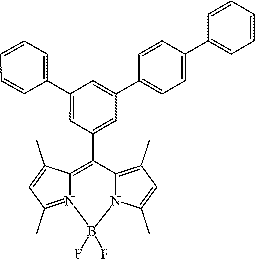

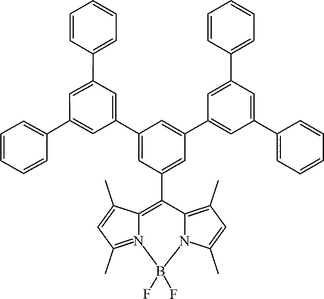

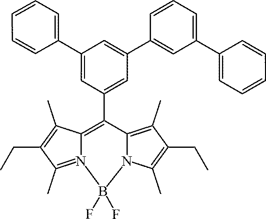

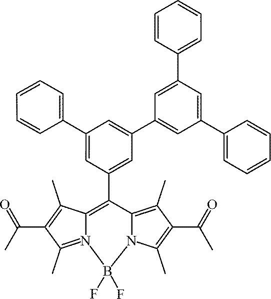

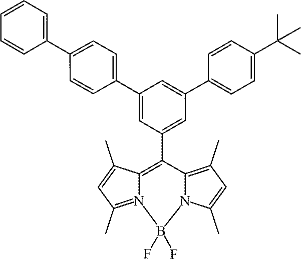

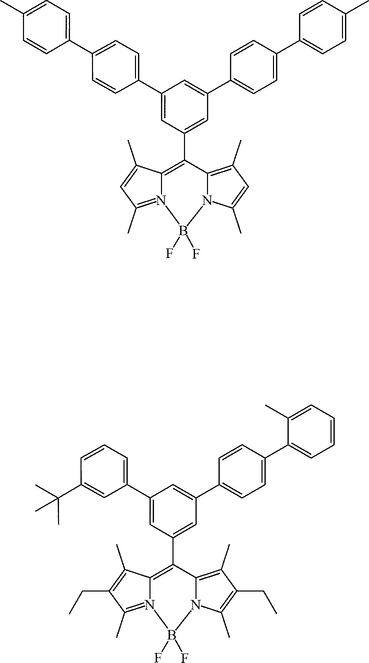

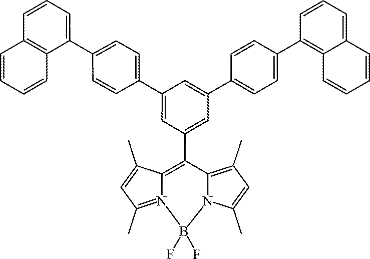

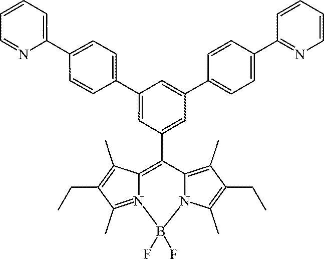

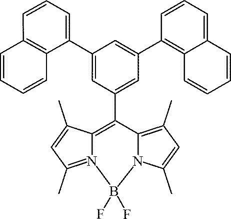

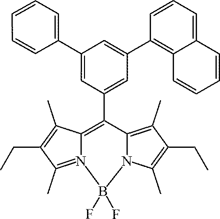

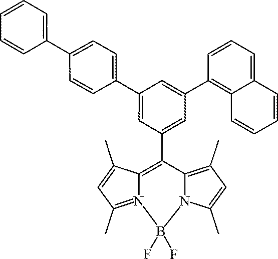

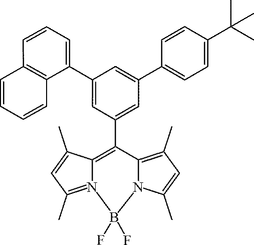

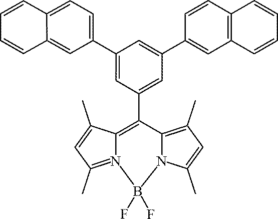

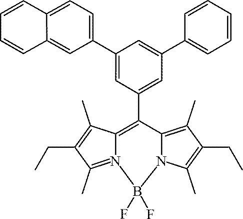

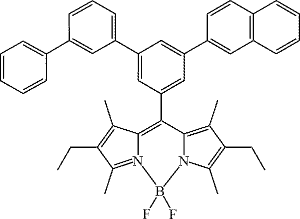

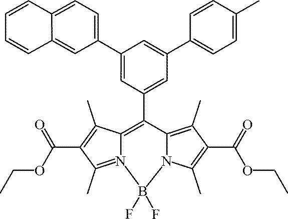

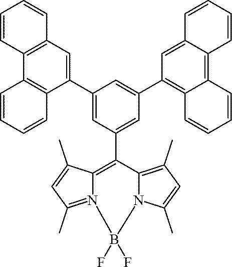

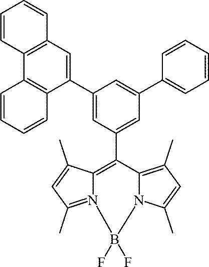

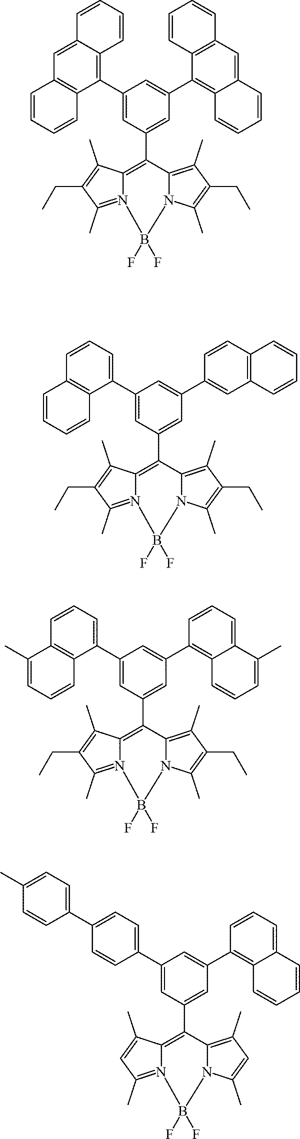

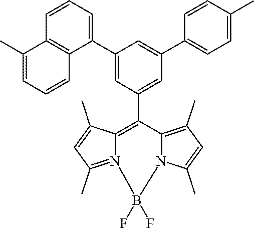

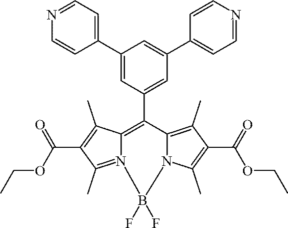

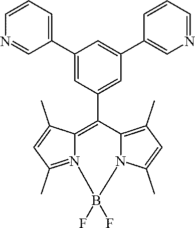

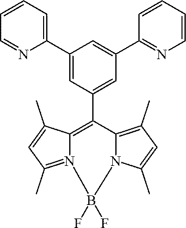

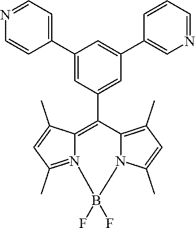

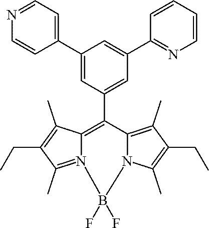

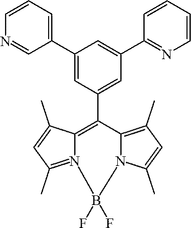

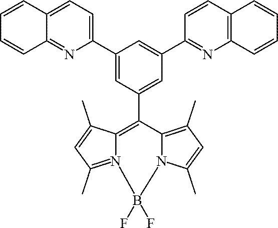

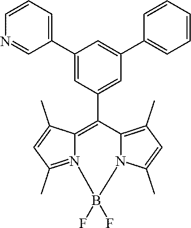

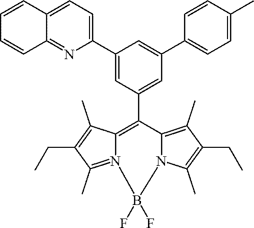

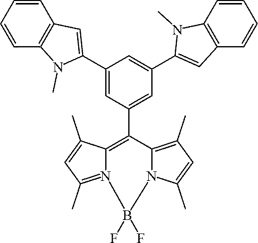

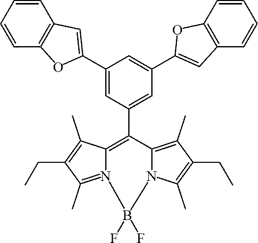

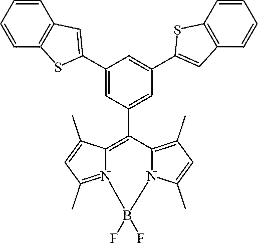

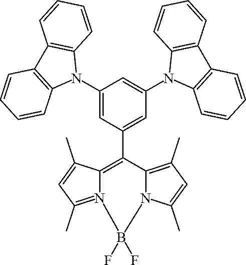

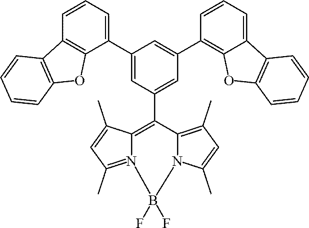

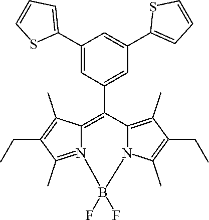

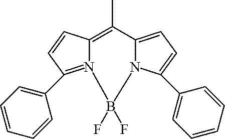

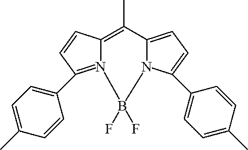

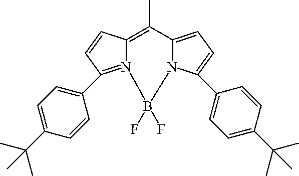

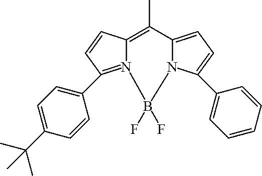

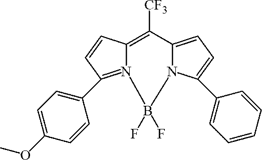

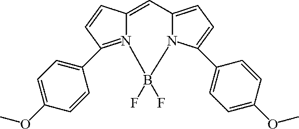

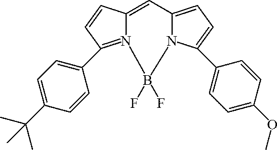

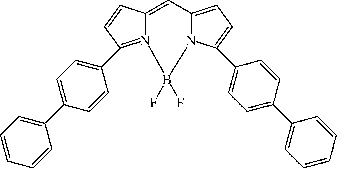

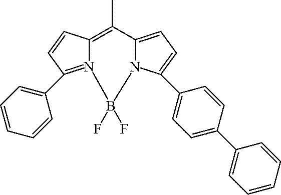

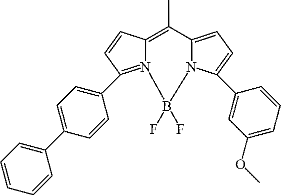

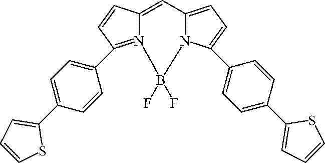

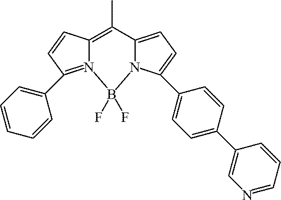

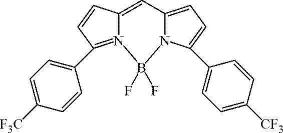

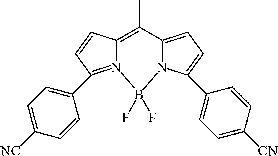

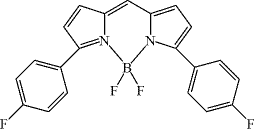

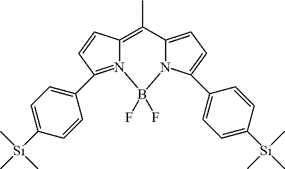

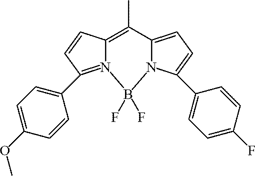

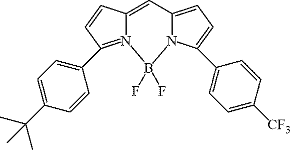

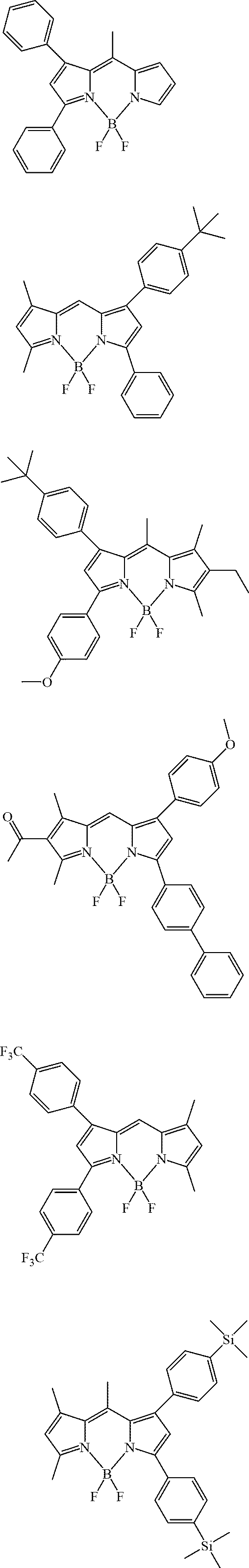

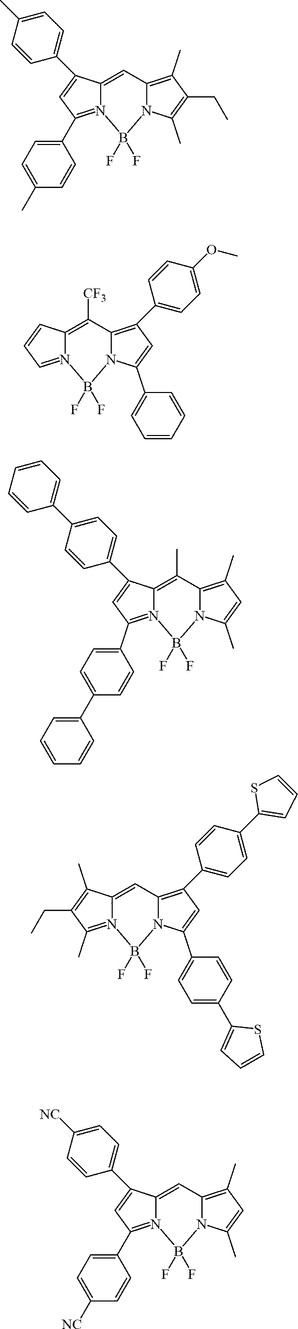

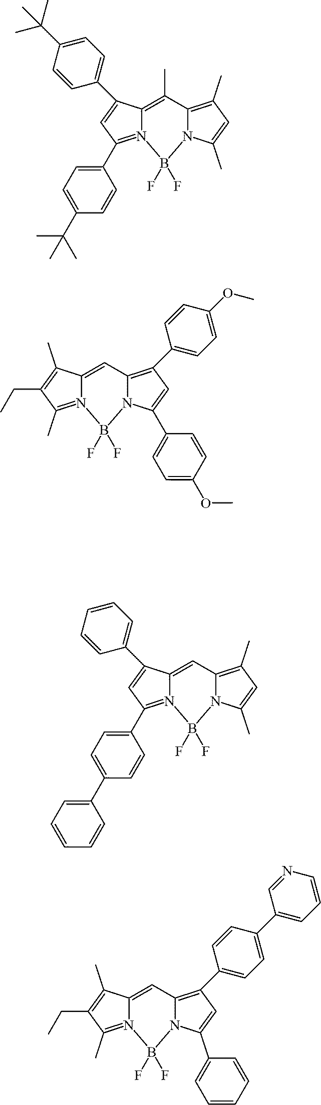

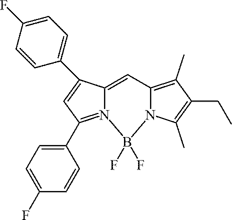

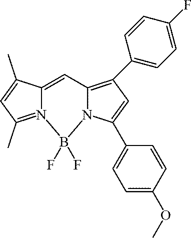

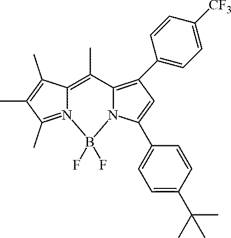

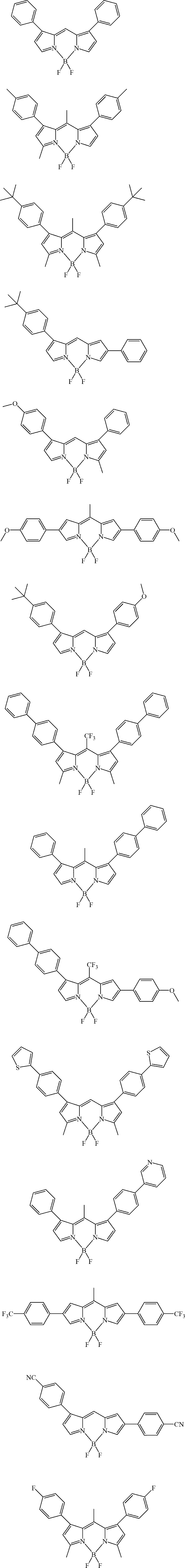

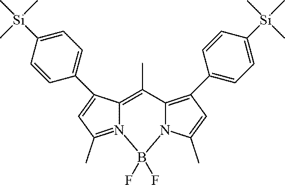

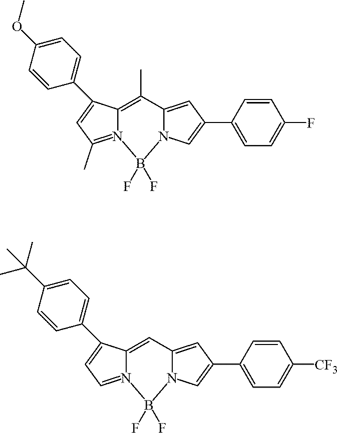

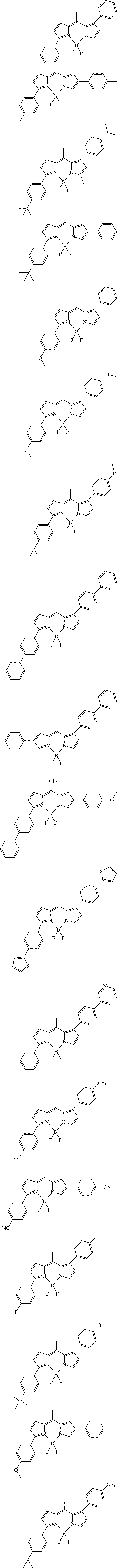

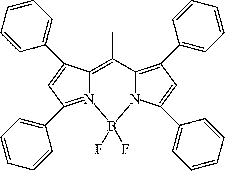

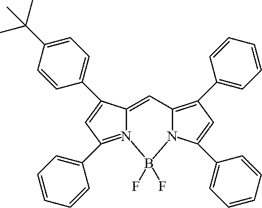

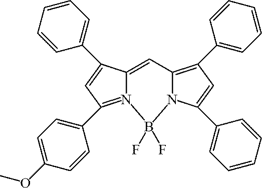

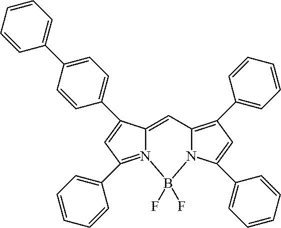

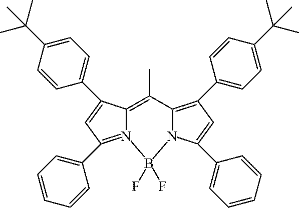

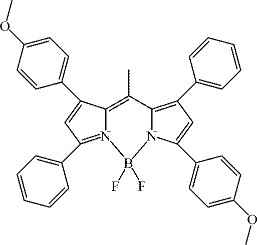

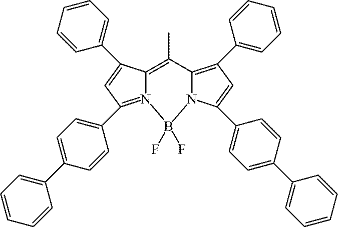

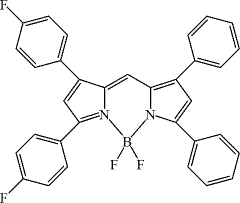

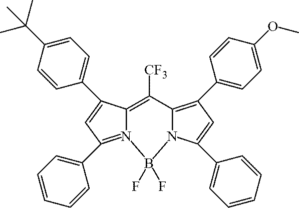

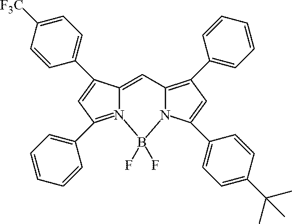

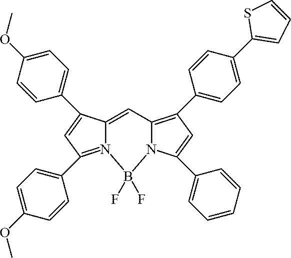

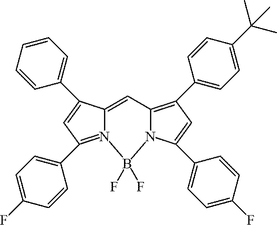

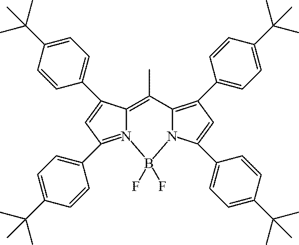

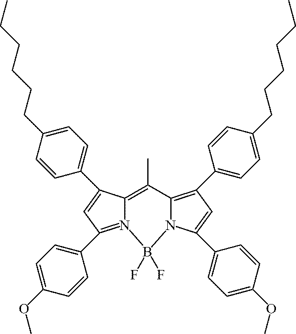

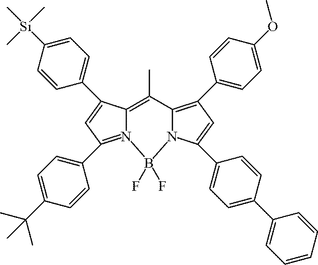

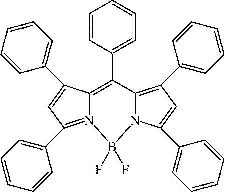

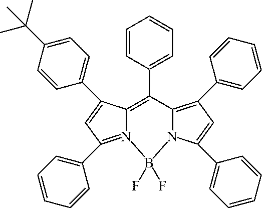

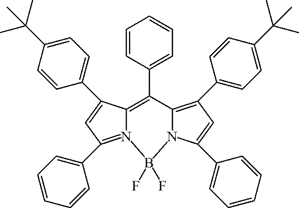

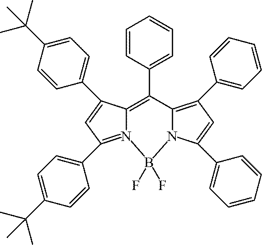

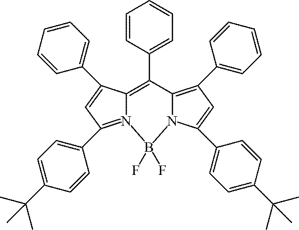

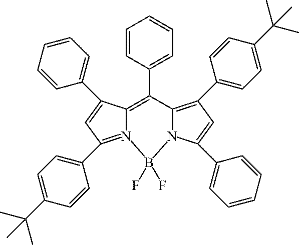

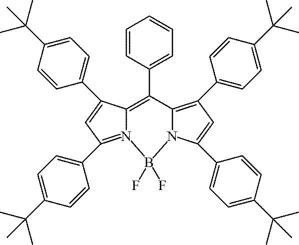

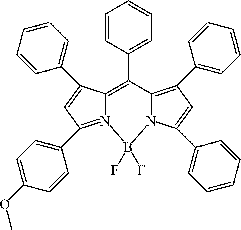

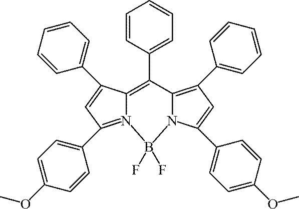

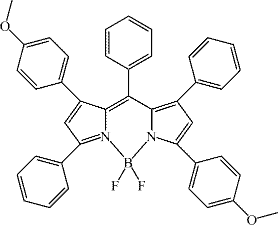

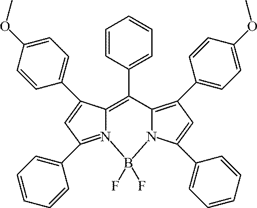

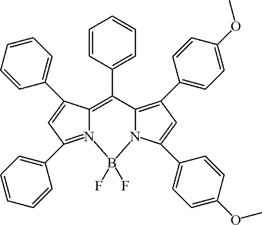

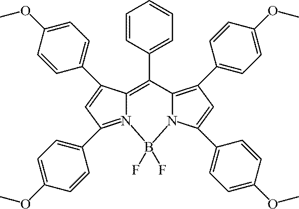

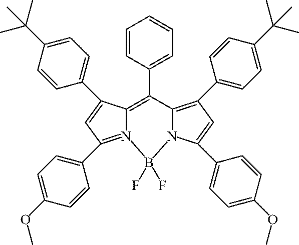

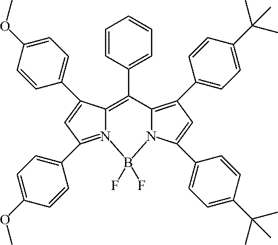

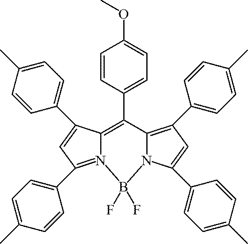

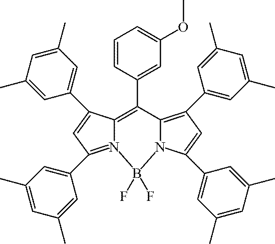

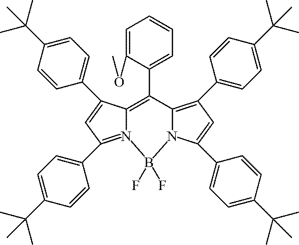

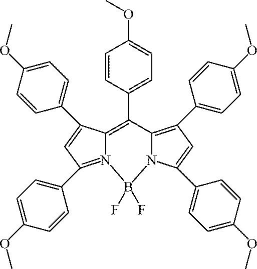

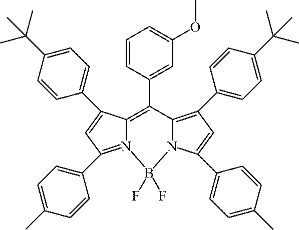

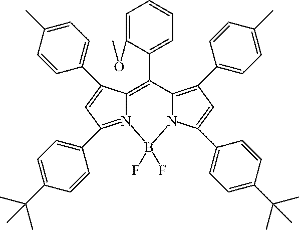

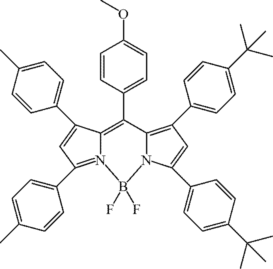

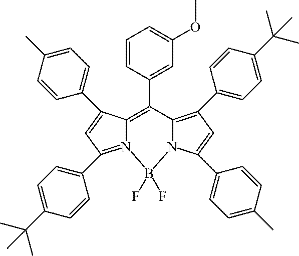

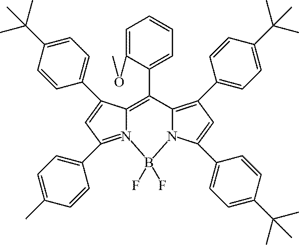

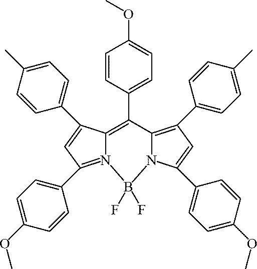

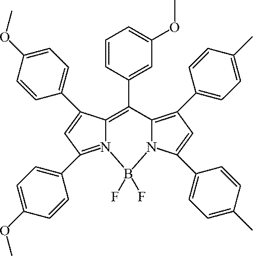

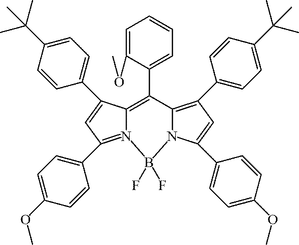

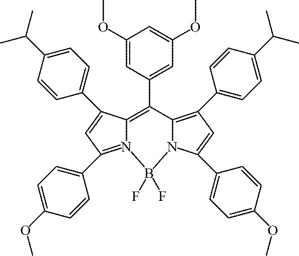

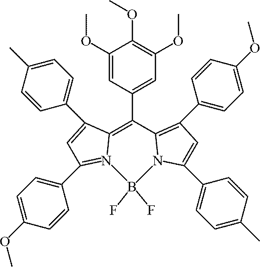

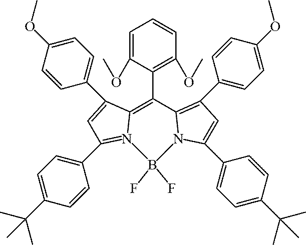

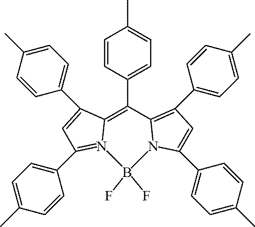

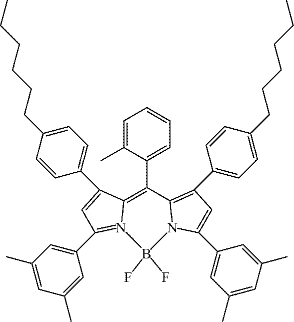

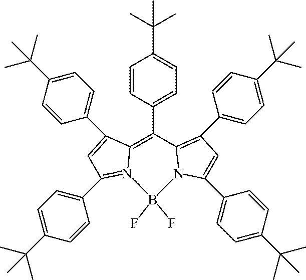

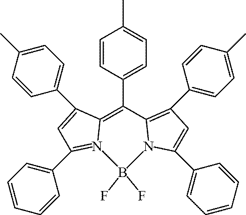

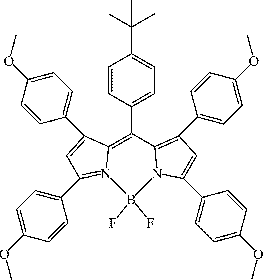

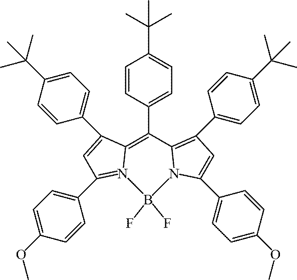

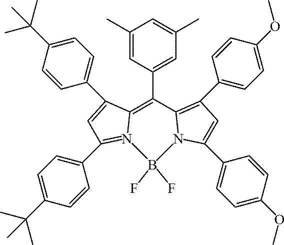

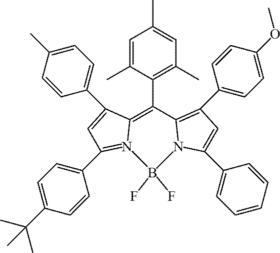

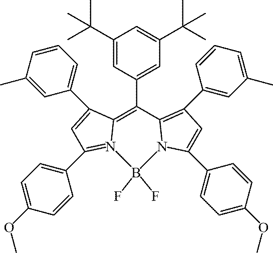

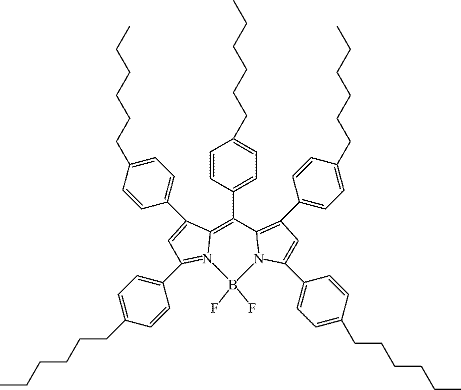

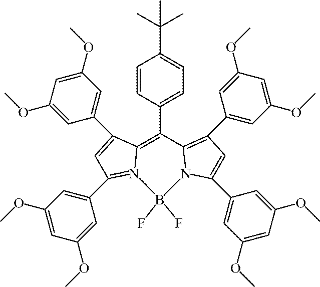

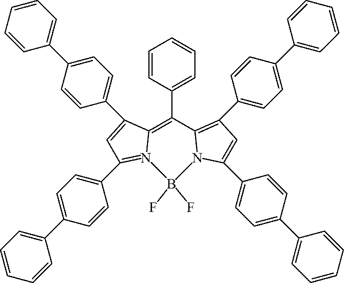

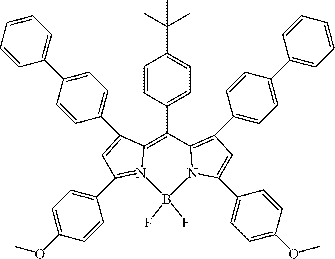

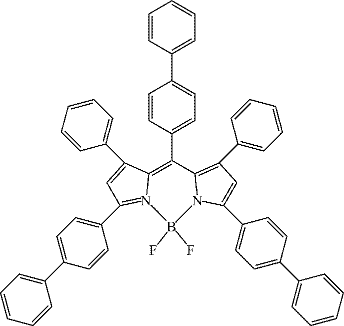

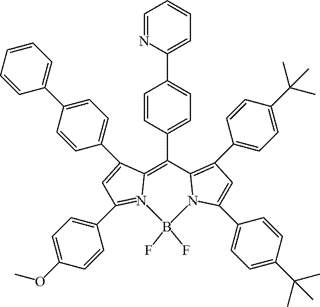

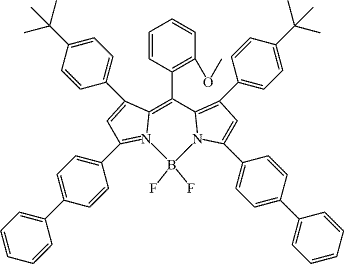

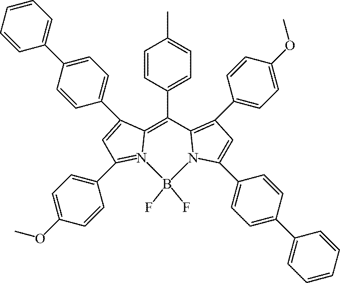

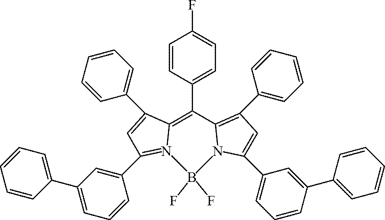

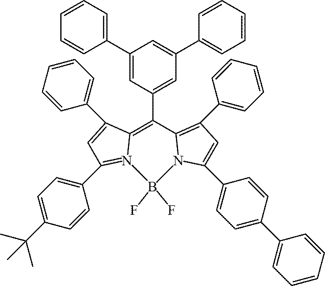

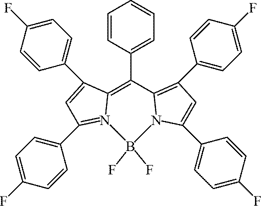

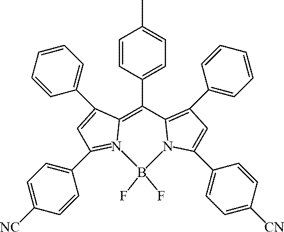

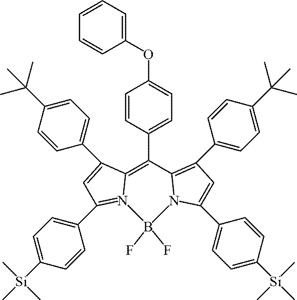

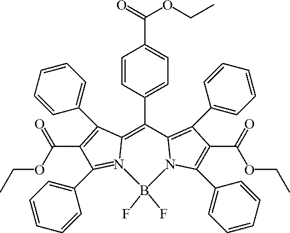

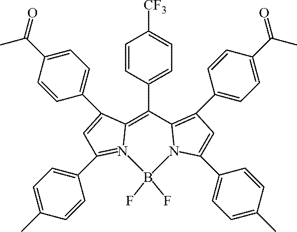

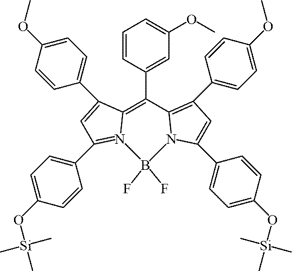

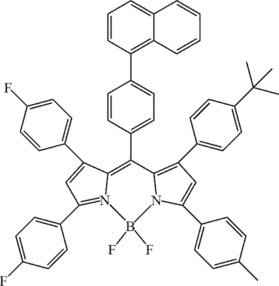

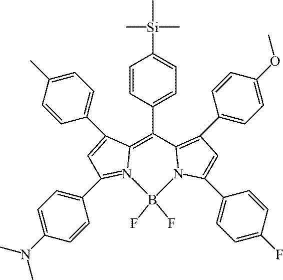

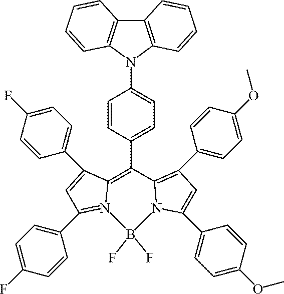

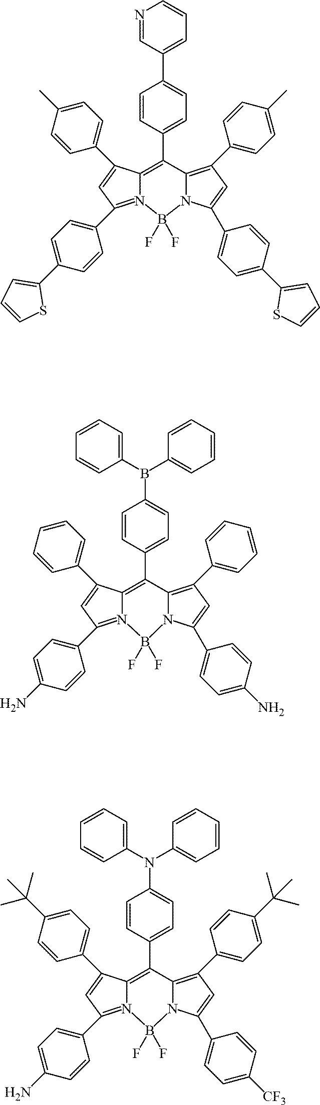

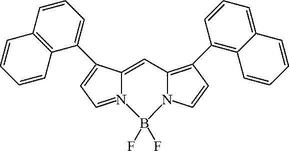

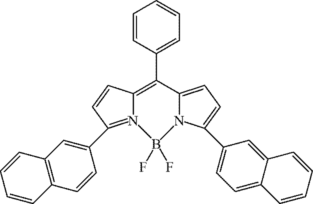

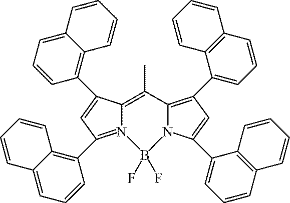

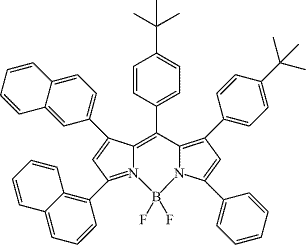

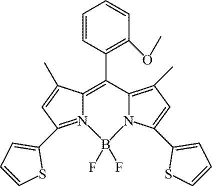

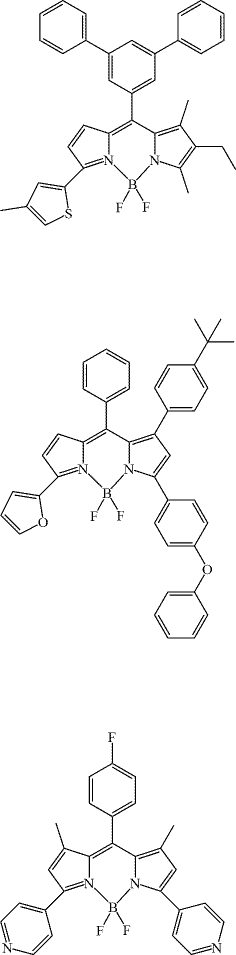

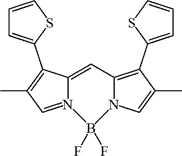

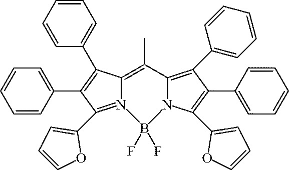

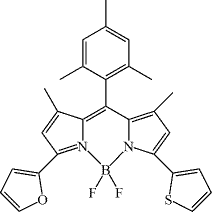

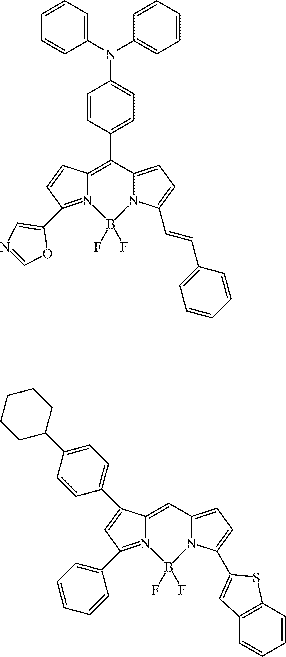

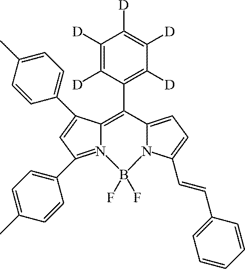

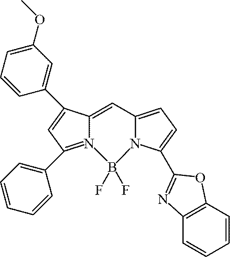

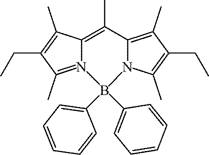

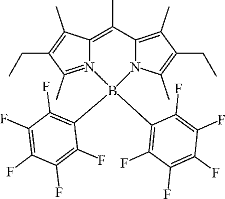

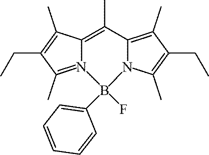

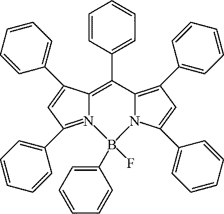

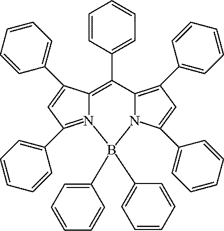

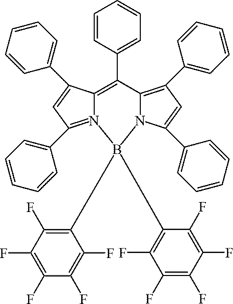

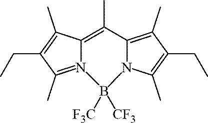

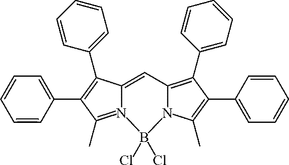

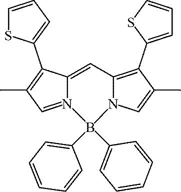

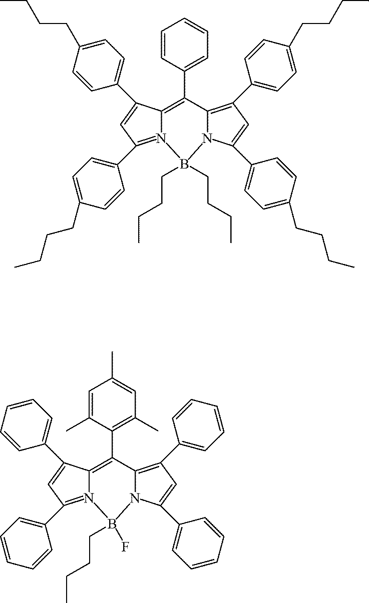

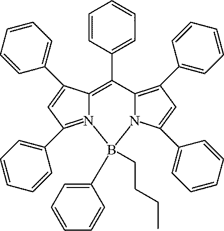

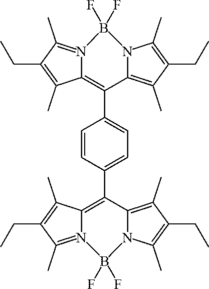

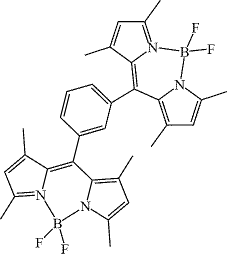

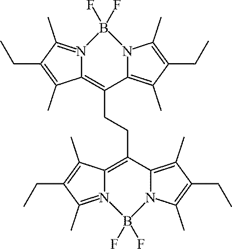

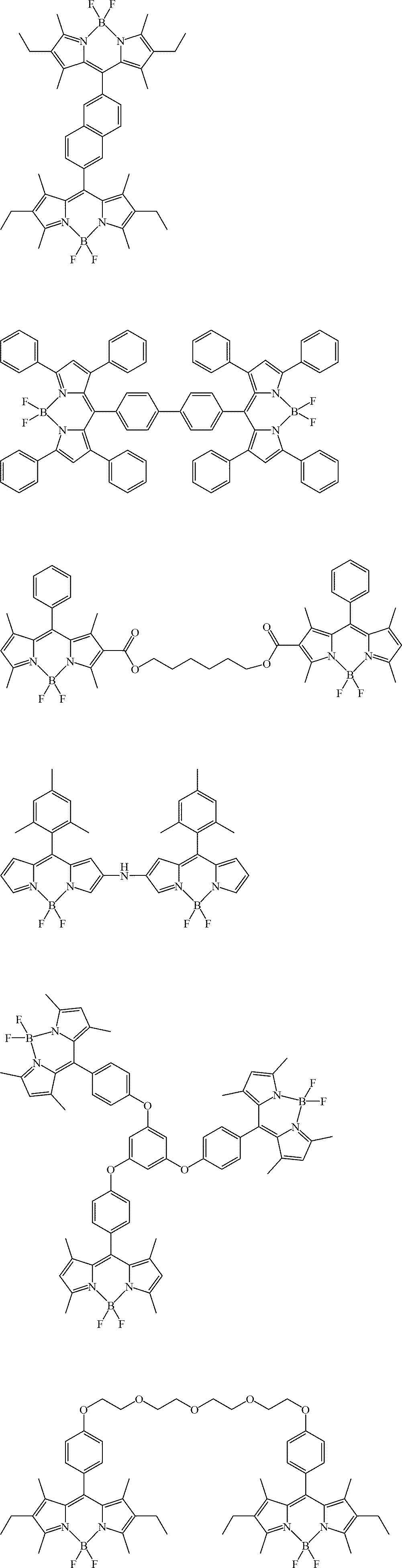

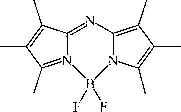

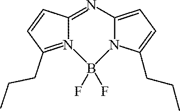

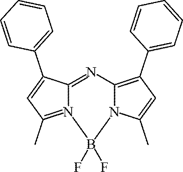

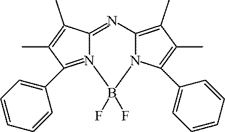

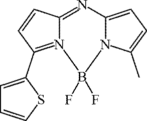

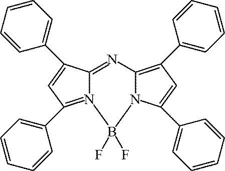

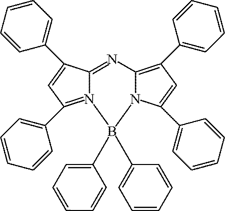

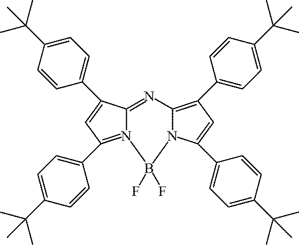

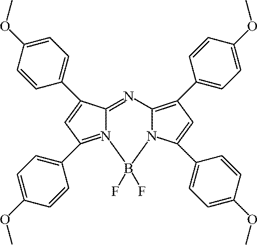

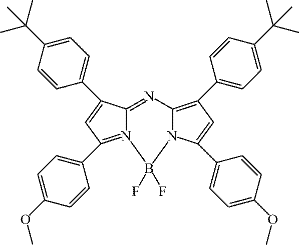

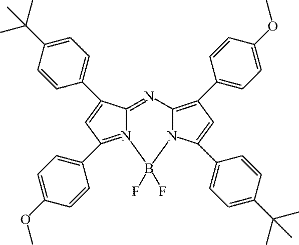

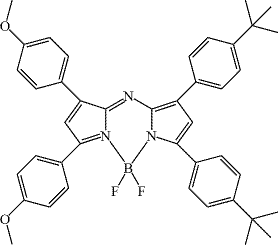

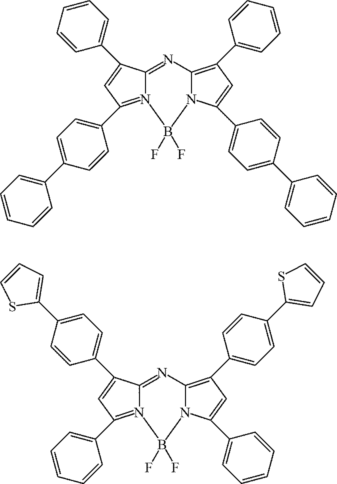

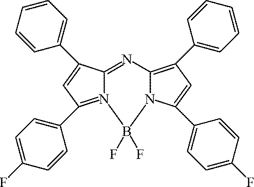

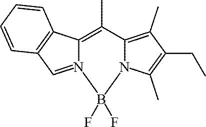

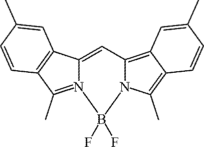

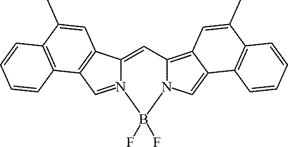

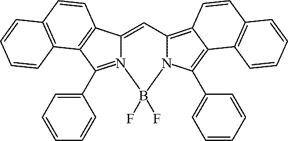

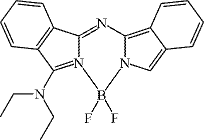

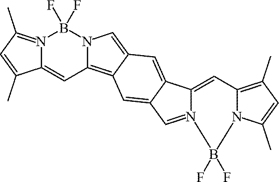

The compound represented by General Formula (1) can be synthesized, for example, by the method described in JP1996-509471A (JP-H8-509471A) and JP2000-208262A. That is, a target pyrromethene-based metal complex is obtained by reacting a pyrromethene compound with a metal salt in the presence of a base.

In addition, with regard to a synthesis of a pyrromethene-boron fluoride complex, the compound represented by General Formula (1) can be synthesized with reference to the method described in J. Org. Chem., vol. 64, No. 21, pp. 7813 to 7819 (1999); Angew. Chem., Int. Ed. Engl., vol. 36, pp. 1333 to 1335 (1997); and the like. Examples thereof include a method of obtaining the compound represented by General Formula (1) by heating a compound represented by General Formula (3) and a compound represented by General Formula (4) in the presence of phosphorus oxychloride, and then reacting with a compound represented by General Formula (5) in 1,2-dichloroethane in the presence of triethylamine. However, the present disclosure is not limited thereto. Here, R¹ to R⁹ are the same as those described above. J represents halogen.

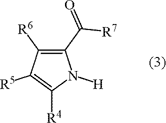

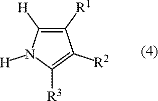

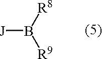

Furthermore, in a case of introducing the aryl group or the heteroaryl group, examples of the above-described method include a method of forming a carbon-carbon bond by a coupling reaction between a halogenated compound and a boronic acid or a boronic esterified compound, but the present disclosure is not limited thereto.

Similarly, in a case of introducing the amino group or the carbazolyl group, examples of the above-described method include a method forming a carbon-nitrogen bond by a coupling reaction between a halogenated compound and an amine or a carbazole compound in the presence of a metal catalyst such as palladium, but the present disclosure is not limited thereto.

The first color conversion layer may appropriately contain other compounds in addition to the compound represented by General Formula (1), as necessary. For example, in order to further increase energy transfer efficiency from the excitation light to the compound represented by General Formula (1), the first color conversion layer may contain an assist dopant such as rubrene.

In addition, in a case where it is desired to add a light-emitting color other than a light-emitting color of the compound represented by General Formula (1), a desired organic light-emitting material (for example, a coumarin-based coloring agent, a rhodamine-based coloring agent, and the like) can be added. In addition to these organic light-emitting materials, it is also possible to add a combination of known light-emitting materials such as an inorganic phosphor, a fluorescent pigment, a fluorescent dye, and quantum dot.

Examples of the organic light-emitting material other than the compound represented by General Formula (1) are shown below, but the present disclosure is not particularly limited thereto.

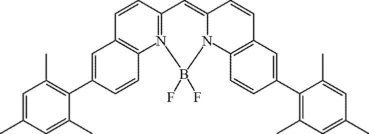

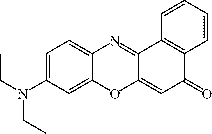

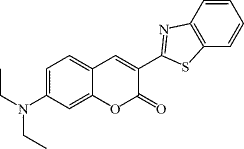

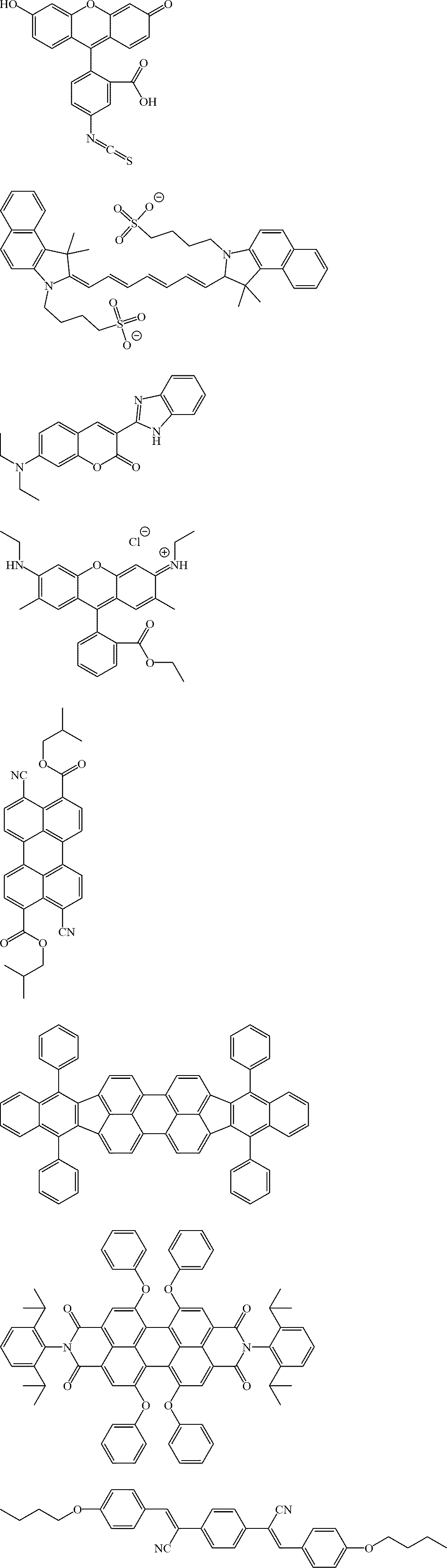

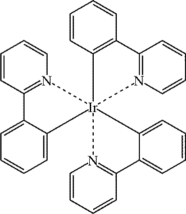

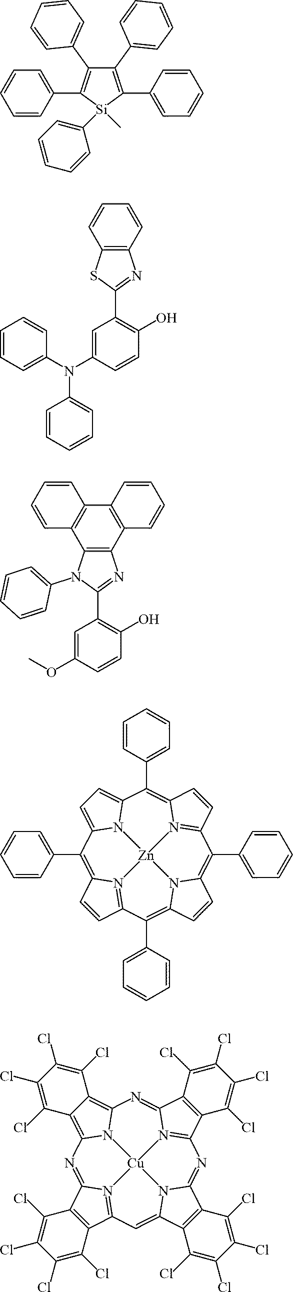

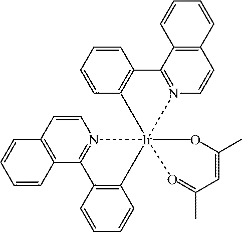

The first color conversion layer may contain two or more kinds of the specific organic light-emitting materials A.

From the viewpoint of wavelength conversion effect, a content of the specific organic light-emitting material A is preferably 0.005 parts by mass to 1 part by mass, more preferably 0.007 parts by mass to 0.7 parts by mass, and still more preferably 0.01 parts by mass to 0.5 parts by mass with respect to 100 parts by mass of the total amount of solid contents contained in the first color conversion layer.

The first color conversion layer may contain one or two or more kinds of the binder resins.

The binder resin is not particularly limited, and examples thereof include an epoxy resin, a silicone resin (including organopolysiloxane cured products (crosslinked products) such as silicone rubber and silicone gel), a polyester resin, a (meth)acrylic resin, a vinyl resin, a polyamide resin, a polyimide resin, a polycarbonate resin, a cellulose resin, a polyolefin resin, a urea resin, a melamine resin, a phenol resin, a polyvinyl alcohol resin, a polyvinyl butyral resin, a fluororesin, a thermocurable resin, and a photocurable resin.

Among the above, from the viewpoint of transparency and heat resistance, an epoxy resin, a silicone resin, a polyester resin, a (meth)acrylic resin, or a mixture thereof is preferable.

It is preferable that the binder resin contained in the first color conversion layer is different from a binder resin contained in the second color conversion layer. Accordingly, the organic light-emitting material contained in the first color conversion layer and the organic light-emitting material contained in the second color conversion layer are dispersed in different binder resins, so that each emission peak wavelength of these organic light-emitting materials can be individually adjusted to the optimum peak wavelength. The fact that the two binder resins are different from each other means that compositions of the resins are different from each other.

In a case where the first color conversion layer contains a binder resin, from the viewpoint of transparency, heat resistance, and dispersibility of the organic light-emitting material, a content of the binder resin is preferably 90 parts by mass or more, more preferably 93 parts by mass or more, and still more preferably 95 parts by mass or more with respect to 100 parts by mass of the total amount of solid contents contained in the first color conversion layer.

In addition, the content of the above-described binder resin is preferably 99 parts by mass or less with respect to 100 parts by mass of the total amount of solid contents contained in the first color conversion layer.

The first color conversion layer may contain a surfactant.

Examples of the surfactant include surfactants described in paragraph [0017] of JP4502784B and paragraphs [0060] to [0071] of JP2009-237362A.

As the surfactant, a fluorine-based surfactant, a nonionic surfactant, or a silicone-based surfactant is preferable.

Examples of a commercially available product of the fluorine-based surfactant include MEGAFACE (registered trademark) F-171, F-172, F-173, F-176, F-177, F-141, F-142, F-143, F-144, F-437, F-475, F-477, F-479, F-482, F-511, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON (registered trademark) S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.); FTERGENT (registered trademark) 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED).

In addition, as the fluorine-based surfactant, a (meth)acrylic compound which has a molecular structure having a functional group containing a fluorine atom and in which the functional group containing a fluorine atom is broken to volatilize a fluorine atom by applying heat to the molecular structure can also be suitably used.

Examples of such a fluorine-based surfactant include MEGAFACE (registered trademark) DS series manufactured by DIC Corporation (The Chemical Daily (Feb. 22, 2016) and Nikkei Business Daily (Feb. 23, 2016)) (for example, MEGAFACE (registered trademark) DS-21).

In addition, as the fluorine-based surfactant, a polymer of a fluorine atom-containing vinyl ether compound having a fluorinated alkyl group or a fluorinated alkylene ether group, and a hydrophilic vinyl ether compound can also be preferably used.

In addition, a block polymer can also be used as the fluorine-based surfactant.

As the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group at a side chain can also be used. Specific examples thereof include MEGAFACE (registered trademark) RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, and ethoxylate and propoxylate thereof (for example, glycerol propoxylate, glycerol ethoxylate, and the like), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester.

Examples of a commercially available product thereof include PLURONIC (registered trademark) L10, L31, L61, L62, 10R5, 17R2, and 25R2 (all of which are manufactured by BASF); TETRONIC (registered trademark) 304, 701, 704, 901, 904, and 150R1 (all of which are manufactured by BASF); Solsperse 20000 (manufactured by Nippon Lubrizol Corporation); NCW-101, NCW-1001, and NCW-1002 (all of which are manufactured by FUJIFILM Wako Pure Chemical Corporation); Pionin D-6112, D-6112-W, and D-6315 (all of which are manufactured by TAKEMOTO OIL & FAT Co., Ltd.); and OLFINE (registered trademark) E1010, SURFYNOL (registered trademark) 104, 400, and 440 (all of which are manufactured by Nissin Chemical Co., Ltd.).

Examples of the silicone-based surfactant include a linear polymer having a siloxane bond and a modified siloxane polymer with an organic group introduced in the side chain or the terminal.

Specific examples of the silicone-based surfactant include DOWSIL (registered trademark) 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Coming Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Silicone Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

The surfactant may be used alone or in combination of two or more kinds thereof.

In a case where the first color conversion layer contains a surfactant, a content of the surfactant is preferably 0.01 parts by mass to 3 parts by mass, more preferably 0.02 parts by mass to 1 part by mass, and still more preferably 0.05 parts by mass to 0.80 parts by mass with respect to 100 parts by mass of solid contents contained in the first color conversion layer.

The first color conversion layer may contain an additive other than the organic light-emitting material and the binder resin described above. Examples of the additive include a viscosity adjuster, an antioxidant, a heat stabilizer, a plasticizer, a leveling agent, an antistatic agent, a crosslinking agent, a curing agent, a silane coupling agent, inorganic particles, and organic particles.

From the viewpoint of wavelength conversion effect, a thickness of the first color conversion layer is preferably 1 µm or more, more preferably 5 µm or more, and still more preferably 10 µm or more.

In addition, from the viewpoint of downsizing of a backlight unit or the like, the thickness of the first color conversion layer is preferably 50 µm or less.

### Second Color Conversion Layer

In the first aspect, the second color conversion layer contains an organic light-emitting material (hereinafter, also referred to as a specific organic light-emitting material B) which emits, by at least one of excitation light having a wavelength of 400 nm or more and less than 500 nm or light emitted from an organic light-emitting material contained in the first color conversion layer, light observed in a region having a peak wavelength of 580 nm or more and less than 750 nm.

Suitable examples of the specific organic light-emitting material B include cyanine compounds such as 4-dicyanomethylene-2-methyl-6-(p-dimethylaminostyryl)-4H-pyran; rhodamine compounds such as rhodamine B, rhodamine 6G, rhodamine 101, and sulforhodamine 101; pyridine compounds such as 1-ethyl-2-(4-(p-dimethylaminophenyl)-1,3-butadienyl)-pyridinium-perchlorate; perylene compounds such as N,N′-bis(2,6-diisopropylphenyl)-1,6,7,12-tetraphenoxyperylene-3,4:9,10-bisdicarboimide; porphyrin compounds; pyrromethene compounds; oxazine compounds; pyrazine compounds; compounds having a fused aryl ring, such as naphthacene and dibenzodiindenoperylene; derivatives thereof; and organic metal complex compounds. However, the specific organic light-emitting material B is not particularly limited thereto.

Among the above-described compounds, a pyrromethene compound is preferable because it provides an excellent emission quantum yield and has good durability. As the pyrromethene compound, for example, the compound represented by General Formula (1) described above is preferable because it exhibits light emission with excellent color purity.

It is preferable that at least one of the organic light-emitting material contained in the first color conversion layer or the organic light-emitting material contained in the second color conversion layer is the compound represented by General Formula (1), and it is more preferable that both are the compounds represented by General Formula (1).

In addition, same as the first color conversion layer, the second color conversion layer may contain an organic light-emitting material other than the compound represented by General Formula (1).

In addition, preferred examples of the compound represented by General Formula (1), which can be suitably used as the specific organic light-emitting material B, include a case where all of R¹, R³, R⁴, and R⁶ are each independently selected from Ar-1 to Ar-6 described above, X is C-R⁷, and R⁷ represents the group represented by General Formula (2). In this case, R⁷ more preferably represents the group represented by General Formula (2), in which r is a tert-butyl group or a methoxy group, and particularly preferably represents the group represented by General Formula (2), in which r is a methoxy group.

The second color conversion layer may contain two or more kinds of the specific organic light-emitting materials B. In addition, same as the first color conversion layer, the second color conversion layer may contain a light-emitting material other than the organic light-emitting material.

From the viewpoint of wavelength conversion effect, a content of the specific organic light-emitting material B is preferably 0.005 parts by mass to 1 part by mass, more preferably 0.007 parts by mass to 0.7 parts by mass, and still more preferably 0.01 parts by mass to 0.5 parts by mass with respect to 100 parts by mass of the total amount of solid contents contained in the second color conversion layer.

The second color conversion layer may contain one or two or more kinds of the binder resins. The type and preferred content of the binder resin are the same as those of the first color conversion layer, and thus the description thereof will be omitted here.

The second color conversion layer may contain one or two or more kinds of surfactants. The type and preferred content of the surfactant are the same as those of the first color conversion layer, and thus the description thereof will be omitted here.

The second color conversion layer may contain the above-described additive.

From the viewpoint of wavelength conversion effect, a thickness of the second color conversion layer is preferably 1 µm or more, more preferably 5 µm or more, and still more preferably 10 µm or more.

In addition, from the viewpoint of downsizing of a backlight unit or the like, the thickness of the second color conversion layer is preferably 50 µm or less.

### Interlayer Mixing Layer

In the first aspect, the color conversion film includes an interlayer mixing layer between the first color conversion layer and the second color conversion layer, in which the first color conversion layer and the second color conversion layer are mixed together.

As will be described later, the above-described interlayer mixing layer is formed by a method in which, in a case where the second color conversion layer is formed on the first color conversion layer, the first color conversion layer is eroded by a coating liquid or the like for forming the second color conversion layer, and the first color conversion layer and the second color conversion layer are mixed together.

The presence and thickness of the interlayer mixing layer can be confirmed by observing a cross section of the color conversion film by a transmission electron microscopy (TEM) or a scanning electron microscopy (SEM).

In addition, the presence of the interlayer mixing layer can also be confirmed by confirming that the organic light-emitting materials and the binder resins, which are contained in each of the first color conversion layer and the second color conversion layer, are contained in the interlayer mixing layer. Specifically, the presence of the interlayer mixing layer can be confirmed by detecting a fragment unique to the binder resin in the cross section of the color conversion film by a secondary ion mass spectrometry (TOF-SIMS).

In addition, the thickness of the interlayer mixing layer can be measured by performing fragment mapping of the detected binder resin. A specific measuring method will be described in Examples.

From the viewpoint of adhesiveness and color reproducibility, the thickness of the interlayer mixing layer can be 0.01 µm to 5.0 µm, preferably 0.1 µm to 2.0 µm and more preferably 0.2 µm to 1.0 µm.

### Protective Layer

In the first aspect, the color conversion film may include a protective layer on the second color conversion layer opposite to the interlayer mixing layer.

As the protective layer, the same material as the support described above can be used. Since the specific materials have been described above, the description thereof will be omitted here.

From the viewpoint of strength of the color conversion film, a thickness of the protective layer is preferably 20 µm or more, and more preferably 30 µm or more.

In addition, from the viewpoint of downsizing of a backlight unit or the like, the thickness of the protective layer is preferably 1000 µm or less.

### Formation of Other Layers

In the color conversion film of the first aspect, other layers may be formed on the support, the second color conversion layer, or the protective layer.

Examples of the other layers include an oxygen barrier layer, a water vapor barrier layer, an antireflection layer, an antistatic layer, and an antifouling later.

### Method for Manufacturing Color Conversion Film According to First Aspect

In the first aspect, a method for manufacturing the color conversion film includes forming, on a support, a first color conversion layer containing an organic light-emitting material which emits, by excitation light having a wavelength of 400 nm or more and less than 500 nm, light observed in a region having a peak wavelength of 500 nm or more and less than 580 nm; and

forming, on the first color conversion layer, a second color conversion layer containing an organic light-emitting material which emits, by at least one of the excitation light having a wavelength of 400 nm or more and less than 500 nm or the light emitted from the organic light-emitting material contained in the first color conversion layer, light observed in a region having a peak wavelength of 580 nm or more and less than 750 nm, and forming an interlayer mixing layer between the first color conversion layer and the second color conversion layer, in which the first color conversion layer and the second color conversion layer are mixed together.

### Formation of First Color Conversion Layer

In the first aspect, the method for manufacturing the color conversion film includes forming the first color conversion layer on the support.

Examples of the method of forming the first color conversion layer include applying and drying, on the support, a coating liquid for forming the first color conversion layer, that contains an organic light-emitting material (specific organic light-emitting material A) which emits, by excitation light having a wavelength of 400 nm or more and less than 500 nm, light observed in a region having a peak wavelength of 500 nm or more and less than 580 nm.

In addition, the first color conversion layer may be formed by melt-extruding a composition containing the specific organic light-emitting material A onto the support.

In a case where the first color conversion layer is formed by applying and drying the coating liquid for forming the first color conversion layer on the support, the applying method is not particularly limited, and a known method in the related art can be performed. Examples of the applying method include a curtain coating method, a dip coating method, a spin coating method, a printing coating method, a spray coating method, a slot coating method, a roll coating method, a slide coating method, a blade coating method, a gravure coating method, and a wire bar method.

A drying method is not particularly limited, and the drying can be performed by a known method in the related art, such as using warm air.

A drying temperature is preferably changed as appropriate depending on composition of a coating liquid for forming the first color conversion layer, but is preferably 50° C. to 200° C. and more preferably 70° C. to 150° C.

### Coating Liquid for Forming First Color Conversion Layer

In the first aspect, the coating liquid for forming the first color conversion layer contains the specific organic light-emitting material A. The specific organic light-emitting material A is as described above, and the description thereof will be omitted here.

In addition, the coating liquid for forming the first color conversion layer may contain the binder resin, the additive, or the like described above.

The coating liquid for forming the first color conversion layer may contain an organic solvent.

From the viewpoint of drying suitability, the coating liquid for forming the first color conversion layer preferably contains a high-boiling-point organic solvent having a boiling point of 100° C. or higher and a low-boiling-point organic solvent having a boiling point of 99° C. or lower.

The boiling point of the high-boiling-point organic solvent is preferably 250° C. or lower, more preferably 110° C. to 180° C., and still more preferably 120° C. to 170° C.

The boiling point of the low-boiling-point organic solvent is preferably 0° C. or higher, more preferably 10° C. to 95° C., and still more preferably 20° C. to 90° C.

Examples of the high-boiling-point organic solvent include 1-methoxy-2-propyl acetate (140° C.), 1,2-pentanediol (206° C.), 1,2-propanediol (188° C.), 1,3-propanediol (214° C.), 1,2-butanediol (193° C.), 3-methoxy-3-methyl-1-butanol (174° C.), 1,3-butanediol (207° C.), 1,4-butanediol (228° C.), 1,5-pentanediol (242° C.), 2-ethyl-1,3-hexanediol (244° C.), 2-butene-1,4-diol (235° C.), 1,2-hexanediol (223° C.), and 2-methyl-2,4-pentanediol (198° C.).

Examples of the low-boiling-point organic solvent include methyl ethyl ketone (80° C.), acetaldehyde (21° C.), acetone (56° C.), acetonitrile (82° C.), benzene (80° C.), and chloroform (61° C.).

The temperature in parentheses is the boiling point.

An amount of the organic solvent contained in the coating liquid for forming the first color conversion layer is not particularly limited, but from the viewpoint dispersibility of the organic light-emitting material and the like, ease of applying a coating liquid onto a support, and ease of drying, a content of the organic solvent is preferably 50 parts by mass to 500 parts by mass with respect to 100 parts by mass of the total amount of solid contents contained in the coating liquid for forming the first color conversion layer.

### Formation of Second Color Conversion Layer and Interlayer Mixing Layer

In the first aspect, the method for manufacturing the color conversion film includes forming the second color conversion layer on the first color conversion layer and forming the interlayer mixing layer between the first color conversion layer and the second color conversion layer, in which the first color conversion layer and the second color conversion layer are mixed together.

Examples of the method of forming the second color conversion layer include applying and drying, on the first color conversion layer, a coating liquid for forming the second color conversion layer, that contains an organic light-emitting material (hereinafter, also referred to as a specific organic light-emitting material B) which emits, by at least one of the excitation light having a wavelength of 400 nm or more and less than 500 nm or the light emitted from the organic light-emitting material contained in the first color conversion layer, light observed in a region having a peak wavelength of 580 nm or more and less than 750 nm. The applying method, the drying temperature, and the like can be the same as those for forming the first color conversion layer, and the description thereof will be omitted here.

In addition, the second color conversion layer may be formed by melt-extruding a composition containing the specific organic light-emitting material B onto the first color conversion layer.

The interlayer mixing layer is formed between the first color conversion layer and the second color conversion layer by a method in which the first color conversion layer is eroded by the above-described coating liquid or composition used for forming the second color conversion layer, and the first color conversion layer and the second color conversion layer are mixed together.

### Coating Liquid for Forming Second Color Conversion Layer

In the first aspect, the coating liquid for forming the second color conversion layer contains the specific organic light-emitting material B. The specific organic light-emitting material B is as described above, and the description thereof will be omitted here.

In addition, the coating liquid for forming the second color conversion layer may contain the binder resin, the additive, or the like described above.

The coating liquid for forming the second color conversion layer may contain an organic solvent.

The coating liquid for forming the second color conversion layer preferably contains a high-boiling-point organic solvent having a boiling point of 100° C. or higher and a low-boiling-point organic solvent having a boiling point of 99° C. or lower.

The boiling point of the high-boiling-point organic solvent is preferably 250° C. or lower, more preferably 110° C. to 180° C., and still more preferably 120° C. to 170° C.

The boiling point of the low-boiling-point organic solvent is preferably 0° C. or higher, more preferably 10° C. to 95° C., and still more preferably 20° C. to 90° C.

Specific examples of the organic solvent are as described above.

A content of the high-boiling-point organic solvent is preferably 10 parts by mass to 90 parts by mass, and more preferably 20 parts by mass to 80 parts by mass with respect to 100 parts by mass of the total amount of the organic solvents contained in the coating liquid for forming the second color conversion layer.

By setting the content of the high-boiling-point organic solvent within the above-described numerical range, an interlayer mixing layer having an appropriate thickness is formed between the first color conversion layer and the second color conversion layer, and the adhesiveness between these layers is further improved while maintaining the color reproducibility.

An amount of the organic solvent contained in the coating liquid for forming the second color conversion layer is not particularly limited, but from the viewpoint dispersibility of the organic light-emitting material and the like, ease of applying a coating liquid onto a support, and ease of drying, a content of the organic solvent is preferably 50 parts by mass to 500 parts by mass with respect to 100 parts by mass of the total amount of solid contents contained in the coating liquid for forming the second color conversion layer.

### Formation of Protective Layer

In the first aspect, the method for manufacturing a color conversion film may include forming a protective layer on the second color conversion layer.

The protective layer can be formed by heating and pressure-bonding the resin film or the like described above onto the second color conversion layer.

In another aspect, the protective layer can be formed by applying and drying a coating liquid containing the resin material on the second color conversion layer.

### Formation of Other Layers

In the method for manufacturing the color conversion film of the first aspect, other layers may be formed on a layer such as the second color conversion layer. Since the specific examples of the other layers have been described above, the description thereof will be omitted here.

### Color Conversion Film According to Second Aspect

In a second aspect, a color conversion film includes a support; a first color conversion layer containing an organic light-emitting material which emits, by at least one of an excitation light having a wavelength of 400 nm or more and less than 500 nm or light emitted from an organic light-emitting material contained in a second color conversion layer, light observed in a region having a peak wavelength of 580 nm or more and less than 750 nm; a second color conversion layer containing the organic light-emitting material which emits, by the excitation light having a wavelength of 400 nm or more and less than 500 nm, light observed in a region having a peak wavelength of 500 nm or more and less than 580 nm; and an interlayer mixing layer between the first color conversion layer and the second color conversion layer, in which the first color conversion layer and the second color conversion layer are mixed together (not shown).

### Support

As the support, the same as the support provided in the color conversion film according to the first aspect can be used, and the description thereof will be omitted here.

### First Color Conversion Layer

In the second aspect, the first color conversion layer contains an organic light-emitting material (specific organic light-emitting material B) which emits, by at least one of excitation light having a wavelength of 400 nm or more and less than 500 nm or light emitted from an organic light-emitting material contained in a second color conversion layer, light observed in a region having a peak wavelength of 580 nm or more and less than 750 nm. Since the specific organic light-emitting material B is as described above, and the description thereof will be omitted here.

From the viewpoint of wavelength conversion effect, a content of the specific organic light-emitting material B is preferably 0.005 parts by mass to 1 part by mass, more preferably 0.007 parts by mass to 0.7 parts by mass, and still more preferably 0.01 parts by mass to 0.5 parts by mass with respect to 100 parts by mass of the total amount of solid contents contained in the first color conversion layer.

The first color conversion layer may contain one or two or more kinds of the binder resins. The type and preferred content of the binder resin are the same as those of the first color conversion layer, and thus the description thereof will be omitted here.

The coating liquid for forming the first color conversion layer may contain the above-described additive.

From the viewpoint of wavelength conversion effect, a thickness of the first color conversion layer is preferably 1 µm or more, more preferably 5 µm or more, and still more preferably 10 µm or more.

In addition, from the viewpoint of downsizing of a backlight unit or the like, the thickness of the first color conversion layer is preferably 50 µm or less.

### Second Color Conversion Layer

In the second aspect, the second color conversion layer contains an organic light-emitting material (hereinafter, also referred to as a specific organic light-emitting material A) which emits, by excitation light having a wavelength of 400 nm or more and less than 500 nm, light observed in a region having a peak wavelength of 500 nm or more and less than 580 nm. Since the specific organic light-emitting material A is as described above, and the description thereof will be omitted here.

From the viewpoint of wavelength conversion effect, a content of the specific organic light-emitting material A is preferably 0.005 parts by mass to 1 part by mass, more preferably 0.007 parts by mass to 0.7 parts by mass, and still more preferably 0.01 parts by mass to 0.5 parts by mass with respect to 100 parts by mass of the total amount of solid contents contained in the second color conversion layer.

The second color conversion layer may contain one or two or more kinds of the binder resins. The type and preferred content of the binder resin are the same as those of the second color conversion layer, and thus the description thereof will be omitted here.

The coating liquid for forming the second color conversion layer may contain the above-described additive.

From the viewpoint of wavelength conversion effect, a thickness of the second color conversion layer is preferably 1 µm or more, more preferably 5 µm or more, and still more preferably 10 µm or more.

In addition, from the viewpoint of downsizing of a backlight unit or the like, the thickness of the second color conversion layer is preferably 50 µm or less.

### Interlayer Mixing Layer

In the second aspect, the color conversion film includes an interlayer mixing layer between the first color conversion layer and the second color conversion layer, in which the first color conversion layer and the second color conversion layer are mixed together. Since the interlayer mixing layer is the same as that in the first aspect, the description thereof will be omitted here.

### Protective Layer

In the second aspect, the color conversion film may include a protective layer on the second color conversion layer. Since the protective layer is the same as that in the first aspect, the description thereof will be omitted here.

### Formation of Other Layers

In the color conversion film of the second aspect, other layers may be formed on the support, the second color conversion layer, or the protective layer. Since the other layers are the same as that in the first aspect, the description thereof will be omitted here.

### Method for Manufacturing Color Conversion Film According to Second Aspect

In the second aspect, a method for manufacturing the color conversion film includes forming, on a support, a first color conversion layer containing an organic light-emitting material which emits, by at least one of excitation light having a wavelength of 400 nm or more and less than 500 nm or light emitted from an organic light-emitting material contained in a second color conversion layer, light observed in a region having a peak wavelength of 580 nm or more and less than 750 nm; and

forming, on the first color conversion layer, a second color conversion layer containing an organic light-emitting material which emits, by the excitation light having a wavelength of 400 nm or more and less than 500 nm, light observed in a region having a peak wavelength of 500 nm or more and less than 580 nm, and forming an interlayer mixing layer between the first color conversion layer and the second color conversion layer, in which the first color conversion layer and the second color conversion layer are mixed together.

### Formation of First Color Conversion Layer

In the second aspect, the method for manufacturing the color conversion film includes forming the first color conversion layer on the support. Since the method of forming the first color conversion layer is the same as that of the first aspect, the description thereof will be omitted here.

### Formation of Second Color Conversion Layer and Interlayer Mixing Layer

In the second aspect, the method for manufacturing the color conversion film includes forming the second color conversion layer on the first color conversion layer and forming the interlayer mixing layer between the first color conversion layer and the second color conversion layer, in which the first color conversion layer and the second color conversion layer are mixed together. Since the method of forming the second color conversion layer and the interlayer mixing layer is the same as that of the first aspect, the description thereof will be omitted here.

### Formation of Protective Layer

In the second aspect, the method for manufacturing a color conversion film may include forming a protective layer on the second color conversion layer. Since the method of forming the protective layer is the same as that of the first aspect, the description thereof will be omitted here.

### Formation of Other Layers

In the method for manufacturing the color conversion film of the second aspect, other layers may be formed on at least one of the first color conversion layer or the second color conversion layer. Since the method of forming the other layers is the same as that of the first aspect, the description thereof will be omitted here.

### Backlight Unit

The backlight unit according to the embodiment of the present disclosure includes a light source, and the color conversion film according to the first aspect or the color conversion film according to the second aspect described above.

In a case of the color conversion film according to the first aspect, the color conversion film may be disposed with a surface on which the support is provided, facing the light source side, or may be disposed with a surface opposite to the surface on which the support is provided, facing the light source side.

In a case of the color conversion film according to the second aspect, the color conversion film may be disposed with a surface opposite to a surface on which the support is provided (surface on which the second color conversion layer is provided), facing the light source side, or may be disposed with a surface with the surface on which the support is provided, facing the light source side.

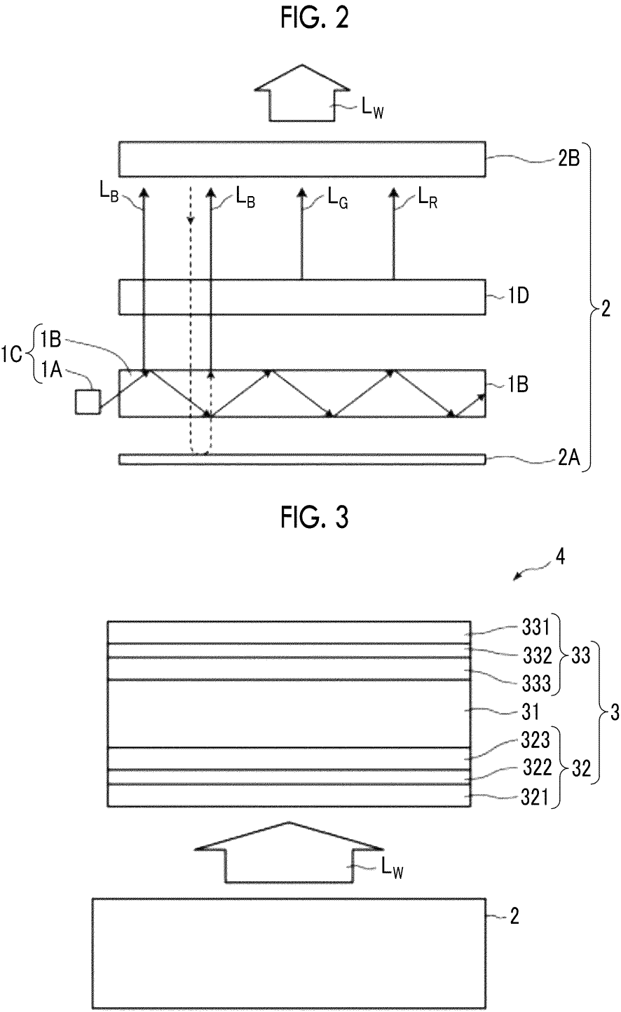

FIG. 2 is a schematic configuration cross-sectional diagram showing an embodiment of the backlight unit, and the backlight unit will be described below with reference to FIG. 2.

As shown in FIG. 2, a backlight unit 2 includes a planar light source 1C including a light source 1A which emits excitation light (blue light L_{B}) having a wavelength of 400 nm or more and less than 500 nm and a light guide plate 1B which guides and emits the excitation light emitted from the light source 1A, a color conversion film 1D provided on the planar light source 1C, a retroreflective member 2B disposed to face the planar light source 1C with the color conversion film 1D interposed therebetween, and a reflecting plate 2A disposed to face the color conversion film 1D with the planar light source 1C interposed therebetween.

In a case where the color conversion film 1D is the color conversion film according to the first aspect, the specific organic light-emitting material A contained in the first color conversion layer emits, by the excitation light emitted from the planar light source 1C, light (green light L_{G}) observed in a region having a peak wavelength of 500 nm or more and less than 580 nm.

In addition, the specific organic light-emitting material B contained in the second color conversion layer emits, by at least one of the excitation light which has passed through the first color conversion layer or the light emitted from the specific organic light-emitting material A, light (red light L_{R}) observed in a region having a peak wavelength of 580 nm or more and 750 nm or less.

White light L_{W} is emitted from a surface of the retroreflective member 2B by the excitation light (blue light L_{B}) which has been passed through the color conversion film, the light (green light L_{G}) which has been passed through the second color conversion layer and is observed in the region having a peak wavelength of 500 nm or more and less than 580 nm, and the light (red light L_{R}) which is observed in the region having a peak wavelength of 580 nm or more and 750 nm or less.

In a case where the color conversion film 1D is the color conversion film according to the second aspect, the specific organic light-emitting material A contained in the second color conversion layer emits, by the excitation light emitted from the planar light source 1C, light (green light L_{G}) observed in a region having a peak wavelength of 500 nm or more and less than 580 nm.

In addition, the specific organic light-emitting material B contained in the first color conversion layer emits, by at least one of the excitation light which has passed through the second color conversion layer or the light emitted from the specific organic light-emitting material B, light (red light L_{R}) observed in a region having a peak wavelength of 580 nm or more and 750 nm or less.

White light L_{W} is emitted from a surface of the retroreflective member 2B by the excitation light (blue light L_{B}) which has been passed through the color conversion film, the light (green light L_{G}) which has been passed through the first color conversion layer and is observed in the region having a peak wavelength of 500 nm or more and less than 580 nm, and the light (red light L_{R}) which is observed in the region having a peak wavelength of 580 nm or more and 750 nm or less.

In FIG. 2, the blue light L_{B}, the green light L_{G}, and the red light L_{R} emitted from the color conversion film 1D are incident on the retroreflective member 2B, and each incident light is repeatedly reflected between the retroreflective member 2B and the reflecting plate 2A and passes through the color conversion film 1D multiple times.

As a result, in the color conversion film 1D, a sufficient amount of the excitation light (blue light L_{B}) is absorbed by the specific organic light-emitting material B which emits the red light L_{R} and the specific organic light-emitting material A which emits the green light L_{G}, a required amount of fluorescence (the green light L_{G} and the red light L_{R}) is emitted, and the white light L_{W} is emitted from the retroreflective member 2B as the sum of the blue light L_{G}, the green light L_{G}, and the red light L_{R}.

From the viewpoint of improving brightness and color reproducibility, half-widths of each light emission intensity of the blue light, the green light, and the red light emitted by the backlight unit are all preferably 80 nm or less, more preferably 50 nm or less, still more preferably 40 nm or less, and even more preferably 30 nm or less. In addition, it is particularly preferable that the half-width of the light emission intensity of the blue light is 25 nm or less.

As the light source, a light-emitting diode, a laser light source, or the like can be used.

As shown in FIG. 2, the planar light source 1C may be a light source (edge light mode light source) including the light source 1A and the light guide plate 1B which guides and emits primary light emitted from the light source 1A, or may be a light source (direct backlight mode light source) in which the light source 1A is disposed in a plane parallel to the color conversion film 1D and a diffusion plate is provided in place of the light guide plate 1B. As the configuration of the backlight unit, although the edge light mode light source including the light guide plate, the reflecting plate, and the like as constituent members has been described in FIG. 2, the backlight unit may be the direct backlight mode light source.

As the light guide plate, a known light guide plate can be used without any limitation. In the present embodiment, the case where the planar light source is used as the light source has been described as an example, but a light source other than the planar light source can also be used as the light source.

In addition, the reflecting plate is not particularly limited, and a known reflecting plate can be used. For example, reflecting plates described in each publication such as JP3416302B, JP3363565B, JP4091978B, and JP3448626B can be used. The contents of these publications are incorporated herein by reference.

The retroreflective member may be configured of a known diffusion plate, diffusion sheet, prism sheet (for example, BEF series manufactured by Sumitomo 3 M), a reflective type polarizing film (for example, DBEF series manufactured by Sumitomo 3 M), or the like.

The configuration of the retroreflective member is described in each publication such as JP3416302B, JP3363565B, JP4091978B, and JP3448626B, the contents of which are incorporated herein by reference.

### Liquid Crystal Display Device

The liquid crystal display device according to the embodiment of the present disclosure includes the above-described backlight unit and a liquid crystal cell unit.

FIG. 3 shows a schematic configuration cross-sectional diagram showing an embodiment of the liquid crystal display device according to the present disclosure. As shown in FIG. 3, a liquid crystal display device 4 includes the backlight unit 2 shown in FIG. 2 and a liquid crystal cell unit 3 disposed to face the retroreflective member 2B side of the backlight unit 2.

The liquid crystal cell unit 3 has a configuration in which a liquid crystal cell 31 is sandwiched between a polarizing plate 32 and a polarizing plate 33. In addition, each of the polarizing plate 32 and the polarizing plate 33 has a configuration in which both main surfaces of a polarizer 322 and a polarizer 332 are protected by polarizing plate protective films 321, 323, 331, and 333.

The liquid crystal cell and the polarizing plate constituting the liquid crystal display device are not particularly limited, and those manufactured by a known method or commercially available products can be used. In addition, a known interlayer such as an adhesive layer may be provided between the layers.

A drive mode of the liquid crystal cell is not particularly limited, and various modes such as twisted nematic (TN), super twisted nematic (STN), vertical alignment (VA), in-plane switching (IPS), and optically compensated bend cell (OCB) can be used.

Examples of a configuration of the liquid crystal display device in the VA mode include a configuration shown in FIG. 2 of JP2008-262161A. However, the specific configuration of the liquid crystal display device is not particularly limited, and a known configuration can be adopted.

The liquid crystal display device may include a functional layer such as an optical compensation member which performs optical compensation and an adhesive layer.

In addition, the liquid crystal display device may include a color filter substrate, a thin-layer transistor substrate, a lens film, a diffusion sheet, a hard coat layer, an antireflection layer, a low reflection layer, an antiglare layer, or the like.

Further, the liquid crystal display device may include a forward scattering layer, a primer layer, an antistatic layer, an undercoat layer, or the like.

The polarizing plate on the backlight unit side may include a phase difference film as the polarizing plate protective film on the liquid crystal cell side. As such a phase difference film, a known phase difference film such as a cellulose acylate film can be used.

### EXAMPLES

Hereinafter, the present disclosure will be described in more detail using Examples. However, the present disclosure is not limited to the following examples as long as it does not exceed the gist of the present invention. In addition, the numerical value in the tables means “part by mass” unless otherwise specified.

### Preparation of Coating Liquid for Forming Color Conversion Layer

Components shown in Table 23 were mixed to prepare coating liquids A-1 to A-5, B-1 to B-5, and a-1 and b-1 for forming a color conversion layer. Details of the components in Table 23 are as follows.
· Organic light-emitting material a: compound represented by the following chemical formula

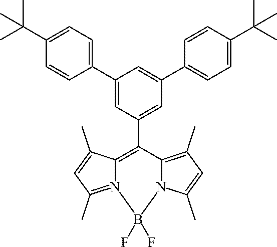

Organic light-emitting material b: compound represented by the following chemical formula

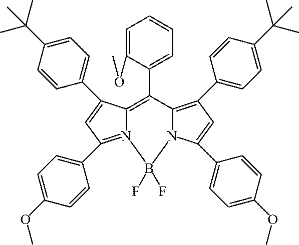

· Polyester resin: (SP value = 10.7 (cal/cm³)^{0.5})
· (Meth)acrylic resin: styrene/acrylic acid = 4/1 (molar ratio), weight-average molecular weight (Mw) = 20,000
· MEK: methyl ethyl ketone, boiling point: 80° C.
· MMPGAC: 1-methoxy-2-propyl acetate, boiling point: 140° C.

TABLE 23

| | Organic light-emitting material | | Binder | | Organic solvent | | | | | |
|---|---|---|---|---|---|---|---|---|---|---|
| | Type | Content | Type | Content | Type | Content | Type | Content | Type | Content |
| A-1 | a | 0.25 | Polyester resin | 100 | MEK | 50 | MMPGAC | 50 | Toluene | – |
| A-2 | a | 0.25 | Polyester resin | 100 | MEK | 20 | MMPGAC | 80 | Toluene | – |
| A-3 | a | 0.25 | Polyester resin | 100 | MEK | 80 | MMPGAC | 20 | Toluene | – |
| A-4 | a | 0.25 | Polyester resin | 100 | MEK | 10 | MMPGAC | 90 | Toluene | – |
| A-5 | a | 0.25 | Polyester resin | 100 | MEK | 90 | MMPGAC | 10 | Toluene | – |
| B-1 | b | 0.03 | (Meth)acrylic resin | 100 | MEK | 150 | MMPGAC | 150 | Toluene | – |
| B-2 | b | 0.03 | (Meth)acrylic resin | 100 | MEK | 60 | MMPGAC | 240 | Toluene | – |
| B-3 | b | 0.03 | (Meth)acrylic resin | 100 | MEK | 240 | MMPGAC | 60 | Toluene | – |
| B-4 | b | 0.03 | (Meth)acrylic resin | 100 | MEK | 30 | MMPGAC | 270 | Toluene | – |
| B-5 | b | 0.03 | (Meth)acrylic resin | 100 | MEK | 270 | MMPGAC | 30 | Toluene | – |
| a-1 | a | 0.25 | Polyester resin | 100 | MEK | 100 | MMPGAC | – | Toluene | – |
| b-1 | b | 0.03 | (Meth)acrylic resin | 100 | MEK | – | MMPGAC | – | Toluene | 300 |

### Example 1

As a support, a polyethylene terephthalate (PET) film (thickness: 50 µm, manufactured by Toray Industries, Inc., LUMIRROR (registered trademark) U48) was prepared.

The coating liquid A-1 for forming a color conversion layer was applied onto one surface of the PET film using a slit-shaped nozzle, and dried at 100° C. to volatilize the solvent, thereby forming, on the support, a first color conversion layer having a thickness of 15 µm after drying.

The coating liquid B-1 for forming a color conversion layer was applied onto the above-described first color conversion layer, and the solvent was volatilized in a drying zone of 100° C., thereby forming, on the first color conversion layer, a second color conversion layer having a thickness of 13 µm after drying.

Next, a chemical mat-treated film having a thickness of 138 µm (manufactured by KIMOTO, Chemical Matte 125PW) as a protective layer was heated and pressure-bonded to the second color conversion layer to manufacture a color conversion film.

The color conversion film was disposed on a planar light-emitting device equipped with a blue LED element having an emission peak wavelength of 405 nm such that a support surface was in contact with the planar light-emitting device, and a prism sheet was placed on the color conversion film.

In a case where a current of 30 mA was passed through the planar light-emitting device to turn on the blue LED element and light having an emission peak wavelength of 447 nm was radiated from the support side, white light including blue light, green light, and red light was observed.

Using a spectral emission brightness meter (CS-1000 manufactured by Konica Minolta Inc.), an emission spectrum of the above-described white light was obtained.

In a case where a peak wavelength of the green light was determined from the obtained emission spectrum, it was 530 nm. In addition, in a case where a peak wavelength of the red light was determined in the same manner, it was 630 nm.

The same measurement was performed for Examples below, and the results are summarized in Table 23. In Examples 6 to 10, the color conversion film was disposed on the planar light-emitting device such that a protective layer surface was in contact with the planar light-emitting device.

### Examples 2 to 5

Color conversion films were manufactured in the same manner as in Example 1, except that, as shown in Table 24, the coating liquid B-1 for forming a color conversion layer was changed to any of the coating liquids B-2 to B-5 for forming a color conversion layer.

### Example 6

As a support, a chemical mat-treated film having a thickness of 138 µm (manufactured by KIMOTO, Chemical Matte 125PW) was prepared.

The coating liquid B-1 for forming a color conversion layer was applied onto one surface of the chemical mat-treated film using a slit-shaped nozzle, and the solvent was volatilized at a drying zone of 100° C., thereby forming, on the support, a first color conversion layer having a thickness of 13 µm after drying.

The coating liquid A-1 for forming a color conversion layer was applied onto the above-described first color conversion layer, and the solvent was volatilized in a drying zone of 100° C., thereby forming, on the first color conversion layer, a second color conversion layer having a thickness of 15 µm after drying.

Next, a polyethylene terephthalate (PET) film (thickness: 50 µm, manufactured by Toray Industries, Inc., LUMIRROR (registered trademark) U48) as a protective layer was heated and pressure-bonded to the second color conversion layer to manufacture a color conversion film.

### Examples 7 to 10

Color conversion films were manufactured in the same manner as in Example 6, except that, as shown in Table 24, the coating liquid A-1 for forming a color conversion layer was changed to any of the coating liquids A-2 to A-5 for forming a color conversion layer.

### Comparative Example 1

A color conversion film was manufactured based on the method disclosed in Example 1 of WO2018/221216A. Specific method thereof is as follows.

As a support, a polyethylene terephthalate (PET) film (thickness: 50 µm, manufactured by Toray Industries, Inc., LUMIRROR (registered trademark) U48) was prepared.

The coating liquid a-1 for forming a color conversion layer was applied onto one surface of the PET film using a slit-shaped nozzle, and the solvent was volatilized at a drying zone of 100° C., thereby forming, on the support, a first color conversion layer having a thickness of 15 µm after drying.

As another support, a chemical mat-treated film having a thickness of 138 µm (manufactured by KIMOTO, Chemical Matte 125PW) was prepared.

The coating liquid b-1 for forming a color conversion layer was applied onto one surface of the chemical mat-treated film using a slit-shaped nozzle, and the solvent was volatilized at a drying zone of 100° C., thereby forming, on the support, a second color conversion layer having a thickness of 13 µm after drying.

The first color conversion layer and the second color conversion layer formed above were heated and laminated to manufacture a color conversion film.

### <<Measurement of Thickness of Interlayer Mixing Layer>>

A fragment of styrene contained in the (meth)acrylic resin was detected and mapped by a secondary ion mass spectrometry (TOF-SIMS) with a cross section of the color conversion film manufactured in Examples and Comparative Examples described above, thereby obtaining a thickness of an interlayer mixing layer.

More specifically, in a case where fragment detection of styrene was started from the layer side using the (meth)acrylic resin as the binder resin (for example, in Example 1, from the second color conversion layer), a position where the styrene fragment weakened was defined as a start position of the interlayer mixing layer and a position where the styrene fragment was no longer detected was defined as an end position of the interlayer mixing layer, and then a thickness of these positions was obtained.

The measurement results are shown in Table 24 with the following standard.

### (Measurement Result)

A: it was confirmed that the interlayer mixing layer was formed, and the thickness of the interlayer mixing layer was less than 0.1 µm.

B: thickness of the interlayer mixing layer was 0.1 µm or more and less than 0.2 µm.

C: thickness of the interlayer mixing layer was 0.2 µm or more and less than 1.0 µm.

D: thickness of the interlayer mixing layer was 1.0 µm or more.

E: formation of the interlayer mixture layer was not confirmed.

### <<Evaluation of Adhesiveness>>

The color conversion films manufactured in Examples and Comparative Examples described above were each cut into a size of 10 cm × 10 cm to prepare a test piece.

Using an HAST test apparatus EHS-221MD (manufactured by ESPEC CORP.), the test piece was allowed to stand for 500 hours in an environment of 65° C. and a relative humidity of 90%.

With the test piece after being allowed to stand, adhesiveness of the first color conversion layer and the second color conversion layer was evaluated by a peeling area of the first color conversion layer and the second color conversion layer based on the following evaluation standard. The evaluation results are shown in Table 24.

### (Evaluation Standard)

A: no peeling occurred between the first color conversion layer and the second color conversion layer.

B: peeling occurred between the first color conversion layer and the second color conversion layer, but the peeling area was less than 5%, which was practically acceptable.

C: peeling occurred between the first color conversion layer and the second color conversion layer, and the peeling area was 5% or more and less than 10%, which was a problem in practical use.

D: peeling occurred between the first color conversion layer and the second color conversion layer, and the peeling area was 10% or more, which was a problem in practical use.

### <<Evaluation of Color Reproducibility>>

From an emission spectrum obtained by color-converting a blue LED with an emission peak wavelength of 405 nm using the color conversion films obtained in Examples and Comparative Examples described above, and from spectral data of transmittance of a color filter, a color gamut in (u′, v′) color space in a case where a color purity was improved by the color filter was calculated. In addition, the calculated color gamut in the (u′, v′) color space was evaluated according to the following standard based on a coverage ratio with respect to DCI-P3 color gamut standard. The evaluation results are shown in Table 24.

### (Evaluation Standard)

A: coverage ratio was 98% or more.

B: coverage ratio was 95% or more and less than 98%.

C: coverage ratio was 94% or more and less than 95%.

D: coverage ratio was less than 94%.

TABLE 24

| | Method of forming second color conversion layer on first color conversion layer | Type of support | Coating liquid used for forming first color conversion layer | Coating liquid used for forming second color conversion layer | Peak wavelength of green light (nm) | Peak wavelength of red light (nm) | Type of protective layer | Measurement of thickness of interlayer mixing layer | Evaluation of adhesiveness | Evaluation of color reproducibility |
|---|---|---|---|---|---|---|---|---|---|---|
| Example 1 | Applying and drying | PET film | A-1 | B-1 | 530 | 630 | Chemical mat-treated film | C | A | A |
| Example 2 | Applying and drying | PET film | A-1 | B-2 | 530 | 630 | Chemical mat-treated film | C | A | A |
| Example 3 | Applying and drying | PET film | A-1 | B-3 | 530 | 630 | Chemical mat-treated film | C | A | B |
| Example 4 | Applying and drying | PET film | A-1 | B-4 | 527 | 632 | Chemical mat-treated film | B | A | A |
| Example 5 | Applying and drying | PET film | A-1 | B-5 | 532 | 633 | Chemical mat-treated film | D | B | C |
| Example 6 | Applying and drying | Chemical mat-treated film | B-1 | A-1 | 530 | 630 | PET film | C | A | A |
| Example 7 | Applying and drying | Chemical mat-treated film | B-1 | A-2 | 530 | 630 | PET film | C | A | A |
| Example 8 | Applying and drying | Chemical mat-treated film | B-1 | A-3 | 530 | 630 | PET film | C | A | B |
| Example 9 | Applying and drying | Chemical mat-treated film | B-1 | A-4 | 527 | 632 | PET film | B | A | A |
| Example 10 | Applying and drying | Chemical mat-treated film | B-1 | A-5 | 532 | 633 | PET film | D | B | C |
| Comparative Example 1 | Heating laminating | PET film | a-1 | b-1 | 530 | 630 | Chemical mat-treated film | E | D | A |

From the results of Examples described above, it was found that the color conversion film according to the embodiment of the present disclosure included the interlayer mixing layer between the first color conversion layer and the second color conversion layer, and had excellent adhesiveness between the first color conversion layer and the second color conversion layer.

The disclosure of JP2020-210832 filed on Dec. 18, 2020 is incorporated in the present specification by reference. All documents, patent applications, and technical standards described in the present specification are herein incorporated by reference to the same extent that each individual document, patent application, or technical standard was specifically and individually indicated to be incorporated by reference.

What is claimed is:

1. A color conversion film comprising, in the following order:
a support;
a first color conversion layer containing an organic light-emitting material which emits, by an excitation light having a wavelength of 400 nm or more and less than 500 nm, light observed in a region having a peak wavelength of 500 nm or more and less than 580 nm;
a second color conversion layer containing an organic light-emitting material which emits, by at least one of the excitation light having a wavelength of 400 nm or more and less than 500 nm or the light emitted from the organic light-emitting material, light observed in a region having a peak wavelength of 580 nm or more and less than 750 nm; and
an interlayer mixing layer between the first color conversion layer and the second color conversion layer, in which the first color conversion layer and the second color conversion layer are mixed together.

2. The color conversion film according to claim 1,
wherein a thickness of the interlayer mixing layer is 0.1 µm to 2.0 µm.

3. The color conversion film according to claim 1, further comprising:
a protective layer on a side of the second color conversion layer opposite to the first color conversion layer.

4. The composition for a color conversion film according to claim 1,
wherein at least one of the organic light-emitting material contained in the first color conversion layer or the organic light-emitting material contained in the second color conversion layer is represented by General Formula (1), 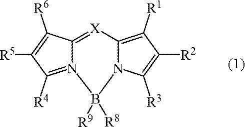
in General Formula (1), X represents C-R⁷ or N, and R¹ to R⁹ are each independently selected from a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an arylether group, an arylthioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, or a phosphine oxide group, where adjacent groups of R¹ to R⁹ may form a fused ring.

5. A color conversion film comprising, in the following order:
a support;
a first color conversion layer containing an organic light-emitting material which emits, by at least one of an excitation light having a wavelength of 400 nm or more and less than 500 nm or light emitted from an organic light-emitting material contained in a second color conversion layer, light observed in a region having a peak wavelength of 580 nm or more and less than 750 nm;
a second color conversion layer containing the organic light-emitting material which emits, by the excitation light having a wavelength of 400 nm or more and less than 500 nm, light observed in a region having a peak wavelength of 500 nm or more and less than 580 nm; and
an interlayer mixing layer between the first color conversion layer and the second color conversion layer, in which the first color conversion layer and the second color conversion layer are mixed together.

6. The color conversion film according to claim 5,
wherein a thickness of the interlayer mixing layer is 0.1 µm to 2.0 µm.

7. The color conversion film according to claim 5, further comprising:
a protective layer on a side of the second color conversion layer opposite to the first color conversion layer.

8. The composition for a color conversion film according to claim 5,
wherein at least one of the organic light-emitting material contained in the first color conversion layer or the organic light-emitting material contained in the second color conversion layer is represented by General Formula (1), 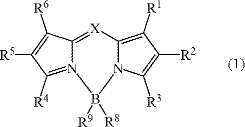
in General Formula (1), X represents C-R⁷ or N, and R¹ to R⁹ are each independently selected from a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an arylether group, an arylthioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, or a phosphine oxide group, where adjacent groups of R¹ to R⁹ may form a fused ring.

9. A backlight unit comprising:
a light source; and
the color conversion film according to claim 1.

10. A backlight unit comprising:
a light source; and
the color conversion film according to claim 5.

11. A liquid crystal display device comprising:
the backlight unit according to claim 9; and
a liquid crystal cell unit.

12. A liquid crystal display device comprising:
the backlight unit according to claim 10; and
a liquid crystal cell unit.
